(19) United States
(12) Patent Application Publication
(10) Pub. No.: US 2018/0164681 A1
(43) Pub. Date: Jun. 14, 2018

(54) COLORING PHOTOSENSITIVE COMPOSITION, CURED FILM, COLOR FILTER, LIGHT-SHIELDING FILM, SOLID-STATE IMAGING DEVICE, IMAGE DISPLAY DEVICE, AND METHOD FOR PRODUCING CURED FILM

(71) Applicant: FUJIFILM Corporation, Tokyo (JP)

(72) Inventors: Tetsuya KAMIMURA, Haibara-gun (JP); Daisuke HAMADA, Haibara-gun (JP); Yushi KANEKO, Haibara-gun (JP); Makoto KUBOTA, Haibara-gun (JP); Keiji YAMAMOTO, Haibara-gun (JP)

(73) Assignee: FUJIFILM Corporation, Tokyo (JP)

(21) Appl. No.: 15/893,794

(22) Filed: Feb. 12, 2018

Related U.S. Application Data
(63) Continuation of application No. PCT/JP2016/075046, filed on Aug. 26, 2016.

(30) Foreign Application Priority Data
Aug. 31, 2015 (JP) 2015-171584
Mar. 22, 2016 (JP) 2016-057099
Apr. 26, 2016 (JP) 2016-088452
Aug. 25, 2016 (JP) 2016-164786

(51) Int. Cl. G03F 7/031

(52) U.S. Cl. CPC G03F 7/031; G02B 5/20

(57) ABSTRACT

Provided are a coloring photosensitive composition that is curable in a low-temperature environment, as well as a cured film, a color filter, a light-shielding film, a solid-state imaging device, an image display device, and a method for producing a cured film, in which the coloring photosensitive composition is used. The coloring photosensitive composition contains a coloring agent, a polymerizable compound, and a photopolymerization initiator, in which the photopolymerization initiator in the form of a solution in which 0.001% by mass of the photopolymerization initiator is dissolved in acetonitrile has an absorbance of 0.45 or more at a wavelength of 340 nm.

### CROSS-REFERENCE TO RELATED APPLICATIONS

This application is a Continuation of PCT International Application No. PCT/JP2016/075046 filed on Aug. 26, 2016, which claims priority under 35 U.S.C. § 119(a) to Japanese Patent Application No. 2015-171584 filed on Aug. 31, 2015, Japanese Patent Application No. 2016-057099 filed on Mar. 22, 2016, Japanese Patent Application No. 2016-088452 filed on Apr. 26, 2016 and Japanese Patent Application No. 2016-164786 filed on Aug. 25, 2016. Each of the above applications is hereby expressly incorporated by reference, in its entirety, into the present application.

### BACKGROUND OF THE INVENTION

### 1. Field of the Invention

The present invention relates to a coloring photosensitive composition, a cured film, a color filter, a light-shielding film, a solid-state imaging device, an image display device, and a method for producing a cured film.

### 2. Description of the Related Art

A color filter is a component part which is essential for a solid-state imaging device, an image display device, or the like.

Furthermore, the solid-state imaging device, the image display device, or the like generates noise by reflection of visible light in some cases. Accordingly, it has been facilitated to inhibit the generation of noise by providing a light-shielding film for the solid-state imaging device, the image display device, or the like.

As a method for forming a cured film which serves as a color filter or a light-shielding film, a method including forming a coloring photosensitive composition layer using a coloring photosensitive composition including a coloring agent, a polymerizable compound, and a photopolymerization initiator, and exposing the coloring photosensitive composition layer to form a cured film is known.

For example, in JP2013-164471A, IRGACURE (registered trademark)-OXE01 (manufactured by BASF), IRGACURE (registered trademark)-OXE02 (manufactured by BASF), or the like is used as a photopolymerization initiator.

### SUMMARY OF THE INVENTION

In a case of exposing the coloring photosensitive composition layer as described above to form a cured film (including a pattern (the same shall apply hereinafter)), a heating treatment (for example, a post-baking at approximately 200° C. after exposure) for accelerating curing is usually carried out in many cases.

However, there has recently been an increasing demand for performing curing a cured film in a low-temperature environment.

The present inventors have investigated a coloring photosensitive composition containing the photopolymerization initiator described in JP2013-164471A, and thus, curing has been sometimes insufficient in a case where a heating treatment in a high-temperature environment is not accompanied.

A cured film which has undergone insufficient curing is deteriorated in characteristics such as heat resistance, light resistance, solvent resistance, moisture resistance, and adhesiveness to a support, which may be problematic in some cases.

Therefore, an object of the present invention is to provide a coloring photosensitive composition that is curable in a low-temperature environment, as well as a cured film, a color filter, a light-shielding film, a solid-state imaging device, an image display device, and a method for producing a cured film, in which the coloring photosensitive composition is used.

The present inventors have conducted extensive studies, and thus, have found that the objects can be achieved by using a specific polymerization initiator.

That is, the present invention provides the following [1] to [29].

[1] A coloring photosensitive composition comprising:

a coloring agent;

a polymerizable compound; and

a photopolymerization initiator,

in which the photopolymerization initiator in the form of a solution in which 0.001% by mass of the photopolymerization initiator is dissolved in acetonitrile has an absorbance of 0.45 or more at a wavelength of 340 nm.

[2] The coloring photosensitive composition as described in [1],

in which the photopolymerization initiator is a compound represented by Formula (I).

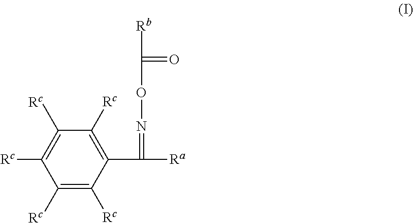

In Formula (I), R^{a} represents an alkyl group, an acyl group, an aryl group, or a heterocyclic group, R^{b} represents an alkyl group, an aryl group, or a heterocyclic group, a plurality of R^{c}'s each independently represent a hydrogen atom, an alkyl group, or a group represented by —OR^{h}, and R^{h} represents an electron-withdrawing group or an alkyl ether group, provided that at least one of the plurality of RC's represents a group represented by —OR^{h}.

[3] The coloring photosensitive composition as described in [2],

in which R^{a} is a heterocyclic group.

[4] The coloring photosensitive composition as described in [2] or [3],

in which one or two of the plurality of R^{c}'s are the groups represented by —OR^{h}.

[5] The coloring photosensitive composition as described in any one of [2] to [4],

in which R^{h} in the group represented by —OR^{h} represents an electron-withdrawing group, and the electron-withdrawing group is an alkyl group having 1 to 20 carbon atoms, in which at least one hydrogen atom is substituted with a fluorine atom.

[6] The coloring photosensitive composition as described in any one of [2] to [4],

in which R^{h} in the group represented by —OR^{h} represents an alkyl ether group.

[7] The coloring photosensitive composition as described in any one of [1] to [6],

in which the polymerizable compound has 5 or more ethylenically unsaturated double bonds.

[8] The coloring photosensitive composition as described in any one of [1] to [7], further comprising a resin.

[9] The coloring photosensitive composition as described in any one of [1] to [8], further comprising a surfactant.

[10] The coloring photosensitive composition as described in any one of [1] to [9], further comprising an ultraviolet absorber.

[11] The coloring photosensitive composition as described in any one of [1] to [10], further comprising a polymerization inhibitor.

[12] The coloring photosensitive composition as described in [11],

in which the polymerization inhibitor is a phenol-based polymerization inhibitor.

[13] The coloring photosensitive composition as described in [11],

in which two or more phenol-based polymerization inhibitors are used in combination as the polymerization inhibitor.

[14] The coloring photosensitive composition as described in [11],

in which a phenol-based polymerization inhibitor and a hindered amine-based polymerization inhibitor are used in combination as the polymerization inhibitor.

[15] The coloring photosensitive composition as described in any one of [1] to [14],

in which the coloring agent includes titanium black.

[16] The coloring photosensitive composition as described in [15],

in which the titanium black is titanium nitride.

[17] The coloring photosensitive composition as described in any one of [1] to [16],

in which the coloring agent includes niobium oxynitride.

[18] The coloring photosensitive composition as described in any one of [1] to [17], further comprising an organic solvent.

[19] The coloring photosensitive composition as described in [18],

in which two or more organic solvents are used in combination as the organic solvent.

[20] A cured film formed by curing the coloring photosensitive composition as described in any one of [1] to [19].

[21] A color filter formed by curing the coloring photosensitive composition as described in any one of [1] to [19].

[22] A light-shielding film formed by curing the coloring photosensitive composition as described in any one of [1] to [19].

[23] A solid-state imaging device comprising the cured film as described in [20].

[24] An image display device comprising the cured film as described in [20].

[25] A method for producing a cured film, comprising at least:

a step of forming a coloring photosensitive composition layer on a support, using the coloring photosensitive composition as described in any one of [1] to [19]; and

a step of exposing the coloring photosensitive composition layer to form a cured film.

[26] The method for producing a cured film as described in [25], further comprising a step of subjecting the cured film to a heating treatment,

in which the temperature for the heating treatment is 120° C. or lower.

[27] The method for producing a cured film as described in [25], further comprising a step of subjecting the cured film to a heating treatment,

in which the temperature for the heating treatment is 80° C. or lower.

[28] The method for producing a cured film as described in [25], further comprising a step of subjecting the cured film to a heating treatment,

in which the temperature for the heating treatment is 50° C. or lower.

[29] The method for producing a cured film as described in any one of [25] to [28],

in which the support has an epoxy resin layer on the surface on which the cured film is formed.

According to the present invention, it is possible to provide a coloring photosensitive composition that is curable in a low-temperature environment, as well as a cured film, a color filter, a light-shielding film, a solid-state imaging device, an image display device, and a method for producing a cured film, in which the coloring photosensitive composition is used.

### DESCRIPTION OF THE PREFERRED EMBODIMENTS

Hereinafter, the contents of the present invention will be described in detail.

In citations for a group (atomic group) in the present specification, in a case where the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In the present specification, light means actinic ray or radiation. Further, “actinic rays” or “radiation” means, for example, a bright line spectrum of a mercury lamp or the like, far ultraviolet rays represented by an excimer laser, extreme ultraviolet rays (EUV light), X-rays, electron beams, or the like.

In the present specification, “exposure” includes, unless otherwise specified, not only exposure by a mercury lamp, far ultraviolet rays represented by an excimer laser, X-rays, EUV light, or the like, but also writing by particle rays such as electron beams and ion beams.

In the present specification, a numerical range expressed using “to” means a range that includes the preceding and succeeding numerical values of “to” as the lower limit value and the upper limit value, respectively.

In the present specification, the total solid content refers to a total mass of the components remaining in a case where a solvent is excluded from the entire composition of a composition.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, a term “step” includes not only an independent step, but also steps which are not clearly distinguished from other steps in a case where an intended action of the steps is obtained.

In the present specification, the weight-average molecular weight (Mw) and the number-average molecular weight (Mn) are defined as a value in terms of polystyrene by gel permeation chromatography (GPC) measurement. More specifically, Mw and Mn are measured under the following conditions.

Types of columns: TSKgel Super AWM-H (manufactured by Tosoh Corporation, 6.0 mm ID (inner diameter)×15.0 cm)

Developing solvent: 10 mmol/L Lithium bromide N-methylpyrrolidinone (NMP) solution

Column temperature: 25° C.

Flow rate (amount of a sample to be injected): 0.6 mL/min

Name of device: HLC-8220 (manufactured by Tosoh Corporation)

Calibration curve base resin: Polystyrene resin

[Coloring Photosensitive Composition]

The coloring photosensitive composition of the present invention (hereinafter simply also referred to as a coloring composition) is a coloring photosensitive composition containing a coloring agent, a polymerizable compound, and a photopolymerization initiator, in which the photopolymerization initiator in the form of a solution in which 0.001% by mass of the photopolymerization initiator is dissolved in acetonitrile has an absorbance of 0.45 or more at a wavelength of 340 nm.

By incorporation of the coloring composition of the present invention, it is possible to perform curing at a low-temperature environment. That is, a cured film obtained using the coloring composition of the present invention has good heat resistance, light resistance, solvent resistance, moisture resistance, adhesiveness to a support, or the like even in a case where a heating treatment at a high temperature is not accomplished.

The reason therefor is presumed to be as follows. That is, it is thought that since the photopolymerization initiator used in the present invention has a relatively high absorbance, the initiator efficiency is improved, and thus, curing sufficiently proceeds in the entire film even though a heating treatment at a high temperature is not carried out. As a result, the curing in the vicinity of a support which is likely to be insufficient only through exposure also proceeds, and thus, the adhesiveness to a support is improved. In addition, the curing in the entire film sufficiently proceeds, and therefore characteristics such as heat resistance, light resistance, solvent resistance, and moisture resistance are also excellent.

These effects are also obtained in the same manner in a case of forming a pattern (colored pattern) using the coloring composition of the present invention.

Furthermore, in a case of forming a line pattern, the linearity of the line pattern is also excellent. The reason therefor is presumed to be as follows: since the curing in exposed areas sufficiently proceeds even though a heating treatment at a high temperature is not carried out, the line width of the line pattern becomes uniform.

Hereinafter, the respective components contained in the coloring composition of the present invention will be first described in detail.

[Coloring Agent]

The coloring composition of the present invention contains a coloring agent. The coloring agent may be either a pigment or a dye.

The content of the coloring agent is preferably 1% to 80% by mass with respect to the total solid content of the coloring composition. The lower limit is preferably 5% by mass or more, more preferably 10% by mass or more, and still more preferably 20% by mass or more. The upper limit is preferably 75% by mass or less, and more preferably 70% by mass or less.

If the concentration of the coloring agent is designed to be high, light for exposure does not reach the under layer of layers, leading to curing failure, in some cases, but since the coloring composition of the present invention has high sensitivity and high polymerization efficiency, the curing can be carried out even though the high concentration is as high as 20% by mass or more, which is thus preferable. In particular, this effect becomes remarkable in a case of a low temperature.

<Pigment>

Examples of the pigment include various inorganic pigments or organic pigments known in the related art.

Examples of the inorganic pigment include oxides of metals such as iron, cobalt, aluminum, cadmium, lead, copper, titanium, magnesium, chromium, zinc, and antimony; and composite oxides of the metals.

Examples of the organic pigments include the following pigments, but the present invention is not limited thereto.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like

C. I. Pigment Orange 2, 5, 13, 16, 17:1, 31, 34, 36, 38, 43, 46, 48, 49, 51, 52, 55, 59, 60, 61, 62, 64, 71, 73, and the like

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279,

C. I. Pigment Green 7, 10, 36, 37, 58, and 59

C. I. Pigment Violet 1, 19, 23, 27, 32, 37, and 42

C. I. Pigment Blue 1, 2, 15, 15:1, 15:2, 15:3, 15:4, 15:6, 16, 22, 60, 64, 66, 79, and 80

These organic pigments can be used singly or in various combinations in order to enhance the color purity.

(Black Pigment)

In the present invention, black pigments can also be used as a black pigment. Hereinafter, the black pigment will be described in more detail.

As the black pigment, various known black pigments can be used. In particular, from the viewpoint of achieving a high optical density with a small amount of the pigment, carbon black, titanium black, and metal pigments can be exemplified. Examples of the metal pigments include metal oxides or metal nitrides including one or two or more metal elements selected from the consisting of Co, Cr, Cu, Mn, Ru, Fe, Ni, Sn, Ti, and Ag.

As the black pigment, from the viewpoint of achieving a high optical density with a small amount of the pigment, metal pigments including carbon black, titanium black, titanium oxide, iron oxide, manganese oxide, graphite, silver, and/or tin are preferable. Among those, metal pigments including at least one of carbon black or titanium black is preferable, and in particular, from the viewpoint that the absorption in the light-absorption wavelength range of an initiator with respect to the curing efficiency due to exposure is small, titanium black is more preferable. Specific examples of the carbon black include, but are not limited to, organic pigments such as C. I. Pigment Black 1, and inorganic pigments such as C. I. Pigment Black 7, which are commercially available products.

(Other Pigments)

In the present invention, a pigment having infrared ray absorptivity can also be used as the pigment, in addition to the pigments described as the black pigment.

As the pigment having infrared ray absorptivity, a tungsten compound, a metal boride, or the like is preferable, and among those, the tungsten compound is more preferable in a view that the light-shielding properties at a wavelength in the infrared region are excellent. In particular, the tungsten compound is preferable from the viewpoint that the light transmittances of an initiator in a light-absorption wavelength range and a visible light region with respect to the curing efficiency due to exposure are excellent.

These pigments may be used in combination of two or more kinds thereof, and may also be used in combination with a dye which will be described later. For the purpose of adjusting the tint and/or enhancing the light-shielding properties of a desired wavelength range, for example, an aspect in which the above-mentioned chromatic color pigment in red, green, yellow, orange, purple, blue, or the like, or a dye which will be described later is mixed with a black pigment or a pigment having infrared-ray-shielding properties may be exemplified. It is preferable to incorporate a red pigment or dye, or a purple pigment or dye into a black pigment or a pigment having infrared-ray-shielding properties, and it is particularly preferable to incorporate a red pigment into a black pigment or a pigment having infrared-ray-shielding properties.

The black pigment preferably contains titanium black and/or niobium oxynitride.

The titanium black is a black particle containing a titanium atom. Preferably, it is substoichiometric titanium oxide, titanium oxynitride, titanium nitride, or the like. The titanium black particle can have the surface modified, as desired, for the purpose of improvement of the dispersibility, suppression of aggregating properties, and the like. For example, it is possible to coat the titanium black particle with silicon oxide, titanium oxide, germanium oxide, aluminum oxide, magnesium oxide, or zirconium oxide, and it is also possible to perform a treatment with a water-repellent material as shown in JP2007-302836A.

The titanium black is typically a titanium black particle, and it is preferable that the primary particle diameter and the average primary particle diameter of the individual particles are both small, which shall apply to niobium oxynitride.

Specifically, the average primary particle diameter is preferably in the range of 10 nm to 45 nm.

Moreover, the average primary particle diameter of the pigments can be measured using a transmission electron microscope (TEM). As the transmission electron microscope, for example, a transmission microscope HT7700 manufactured by Hitachi High-Technologies Corporation can be used.

A maximum length (Dmax: a maximum length between two points on a contour of a particle image) and a maximum perpendicular length (DV-max: a shortest length connecting perpendicularly between two straight lines when the image is interposed between the two straight lines parallel with the maximum length) of a particle image acquired by using a transmission electron microscope are measured, and a geometric mean value (Dmax×DV-max)½ is defined as a particle diameter. The particle diameters of 100 particles are measured by this method, an arithmetic average value thereof is taken as the average particle diameter, which is defined as an average primary particle diameter of the pigments.

The specific surface areas of the titanium black and niobium oxynitride are not particularly limited, and the value measured by a Brunauer, Emmett, Teller (BET) method is preferably in the order of from 5 m²/g to 150 m²/g, and more preferably from 20 m²/g to 120 m²/g so that the water repellency of the titanium black and the niobium oxynitride after the surface treatment using a water-repellent agent exhibits a predetermined performance.

Examples of a commercially available product of the titanium black include Titanium Black 10S, 12S, 13R, 13M, 13M-C, 13R, 13R-N, and 13M-T (trade names, manufactured by Mitsubishi Materials Corporation), Tilack D (trade name, manufactured by Akokasei Co., Ltd.), and Titanium Nitride 50 nm (trade name: manufactured by Wako Pure Chemical Industries, Ltd.).

In the present invention, titanium oxynitride, titanium nitride, or niobium oxynitride is preferably used as the coloring agent, and for a reason that the moisture resistance of a cured film thus obtained is superior, titanium nitride or niobium oxynitride is more preferable, and niobium oxynitride is still more preferable. A reason therefor is thought to be that these coloring agents are hydrophobic.

In addition, it is also suitable to mix and use two or more selected from the group consisting of titanium oxynitride, titanium nitride, and niobium oxynitride. Here, the mixing ratio is not particularly limited, but for example, in a case of using two thereof, in which one is defined as A and the other is defined as B, the mass ratio (A/B) is preferably 1/99 to 99/1, and more preferably 5/95 to 95/5.

Furthermore, it is also preferable that the titanium black is contained as a dispersoid including the titanium black and Si atoms.

In this form, the titanium black is contained as a dispersoid in a composition, and the content ratio (Si/Ti) of Si atoms to Ti atoms in the dispersoid is preferably 0.05 or more, more preferably 0.05 to 0.5, and still more preferably 0.07 to 0.4 in terms of mass.

Here, the dispersoid includes both the titanium black in the state of primary particles and the titanium black in the state of aggregates (secondary particles).

In order to change the Si/Ti of the dispersoid (to 0.05 or more, for example), it is possible to use the following means.

First, a dispersion is obtained by dispersing titanium oxide and silica particles with a dispersing machine, and then the dispersion is subjected to a reducing treatment at a high temperature (for example, 850° C. to 1,000° C.). Thus, the dispersoid having the titanium black particles as a main component and containing Si and Ti can be obtained. The reduction treatment can also be carried out in the reductive gas atmosphere such as ammonia.

Examples of the titanium oxide include TTO-51N (trade name: manufactured by Ishihara Sangyo Kaisha, Ltd.). Further, titanium oxide fine particles manufactured by a method for producing nano-sized fine particles in using plasma described in JP2012-055840A can also be suitably used. For a reason that the primary particle diameter of a dispersoid thus obtained can be reduced, it is preferable to use particles having small primary particle diameters as the titanium oxide. The titanium oxide is not limited to the above-mentioned titanium oxide, and the primary particle diameter of the titanium oxide is preferably 5 to 100 nm, more preferably 5 to 70 nm, and still more preferably 10 to 50 nm.

Examples of the commercially available products of the silica particles include AEROSIL (trademark) 90, 130, 150, 200, 255, 300, and 380 (trade name: manufactured by Evonik Industries).

Dispersion of titanium oxide and silica particles may be carried out using a dispersant. Examples of the dispersant include those described in the section of the dispersant which will be described later.

The dispersion can also be carried out in a solvent. Examples of the solvent include water and organic solvents. Examples of the solvents include those described in the section of the organic solvent which will be described later.

The titanium black with the Si/Ti adjusted to 0.05 or more, for example, can be manufactured by the methods described in, for example, paragraph Nos. [0005], and [0016] to

of JP2008-266045A.

By adjusting the content ratio (Si/Ti) of the Si atoms to the Ti atoms in the dispersoid including the titanium black and the Si atoms to a suitable range (for example, 0.05 or more), the amount of the residue derived from the composition, remaining on the outside of a region where the light-shielding film is formed is reduced in a case where the light-shielding film is formed by using the composition including the dispersoid. Further, the residue includes a component derived from the titanium black particles or a composition such as a resin component.

The reason why the amount of the residue is reduced has not been clarified yet, but the above-mentioned dispersoid tends to have a small particle diameter (for example, a particle diameter of 30 nm or less), and the adsorptivity to the underlying substrate of the whole film decreases as the component including the Si atoms increases in the dispersoid. This is assumed to contribute to improvement of the development removability of uncured composition (in particular, the titanium black) in the formation of the light-shielding film.

Furthermore, from the viewpoint that the titanium black has excellent light-shielding properties to light in wavelength ranges widely ranging from ultraviolet rays to infrared light, the light-shielding film formed using the dispersoid (preferably with the Si/Ti of 0.05 or more in terms of mass) including the titanium black and Si atoms exerts excellent light-shielding properties.

Incidentally, the content ratio (Si/Ti) of the Si atoms to the Ti atoms in the dispersoid can be measured using, for example, the method (1-1) or the method (1-2) described in paragraph 0033 of JP2013-249417A.

In addition, for the dispersoid contained in the light-shielding film obtained by curing the composition, it is determined whether the content ratio (Si/Ti) of the Si atoms to the Ti atoms in the dispersoid is 0.05 or more, using the method (2) described in paragraph 0035 of JP2013-249417A.

In the dispersoid including the titanium black and the Si atom, the titanium black as described above can be used.

Furthermore, in this dispersoid, one kind or two or more kinds of composite oxides such as Cu, Fe, Mn, V, and Ni, cobalt oxide, iron oxide, a black pigment formed of carbon black, aniline black, or the like may be combined as the dispersoid with the titanium black, for the purpose of adjusting dispersibility, colorability, and the like.

In this case, it is preferable that the dispersoid formed of the titanium black occupies 50% by mass or more of the entire dispersoid.

Incidentally, in the dispersoid, another coloring agent (an organic pigment, a dye, or the like) may be used together with the titanium black as desired as long as the coloring agent does not impair the effects of the present invention, for the purpose of adjusting light-shielding properties or the like.

Hereinafter, the materials used in introducing the Si atoms into the dispersoid will be described. In a case where the Si atoms are introduced into the dispersoid, a Si-containing material such as silica may be used.

Examples of the silica which can be used herein include precipitated silica, fumed silica, colloidal silica, and synthetic silica, and may be selected as appropriate.

Furthermore, since the light-shielding properties are more excellent in a case where the particle diameter of the silica particle is smaller than the thickness of the film in the formation of a light-shielding film, it is preferable to use fine particle-type silica as the silica particle. Further, examples of the fine particle-type silica include the silica described in paragraph 0039 of JP2013-249417A, the contents of which are incorporated herein by reference.

Furthermore, in the same manner as in the method for producing a dispersoid except that niobium oxide was used instead of titanium oxide, a dispersoid including niobium oxynitride and a Si atom can be manufactured can also be manufactured. In this case, as the raw material, for example, niobium pentoxide powder (Nb₂O₅, H. C. Starck) which is commercially available can be used. Further, niobium oxide as the raw material can be produced in the same manner as the method for nano-sized fine particles using plasma described in JP2012-055840A except that metal niobium powder is used instead of Ti powder as a raw material, and further, by appropriately regulating treatment parameters of a device.

Furthermore, a tungsten compound and a metal boride can also be used as the pigment.

Hereinafter, the tungsten compound and the metal boride will be described in detail.

For the coloring composition of the present invention, a tungsten compound and/or a metal boride can be used.

The tungsten compound and the metal boride are each an infrared-ray-blocking material having high absorption of infrared rays (light at a wavelength of about 800 to 1,200 nm) (that is, high light-shielding properties (light-blocking properties) for infrared rays) and low absorption of visible light. Accordingly, by incorporating the tungsten compound and/or the metal boride into the coloring composition of the present invention, the coloring composition can form a pattern having high light-shielding properties in the infrared region and high light transmittance in the visible light region.

Furthermore, the tungsten compound and the metal boride exhibit a small absorption for light at a wavelength shorter than the visible region, which is employed in the image formation and used at exposure to a high-pressure mercury lamp, KrF, ArF, or the like. Therefore, by combining the tungsten compound and the metal boride with a polymerizable compound, an alkali-soluble resin, and a photopolymerization initiator, each of which will be described later, an excellent pattern is obtained, and at the same time, development scum can further be suppressed in the pattern formation.

Examples of the tungsten compound include a tungsten oxide-based compound, a tungsten boride-based compound, and a tungsten sulfide-based compound, and the tungsten compound is preferably a tungsten oxide-based compound represented by General Formula (compositional formula) (I):

MₓW_{y}O_{z} (I)

M represents a metal, W represents tungsten, and O represents oxygen,

0.001≤x/y≤1.1, and

2.2≤z/y≤3.0.

Examples of the metal of M include an alkali metal, an alkaline earth metal, Mg, Zr, Cr, Mn, Fe, Ru, Co, Rh, Ir, Ni, Pd, Pt, Cu, Ag, Au, Zn, Cd, Al, Ga, In, Tl, Sn, Pb, Ti, Nb, V, Mo, Ta, Re, Be, Hf, Os, and Bi, with the alkali metal being preferable. The metal of M may be one kind or two or more kinds of metals.

M is preferably an alkali metal, more preferably Rb or Cs, and still more preferably Cs.

In a case where x/y is 0.001 or more, the infrared rays can be sufficiently blocked, and in a case where x/y is 1.1 or less, production of an impurity phase in the tungsten compound can be more reliably avoided.

In a case where z/y is 2.2 or more, chemical stability as the material can be more enhanced, and in a case where it is 3.0 or less, the infrared rays can be sufficiently blocked.

Specific examples of the tungsten oxide-based compound represented by General Formula (I) include Cs_{0.33}WO₃, Rb_{0.33}WO₃, K_{0.33}WO₃, and Ba_{0.33}WO₃, and the compound is preferably Cs_{0.33}WO₃ or Rb_{0.33}WO₃, and more preferably Cs_{0.33}WO₃.

The tungsten compound is preferably a fine particle. The average primary particle diameter of the tungsten fine particles is preferably 800 nm or less, more preferably 400 nm or less, and still more preferably 200 nm or less. In a case where the average primary particle diameter is in such the range, the tungsten fine particle is scarcely allowed to block the visible light because of light scattering, so that light transmittance in the visible region can be more successfully ensured. In a view of avoiding light scattering, the average primary particle diameter is preferably smaller, but for the reason of easy handling or the like at the production, the average primary particle diameter of the tungsten fine particles is usually 1 nm or more.

Moreover, it is possible to use two or more kinds of the tungsten compounds.

The tungsten compound is available as a commercially available product, but in a case where the tungsten compound is, for example, a tungsten oxide-based compound, the tungsten oxide-based compound can be obtained by a method of heat-treating a tungsten compound in an inert gas atmosphere or a reductive gas atmosphere (refer to JP4096205B).

Furthermore, the tungsten oxide-based compound is also available, for example, as a dispersion of tungsten fine particle, such as YMF-02 manufactured by Sumitomo Metal Industries, Ltd.

Examples of the metal boride include one kind or two or more kinds of, for example, lanthanum boride (LaB₆), praseodymium boride (PrB₆), neodymium boride (NdB₆), cerium boride (CeB₆), yttrium boride (YB₆), titanium boride (TiB₂), zirconium boride (ZrB₂), hafnium boride (HfB₂), vanadium boride (VB₂), tantalum boride (TaB₂), chromium boride (CrB, CrB₂), molybdenum boride (MoB₂, Mo₂B₅, MoB), and tungsten boride (W₂B₅), with lanthanum boride (LaB₆) being preferable.

The metal boride is preferably a fine particle. The average primary particle diameter of the metal boride fine particle is preferably 800 nm or less, more preferably 300 nm or less, still more preferably 100 nm or less. In a case where the average primary particle diameter is in such the range, the metal boride fine particle is less likely to block visible light by light scattering, so that light transmittance in the visible region can be more reliably ensured. In a view of avoiding light scattering, the average primary particle diameter is preferably smaller, but for a reason of easy handling or the like during the production, the average particle diameter of the metal boride fine particles is usually 1 nm or more.

Furthermore, it is possible to use two or more kinds of the metal boride.

The metal boride is available as a commercially available product, and is also available as a dispersion of metal boride fine particles, such as KHF-7 produced by Sumitomo Metal Industries, Ltd.

<Dye>

As the dye, the coloring agents disclosed in, for example, JP1989-90403A (JP-564-90403A) JP1989-91102A (JP-S64-91102A), JP1989-94301A (JP-H01-94301A), JP1994-11614A (JP-H06-11614A), JP2592207B, U.S. Pat. No. 4,808,501A, U.S. Pat. No. 5,667,920A, U.S. Pat. No. 5,059,50A, JP1993-333207A (JP-H05-333207A), JP1994-35183A (JP-H06-35183A), JP1994-51115A (JP-H06-51115A), and JP1994-194828A (JP-H06-194828A) can be used. In terms of classification based on the chemical structure, it is possible to use a pyrazoleazo compound, a pyrromethene compound, an anilinoazo compound, a triphenylmethane compound, an anthraquinone compound, a benzylidene compound, an oxonol compound, a pyrazolotriazoleazo compound, a pyridoneazo compound, a cyanine compound, a phenothioazine compound, a pyrrolopyrazoleazomethine compound, or the like can be used. In addition, as the dye, a coloring agent multimer may be used. Examples of the coloring agent multimer include the compounds described in JP2011-213925A and JP2013-041097A. Further, a polymerizable dye having polymerizability in the molecule may be used, and examples of a commercially available product thereof include RDW Series (for example, RDW-K01 and RDW-R56) manufactured by Wako Pure Chemical Industries, Ltd.

Furthermore, in the present invention, a coloring agent having a maximum absorption in a wavelength range of 800 to 900 nm can be used as the coloring agent.

Examples of the coloring agent having such spectral characteristics include a pyrrolopyrrole compound, a copper compound, a cyanine compound, a phthalocyanine compound, an iminium compound, a thiol complex-based compounds, a transition metal oxide-based compounds, a squarylium compounds, a naphthalocyanine compounds, a quaterylene compound, a dithiol metal complex-based compound, and a croconium compound.

As the phthalocyanine compound, the naphthalocyanine compound, the iminium compound, the cyanine compound, the squarylium compound, and the croconium compound, the compounds disclosed in paragraphs 0010 to 0081 of JP2010-111750A may be used, the contents of which are incorporated herein by reference. With regard to the cyanine compound, reference can be made to, for example, “Functional Coloring Agent, written by Okawara Shin, Matsuoka Ken, Kitao Teijirou, and Hirashima Kousuke, published by Kodansha Scientific Ltd.”, the contents of which are incorporated to the present specification.

As the coloring agent having the spectral characteristics, the compounds disclosed in paragraphs 0004 to 0016 of JP1995-164729A (JP-H07-164729A), the compounds disclosed in paragraphs 0027 to 0062 of JP2002-146254A, and the near-infrared absorption particles disclosed in paragraphs 0034 to 0067 of JP2011-164583A, which are formed of crystallites of oxide including Cu and/or P, and that have a number-average aggregate particle diameter of 5 to 200 nm can also be used.

In the present invention, the coloring agent having maximum absorption in a wavelength range of 800 to 900 nm is preferably a pyrrolopyrrole compound. The pyrrolopyrrole compound may be either a pigment or a dye, but is preferably the pigment for a reason that a coloring composition capable of forming a film having excellent heat resistance is easily obtained.

With regard to the details of the pyrrolopyrrole compound, reference can be made to the description in paragraph Nos. 0017 to 0047 of JP2009-263614A, the contents of which are incorporated herein by reference. Incidentally, specific examples of the pyrrolopyrrole compound include the compounds described in paragraph Nos. 0049 to 0058 of JP2009-263614A, the contents of which are incorporated herein by reference.

[Pigment Derivative]

The coloring composition of the present invention may contain a pigment derivative. The pigment derivative is preferably a compound having a structure in which some of an organic pigment is substituted with an acidic group, a basic group, or a phthalimidomethyl group. As the pigment derivative, a pigment derivative having an acidic group or a basic group is preferable from the viewpoint of dispersibility and the dispersion stability of the coloring agent A, and a pigment derivative having a basic group is particularly preferable. Further, a combination of the above-mentioned resin (dispersant) and the pigment derivative is preferably a combination in which the dispersant is an acidic dispersant and the pigment derivative is a compound having a basic group.

Examples of the organic pigment for constituting the pigment derivative include a diketopyrrolopyrrole-based pigment, an azo-based pigment, a phthalocyanine-based pigment, an anthraquinone-based pigment, a quinacridone-based pigment, a dioxazine-based pigment, a perinone-based pigment, a perylene-based pigment, a thioindigo-based pigment, an isoindoline-based pigment, an isoindolinone-based pigment, a quinophthalone-based pigment, a threne-based pigment, and a metal complex-based pigment.

In addition, the acidic group contained in the pigment derivative is preferably a sulfonic acid group, a carboxylic acid group, or a salt thereof, more preferably a carboxylic acid group or a sulfonic acid group, and particularly preferably a sulfonic acid group. The basic group contained in the pigment derivative is preferably an amino group, and particularly preferably a tertiary amino group.

In a case where the coloring composition of the present invention contains the pigment derivative, the content of the pigment derivative is preferably 1% to 30% by mass, and more preferably 3% to 20% by mass, with respect to the mass of the pigment. The pigment derivative may be used singly or in combination of two or more kinds thereof.

[Polymerizable Compound]

The coloring composition of the present invention includes a polymerizable compound.

The polymerizable compound is preferably a compound having one or more groups having an ethylenically unsaturated bond, more preferably a compound having a group having two or more ethylenically unsaturated bonds, still more preferably a compound having a group having three or more ethylenically unsaturated bonds, and particularly preferably a compound having a group having five or more ethylenically unsaturated bonds. The upper limit is, for example, 15 or less. Examples of the group having an ethylenically unsaturated bond include a vinyl group, a (meth)allyl group, and a (meth)acryloyl group.

The polymerizable compound may be any chemical form of, for example, a monomer, a prepolymer, that is, a dimer or a trimer, and an oligomer, a mixture thereof, and a multimer thereof, with the monomer being preferable.

The molecular weight of the polymerizable compound is preferably 100 to 3,000, and more preferably 250 to 1,500.

The polymerizable compound is preferably a trifunctional to pentadecafunctional (meth)acrylate compound, and more preferably a trifunctional to hexafunctional (meth)acrylate compound.

Examples of the monomer and the prepolymer include unsaturated carboxylic acids (for example, acrylic acid, methacrylic acid, itaconic acid, crotonic acid, isocrotonic acid, and maleic acid); esters thereof amides thereof and multimers thereof, and the monomer and the prepolymer are preferably esters of unsaturated carboxylic acids and aliphatic polyhydric alcohol compounds, amides of unsaturated carboxylic acids and an aliphatic polyvalent amine compounds, and multimers thereof are included. Further, addition reaction products of unsaturated carboxylic esters or amides having nucleophilic substituents such as a hydroxyl group, an amino group, and a mercapto group with monofunctional or polyfunctional isocyanates or epoxies; dehydration condensation reaction products with monofunctional or polyfunctional carboxylic acids; or the like is also suitably used. In addition, reaction products of unsaturated carboxylic esters or amides having electrophilic substituents such as an isocyanate group and an epoxy group with monofunctional or polyfunctional alcohols, amines, or thiols; reaction products of unsaturated carboxylates or amides having dissociating substituents such as a halogen group and a tosyloxy group with monofunctional or polyfunctional alcohols, amines, or thiols; or the like is also suitably used. In addition, a compound group substituted with a vinyl benzene derivative such as unsaturated phosphoric acid and styrene, vinyl ether, allyl ether, or the like instead of the unsaturated carboxylic acids can also be used.

As the specific examples of these compounds, the compounds described in paragraph Nos. [0095] to [0108] of JP2009-288705A can also be suitably used in the present invention.

In the present invention, as the polymerizable compound, a compound having a boiling point of 100° C. or higher at normal pressure, which has one or more groups having an ethylenically unsaturated bond, is also preferable. With regard to examples thereof, reference can be made to the compounds described in paragraph 0227 of JP2013-29760A and the compounds described in paragraph Nos. 0254 to 0257 of JP2008-292970A, the contents of which are incorporated herein by reference.

As the polymerizable compound, dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd., A-DPH-12E manufactured by Shin-Nakamura Chemical Co., Ltd.), a structure (for example, SR454 and SR499, commercially available from Sartomer Company, Inc.) in which an ethylene glycol or propylene glycol residue is interposed between these (meth)acryloyl groups is preferable. Oligomer types of these can also be used. In addition, NK ESTER A-TMMT (pentaerythritol tetraacrylate, manufactured by Shin-Nakamura Chemical Co., Ltd.), KAYARAD RP-1040 (manufactured by Nippon Kayaku Co., Ltd.), or the like can also be used.

Preferred aspects of the polymerizable compound will be shown below.

The polymerizable compound may have an acid group such as a carboxyl group, a sulfonic acid group, and a phosphoric acid group. The polymerizable compound having an acid group is preferably an ester of an aliphatic polyhydroxy compound with an unsaturated carboxylic acid, and more preferably a polymerizable compound in which a non-aromatic carboxylic acid anhydride is reacted with an unreacted hydroxyl group of the aliphatic polyhydroxy compound to make an acid group bonded thereto. Particularly preferably in this ester, the aliphatic polyhydroxy compound is pentaerythritol and/or dipentaerythritol. Examples of the commercially available product thereof include ARONIX TO-2349, M-305, M-510, and M-520, manufactured by TOAGOSEI, CO., LTD.

The acid value of the polymerizable compound having an acid group is preferably 0.1 to 40 mgKOH/g, and particularly preferably 5 to 30 mgKOH/g. In a case where the acid value of the polymerizable compound is 0.1 mgKOH/g or more, the development and dissolution characteristics are good, whereas in a case where the acid value is 40 mgKOH/g or less, it is advantageous in production and/or handling. In addition, the photopolymerization performance is good and the curability is excellent.

It is also a preferred aspect that the polymerizable compound is a compound having a caprolactone structure.

The compound having a caprolactone structure is not particularly limited as long as it has a caprolactone structure in a molecule thereof, and examples thereof include ε-caprolactone-modified polyfunctional (meth)acrylates which are obtained by esterifying polyhydric alcohols such as trimethylolethane, ditrimethylolethane, trimethylolpropane, ditrimethylolpropane, pentaerythritol, dipentaerythritol, tripentaerythritol, glycerin, diglycerol, and trimethylolmelamine with (meth)acrylic acid and ε-caprolactone. Among those, a compound having a caprolactone structure represented by General Formula (Z-1) is preferable.

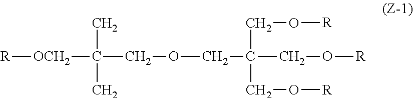

In General Formula (Z-1), all of six R's are a group represented by General Formula (Z-2). Alternatively, one to five out of six R's are a group represented by General Formula (Z-2), and the remainder is a group represented by General Formula (Z-3).

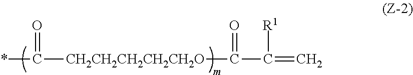

In General Formula (Z-2), R¹ represents a hydrogen atom or a methyl group, m represents a number 1 or 2, and “*” represents a binding arm.

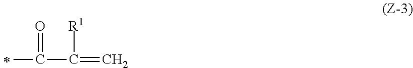

In General Formula (Z-3), R¹ represents a hydrogen atom or a methyl group, and “*” represents a binding arm.)

The polymerizable compound having a caprolactone structure is commercially available as a KAYARAD DPCA series from Nippon Kayaku Co., Ltd., and examples thereof include DPCA-20 (a compound in which m is 1, the number of the groups represented by Formula (Z-2) is 2, and all of R¹'s are hydrogen atoms in Formulae (Z-1) to (Z-3)), DPCA-30 (a compound in which m is 1, the number of the groups represented by Formula (Z-2) is 3, and all of R¹'s are hydrogen atoms in Formulae (Z-1) to (Z-3)), DPCA-60 (a compound in which m is 1, the number of the groups represented by Formula (Z-2) is 6, and all of R¹'s are hydrogen atoms in Formulae (Z-1) to (Z-3)), and DPCA-120 (a compound in which m is 2, the number of the groups represented by Formula (Z-2) is 6, and all of R¹'s are hydrogen atoms in Formulae (Z-1) to (Z-3)).

As the polymerizable compound, a compound represented by General Formula (Z-4) or (Z-5) can also be used.

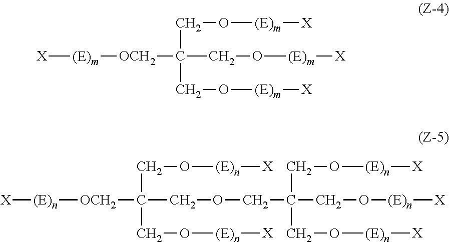

In General Formulae (Z-4) and (Z-5), E's each independently represent —((CH₂)_{y}CH₂O)— or —((CH₂)_{y}CH(CH₃)O)—, y's each independently represent an integer of 0 to 10, and X's each independently represent a (meth)acryloyl group, a hydrogen atom, or a carboxyl group.

In General Formula (Z-4), the sum of the (meth)acryloyl groups is 3 or 4, m's each independently represent an integer of 0 to 10, and the sum of the respective m's is an integer of 0 to 40.

In General Formula (Z-5), the sum of the (meth)acryloyl groups is 5 or 6, n's each independently represent an integer of 0 to 10, and the sum of the respective n's is an integer of 0 to 60.

In General Formula (Z-4), m is preferably an integer of 0 to 6, and more preferably an integer of 0 to 4.

Furthermore, the sum of the respective m's is preferably an integer of 2 to 40, more preferably an integer of 2 to 16, and particularly preferably an integer of 4 to 8.

In General Formula (Z-5), n is preferably an integer of 0 to 6, and more preferably an integer of 0 to 4.

Furthermore, the sum of the respective n's is preferably an integer of 3 to 60, more preferably an integer of 3 to 24, and particularly preferably an integer of 6 to 12.

In addition, —((CH₂)_{y}CH₂O)— or —((CH₂)_{y}CH(CH₃)O)— in General Formula (Z-4) or (Z-5) is preferably in the form in which the terminal at an oxygen atom side binds to X.

The compound represented by General Formula (Z-4) or (Z-5) may be used singly or in combination of two or more kinds thereof. In particular, a form in which all of six X's in General Formula (Z-5) are an acryloyl group, and an aspect of a mixture of a compound in which in General Formula (Z-5), all of six X's are an acryloyl group and a compound in which at least one of six X's is a hydrogen atom is preferable. By adopting such a configuration, developability can be more improved.

Moreover, the total content of the compound represented by General Formula (Z-4) or (Z-5) in the polymerizable compound is preferably 20% by mass or more, and more preferably 50% by mass or more.

The compound represented by General Formula (Z-4) or (Z-5) can be synthesized by steps known in the related art, which includes a step of bonding ethylene oxide or propylene oxide to pentaerythritol or dipentaerythritol by a ring-opening addition reaction to form a ring-opening skeleton, and a step of reacting, for example, (meth)acryloyl chloride to a terminal hydroxyl group of the ring-opening skeleton to introduce a (meth)acryloyl group. Since the respective steps are well-known, a person skilled in the art can easily synthesize the compound represented by General Formula (Z-4) or (Z-5).

Among the compounds represented by General Formula (Z-4) or (Z-5), a pentaerythritol derivative and/or a dipentaerythritol derivative is/are more preferable.

Specific examples of the compounds include compounds represented by Formulae (a) to (f) (hereinafter also referred to as “exemplary compounds (a) to (f)”). Among those, the exemplary compounds (a), (b), (e), and (f) are preferable.

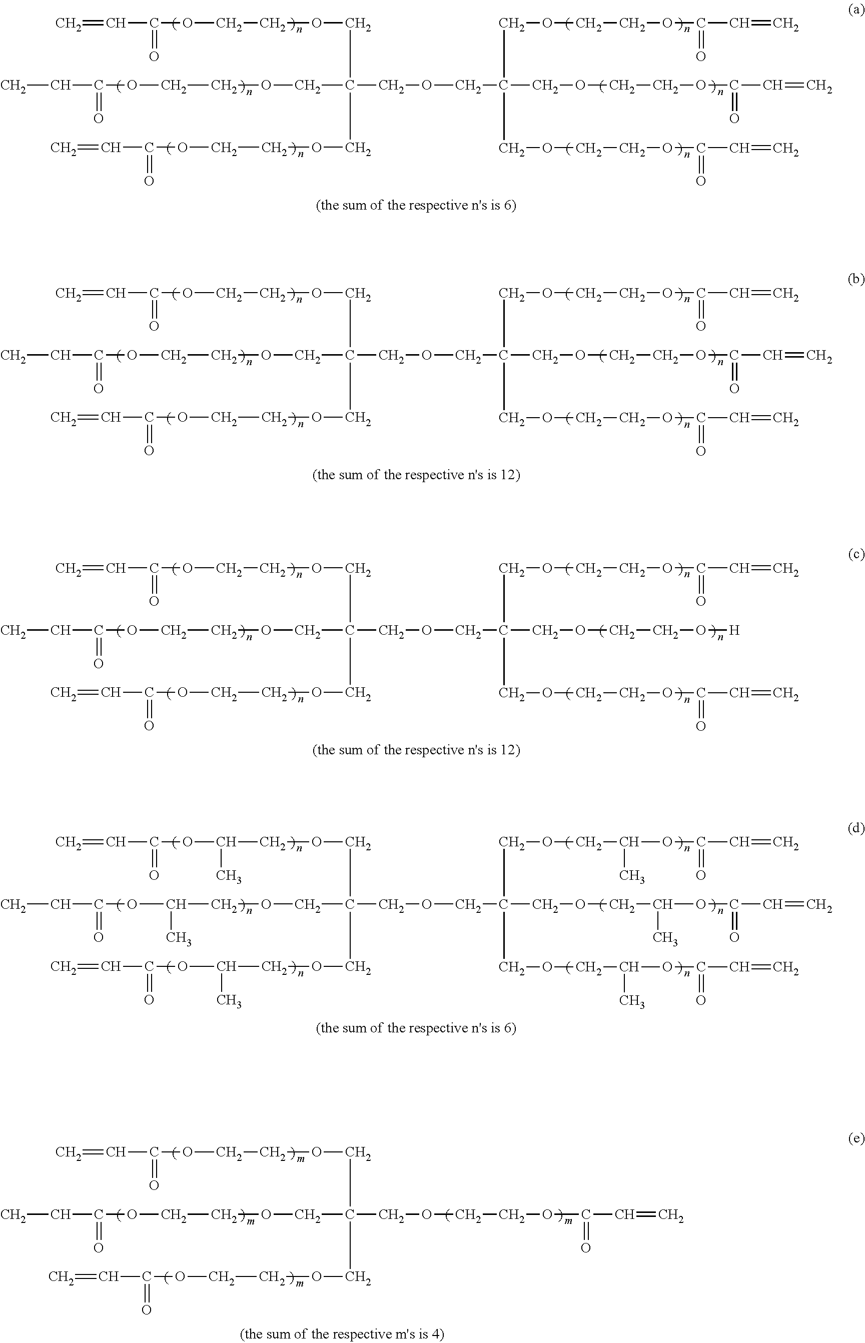

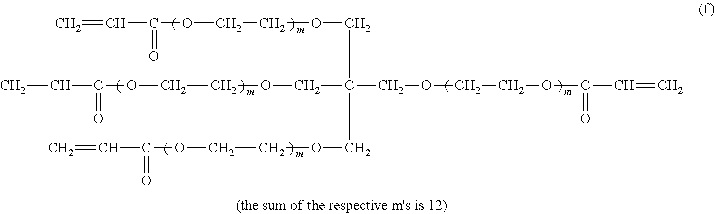

Examples of the commercially available product of the polymerizable compound represented by General Formula (Z-4) or (Z-5) include SR-494 which is a tetrafunctional acrylate having four ethyleneoxy chains, manufactured by Sartomer, and DPCA-60 which is a hexafunctional acrylate having six pentyleneoxy chains, and TPA-330 which is a trifunctional acrylate having three isobutyleneoxy chains, manufactured by Nippon Kayaku Co., Ltd.

As polymerizable compounds, the urethane acrylates described in JP1973-41708B (JP-S48-41708B), JP1976-37193A (JP-S51-37193A), JP1990-32293B (JP-H02-32293B), and JP1990-16765B (JP-H02-16765B) or urethane compounds having an ethylene oxide-based skeleton described in JP1983-49860B (JP-S58-49860B), JP1981-17654B (JP-S56-17654B), JP1987-39417B (JP-S62-39417B), and JP1987-39418B (JP-S62-39418B) are also suitable. In addition, by using addition-polymerizable compounds, which have an amino structure or a sulfide structure in a molecule and are described in JP1988-277653A (JP-S63-277653A), JP1988-260909A (JP-563-260909A), and JP1989-105238A (JP-H01-105238A), as the polymerizable compounds, a coloring composition which is extremely excellent in a photosensitization speed can be obtained.

Examples of commercially available products thereof include urethane oligomers UAS-10 and UAB-140 (manufactured by Sanyo-Kokusaku Pulp, Co., Ltd.), UA-7200 (manufactured by SHIN-NAKAMURA CHEMICAL CO., LTD.), DPHA-40H (manufactured by Nippon Kayaku Co., Ltd.), and UA-306H, UA-306T, UA-3061, AH-600, T-600, and AI-600 (manufactured by KYOEISHA CHEMICAL CO., LTD.).

Furthermore, the SP (solubility parameter) value of the polymerizable compound used in the present invention is, for example, 9.50 or more, preferably 10.40 or more, and more preferably 10.60 or more.

In addition, in the present specification, the SP value is determined in accordance with a Hoy method unless otherwise specified (H. L. HoyJournal of Painting, 1970, Vol. 42, 76-118). Further, the SP value is shown with the unit thereof omitted, and the unit is cal^{1/2} cm^{-3/2}.

The content of the polymerizable compound in the coloring composition of the present invention is preferably 0.1% to 40% by mass with respect to the total solid content of the coloring composition. The lower limit is, for example, more preferably 0.5% by mass or more, and still more preferably 1% by mass or more. The upper limit is, for example, more preferably 30% by mass or less, and still more preferably 20% by mass or less. The polymerizable compound may be used singly or in combination of two or more kinds thereof. In a case where the polymerizable compound is used in combination of two or more kinds thereof, the total amount thereof preferably falls within the above range.

Moreover, in the coloring composition of the present invention, the mass ratio (B/M) of the alkali-soluble resin (B) which will be described later to the polymerizable compound (M) is preferably 0.3 to 3.0, and from the viewpoint of superior solvent resistance, moisture resistance, and adhesiveness, it is more preferably 0.5 to 2.5.

[Photopolymerization Initiator]

The coloring composition of the present invention contains a photopolymerization initiator. The photopolymerization initiator used in the present invention has an absorbance at a wavelength of 340 nm of 0.45 or more, in the form of a solution in which the photopolymerization initiator is dissolved in acetonitrile at 0.001% by mass. Thus, the coloring composition of the present invention can be cured in a low-temperature environment.

The absorbance is preferably 0.48 or more, and more preferably 0.50 or more. The upper limit is not particularly limited, but is, for example, 2.0 or less.

In addition, in the present invention, the absorbance is measured using a spectrophotometer of an ultraviolet-visible-near-infrared spectrophotometer (U-4100, manufactured by Hitachi High-Technologies Corporation).

The photopolymerization initiator used in the present invention is not particularly limited as long as it is a photopolymerization initiator satisfying the absorbance, but suitable examples thereof include a compound represented by Formula (I) or a compound represented by Formula (J).

In addition, a geometric isomer which is a substituted form of a double bond in Formula (I) or (II) may be either an E isomer or a Z isomer, or a mixture thereof unless other specifically described even in a case where one of the isomers is described for the convenience of representation.

<Compound Represented by Formula (I)>

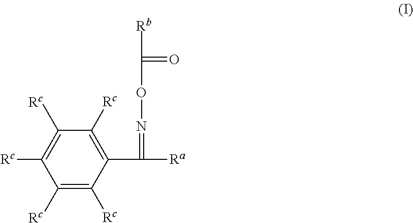

Formula (I), R^{a} represents n alkyl group, an acyl group, an aryl group, or a heterocyclic group, R^{b} represents an alkyl group, an aryl group, or a heterocyclic group, a plurality of R^{c}'s each independently represent a hydrogen atom, an alkyl group, or a group represented by —OR^{h}. R^{h} represents an electron-withdrawing group or an alkyl ether group, provided that at least one of the plurality of R^{c}'s represents a group represented by —OR^{h}.

Formula (I), R^{a} represents an alkyl group, an acyl group, an aryl group, or a heterocyclic group, and is preferably an aryl group or a heterocyclic group, and more preferably a heterocyclic group.

The number of carbon atoms in the alkyl group is preferably 1 to 20, more preferably 1 to 15, still more preferably 1 to 10, and particularly preferably 1 to 4. The alkyl group may be in any one of linear, branched, and cyclic forms, and is preferably linear or branched.

The number of carbon atoms in the acyl group is preferably 2 to 20, and more preferably 2 to 15. Examples of the acyl group include an acetyl group and a benzoyl group.

The number of carbon atoms in the aryl group is preferably 6 to 20, more preferably 6 to 15, and still more preferably 6 to 10. The aryl group may be a monocycle or a fused ring.

The heterocyclic group is preferably a 5- or 6-membered ring. heterocyclic group may be a monocycle or a fused ring. The number of fusions is preferably 2 to 8, more preferably 2 to 6, still more preferably 3 to 5, and particularly preferably 3 or 4. The number of carbon atoms constituting the heterocyclic group is preferably 3 to 40, more preferably 3 to 30, and still more preferably 3 to 20. The number of heteroatoms constituting the heterocyclic group is preferably 1 to 3. The heteroatom constituting the heterocyclic group is preferably a nitrogen atom, an oxygen atom, or a sulfur atom, and more preferably a nitrogen atom.

The above-mentioned group represented by R^{a} may be unsubstituted or may have a substituent. Examples of the substituent include an alkyl group, an aryl group, a heterocyclic group, a nitro group, a cyano group, a halogen atom, —OR^{X1}, —SR^{X1}, —COR^{X1}, —COOR^{X1}, —OCOR^{X1}, —NR^{X1}R^{X2}, —NHCOR^{X1}, —CONR^{X1}R^{X2}, —NHCONR^{X1}R^{X2}, —NHCOOR^{X1}, —SO₂R^{X1}, —SO₂OR^{X1}, and —NHSO₂R^{X1}. R^{X1} and R^{X2} each independently represent a hydrogen atom, an alkyl group, an aryl group, or a heterocyclic group.

Examples of the halogen atom include a fluorine atom, a chlorine atom, a bromine atom, and an iodine atom, and the halogen atom is preferably a fluorine atom.

The number of carbon atoms of the alkyl group as the substituent, and the alkyl group represented by R^{X1} and R^{X2} is preferably 1 to 20. The alkyl group may be in any one of linear, branched, and cyclic forms, and is preferably linear or branched. A part or all of the hydrogen atoms of the alkyl group may be substituted with halogen atoms (preferably fluorine atoms). Further, a part or all of the hydrogen atoms of the alkyl group may be substituted with the substituents.

The number of carbon atoms of the aryl group as the substituent, and the aryl group represented by R^{X1} and R^{X2} is preferably 6 to 20, more preferably 6 to 15, and still more preferably 6 to 10. The aryl group may be a monocycle or a fused ring. Further, a part or all of the hydrogen atoms of the aryl group may be substituted with the substituents.

The heterocyclic group as the substituent, and the heterocyclic group represented by R^{X1} and R^{X2} are preferably a 5- or 6-membered ring. The heterocyclic group may be a monocycle or a fused ring. The number of carbon atoms constituting the heterocyclic group is preferably 3 to 30, more preferably 3 to 18, and still more preferably 3 to 12. The number of heteroatoms constituting the heterocyclic group is preferably 1 to 3. The heteroatom constituting the heterocyclic group is preferably a nitrogen atom, an oxygen atom, or a sulfur atom. Further, a part or all of the hydrogen atoms of the hetero group may be substituted with the substituents.

The heterocyclic group represented by R^{a} is preferably a group represented by Formula (II).

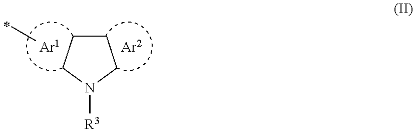

In Formula (II), Ar¹ and Ar² each independently represent an aromatic hydrocarbon ring which may have a substituent, R³ represents an alkyl group or an aryl group, and * represents a binding position.

In Formula (II), Ar¹ and Ar² each independently represent an aromatic hydrocarbon ring which may have a substituent.

The aromatic hydrocarbon ring may be a monocycle or a fused ring. The number of carbon atoms constituting the ring of the aromatic hydrocarbon ring is preferably 6 to 20, more preferably 6 to 15, and particularly preferably 6 to 10. The aromatic hydrocarbon ring is preferably a benzene ring or a naphthalene ring. Among those, at least one of Ar¹ or Ar² is preferably a benzene ring, and Ar¹ is more preferably a benzene ring. Ar¹ is preferably a benzene ring or a naphthalene ring, and Ar¹ is more preferably a naphthalene ring.

Examples of the substituent which may be contained in the Ar¹ and Ar² include the substituents described in R^{a}.

It is preferable that Ar¹ is unsubstituted. Ar¹ may be unsubstituted or may have a substituent. The substituent is preferably —COR^{X1}. R^{X1} is preferably an alkyl group, an aryl group, or a heterocyclic group, and more preferably an aryl group. The aryl group may have a substituent or may be unsubstituted. Examples of the substituent include having an alkyl group having 1 to 10 carbon atoms.

In Formula (II), R³ represents an alkyl group or an aryl group, and is preferably an alkyl group. The alkyl group and the aryl group may be unsubstituted and may have a substituent. Examples of the substituent include the substituents for R^{a} described above.

The number of carbon atoms in the alkyl group is preferably 1 to 20, more preferably 1 to 15, and still more preferably 1 to 10. The alkyl group may be in any one of linear, branched, and cyclic forms, but is preferably linear or branched.

The number of carbon atoms of the aryl group is preferably 6 to 20, more preferably 6 to 15, and still more preferably 6 to 10. The aryl group may be a monocycle or a fused ring.

In Formula (I), R^{b} represents an alkyl group, an aryl group, or a heterocyclic group, and is preferably an alkyl group or an aryl group, and more preferably an alkyl group. The alkyl group, the aryl group, and the heterocyclic group have the same definitions as the groups described for R^{a}. These groups may be unsubstituted and may have a substituent. Examples of the substituent include the substituents described for R^{a}.

Formula (I), a plurality of R^{c}'s each independently represent a hydrogen atom, an alkyl group, or a group represented by —OR^{h}. R^{h} represents an electron-withdrawing group or an alkyl ether group, provided that at least one of the plurality of R^{c}'s represents a group represented by —OR^{h}.

The number of carbon atoms in the alkyl group represented by R^{c} is preferably 1 to 20, more preferably 1 to 15, still more preferably 1 to 10, and particularly preferably 1 to 4. The alkyl group may be in any one of linear, branched, and cyclic forms, and is preferably linear or branched.

Examples of the electron-withdrawing group represented by R^{h} in —OR^{h} include a nitro group, a cyano group, a fluorine atom, an alkyl group having 1 to 20 carbon atoms, in which at least one hydrogen atom is substituted with a fluorine atom.

Among these, an alkyl group having 1 to 20 carbon atoms, in which at least one hydrogen atom is substituted with a fluorine atom is preferable. The number of carbon atoms in the alkyl group is preferably 1 to 15, more preferably 1 to 10, and still more preferably 1 to 4, and the alkyl group may be in any one of linear, branched, and cyclic forms, and is preferably linear or branched.

The alkyl ether group represented by R^{h} in —OR^{h} means an alkyl group substituted with an alkoxy group. The number of carbon atoms in the alkyl group in the alkyl ether group and the alkoxy group in the alkyl ether group is preferably 1 to 20, more preferably 1 to 15, still more preferably 1 to 10, and particularly preferably 1 to 4. The alkyl group may be in any one of linear, branched, and cyclic forms, and is preferably linear or branched.

The total number of carbon atoms in the alkyl ether group is preferably 2 to 8, more preferably 2 to 6, and still more preferably 2 to 4.

It is preferable that one or two of a plurality of R^{c}'s are groups represented by —OR^{h}. Here, in a case where R^{h} in —OR^{h} is an electron-withdrawing group (for example, an alkyl group having 1 to 20 carbon atoms, in which at least one hydrogen atom is substituted with a fluorine atom), it is preferable that the rest of R^{c}'s are hydrogen atoms. On the other hand, in a case where R^{h} in —OR^{h} is an alkyl ether group, it is preferable that one of the rest of R^{c}'s is an alkyl group and the others are hydrogen atoms.

In addition, in a benzene ring to which R^{c} is bonded, it is preferable that the alkyl group represented by R^{c} or the group represented by —OR^{h} is positioned on the ortho-position or para-position with respect to one carbon to which R^{c} is not bonded.

Specific examples of the photopolymerization initiator represented by Formula (I) include the following compounds.

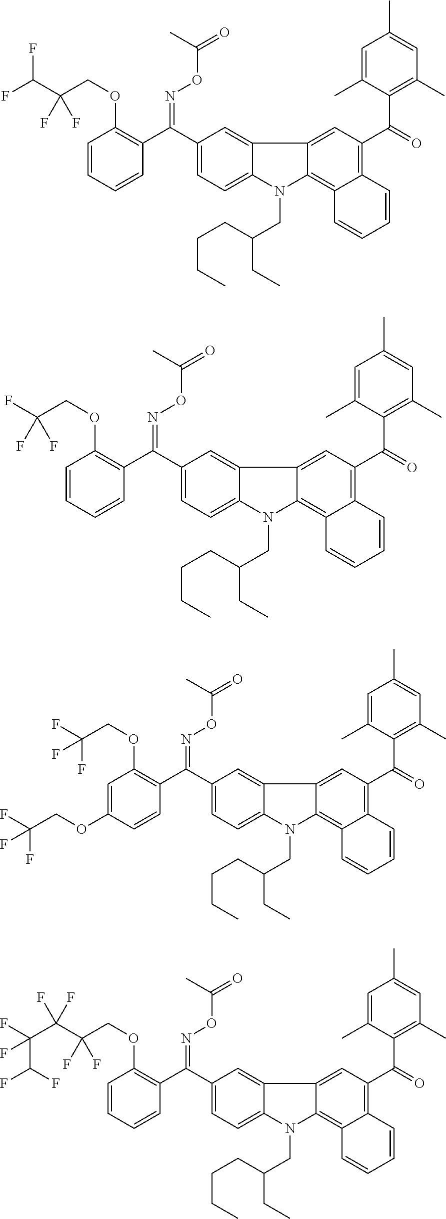 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CCCCC(CC)Cn1c2ccc(/C(=N\OC(C)=O)c3ccccc3OCC(F)(F)F)cc2c2cc(C(=O)c3c(C)cc(C)cc3C)c3ccccc3c21 ; CCCCC(CC)Cn1c2ccc(/C(=N\OC(C)=O)c3ccc(OCC(F)(F)F)cc3OCC(F)(F)F)cc2c2cc(C(=O)c3c(C)cc(C)cc3C)c3ccccc3c21 ; CCCCC(CC)Cn1c2ccc(/C(=N\OC(C)=O)c3ccccc3OCC(F)(F)C(F)(F)C(F)(F)C(F)F)cc2c2cc(C(=O)c3c(C)cc(C)cc3C)c3ccccc3c21]

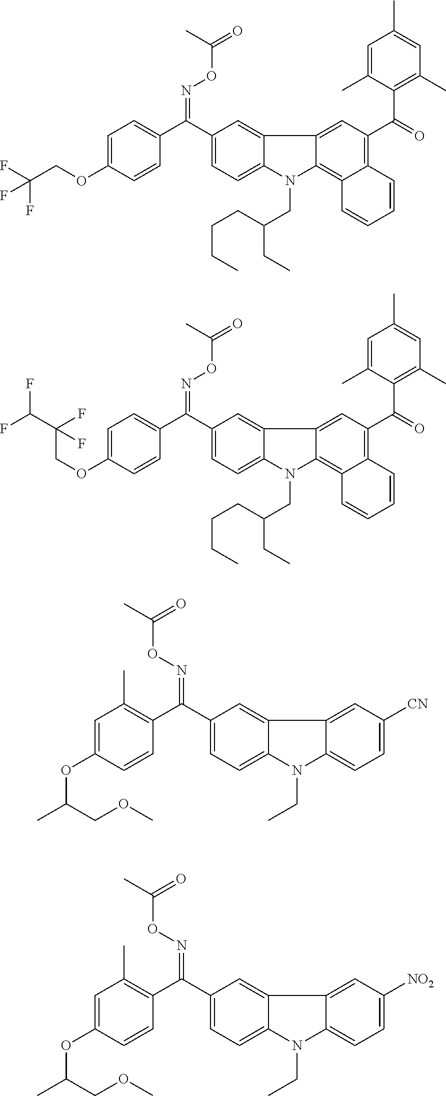

<Compound Represented by Formula (J)>

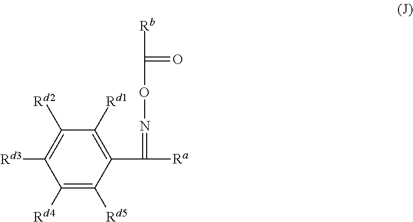

In Formula (J),

R^{a} represents an alkyl group, an acyl group, an aryl group, or a heterocyclic group,

R^{b} represents an alkyl group, an aryl group, or a heterocyclic group,

R^{d1} to R^{d5} each independently represent a hydrogen atom, an alkyl group, or a group represented by —SRⁱ. Rⁱ represents an electron-withdrawing group, an alkyl ether group, a group having a benzofuran skeleton, or a group having a benzothiophene skeleton.

However, at least any one of R^{d1} to R^{d5} represents a group represented by —SRⁱ.

R^{a} in Formula (J) has the same definition as R^{a} in Formula (I) described above.

R^{b} in Formula (J) has the same definition as R^{b} in Formula (I) described above.

The alkyl group represented by each of R^{d1} to R^{d5} in Formula (J) have the same definitions as the alkyl group represented by R^{c} in Formula (I) described above.

The electron-withdrawing group and the alkyl ether group represented by Rⁱ in —SRⁱ represented by each of R^{d1} to R^{d5} in Formula (J) have the same definitions as the electron-withdrawing group and the alkyl ether group represented by R^{h} in —OR^{h} represented by R^{c} in Formula (I).

Suitable examples of the group having a benzofuran skeleton and the group having a benzothiophene skeleton represented by Rⁱ in —SRⁱ represented by each of R^{d1} to R^{d5} in Formula (J) include a group represented by Formula (k).

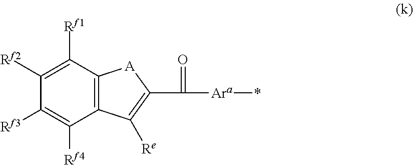

In Formula (k),

Ar^{a} represents a divalent aromatic ring group,

A represents an oxygen atom or a sulfur atom,

R^{e} represents a hydrogen atom or a monovalent organic group,

R^{f1} to R^{f4} each independently represent a hydrogen atom or a monovalent organic group, and

* represents a binding position.

Examples of the divalent aromatic ring group represented by Ar^{a} in Formula (k) include an arylene group having 6 to 20 carbon atoms, such as a phenylene group and a naphthylene group, each of which may have a substituent, and the divalent aromatic ring group is preferably a group represented by Formula (m).

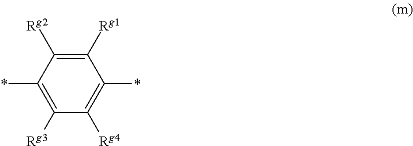

R^{g1} to R^{g4} in Formula (m) each independently represent a hydrogen atom or a monovalent organic group (for example, an alkyl group having 1 to 4 carbon atoms). * represents a binding position.

R^{g1} and R^{g4} in Formula (m) may be linked to R^{d1} to R^{d5} in Formula (J) to form a ring.

That is, R^{d1} to R^{d5} in Formula (J) described above may be linked to R^{g1} and R^{g4} in Formula (m) to form a ring.

Formula (k) will be hereinafter further described.

Examples of the monovalent organic group represented by R^{e} in Formula (k) include an alkyl group. The number of carbon atoms in the alkyl group is preferably 1 to 20, more preferably 1 to 15, still more preferably 1 to 10, and particularly preferably 1 to 4. The alkyl group may be in any one of linear, branched, and cyclic forms, and is preferably linear or branched.

R^{e} in Formula (k) is preferably a hydrogen atom or an alkyl group having 1 to 4 carbon atoms.

Examples of the monovalent organic group represented by R^{f1} to R^{f4} in Formula (k) include an alkyl group and an alkenyl group. The number of carbon atoms in each of the alkyl group and the alkenyl group is preferably 1 to 20, more preferably 1 to 15, still more preferably 1 to 10, and particularly preferably 1 to 4. The alkyl group and the alkenyl group may be in any one of linear, branched, and cyclic forms, and is preferably linear or branched.

R^{f1} to R^{f4} may be linked to the adjacent member to form a ring such as a benzene ring.

R^{f1} and R^{f2} are each preferably a hydrogen atom.

It is preferable that R^{f3} and R^{f4} are each a hydrogen atom or are linked to each other to form a benzene ring.

As one of the suitable aspects of Formula (J) described above, an aspect in which R^{d3} of R^{d1} to R^{d5} is a group represented by —SRⁱ is preferable.

Furthermore, Rⁱ in —SRⁱ is preferably a group having a benzofuran skeleton or a group having a benzothiophene skeleton, and more preferably a group represented by Formula (k).

Here, Ar^{a} in Formula (k) is preferably a group represented by Formula (m).

Here, it is preferable that R^{g1} to R^{g4} in Formula (m) are both hydrogen atoms, or R^{g1} is linked to R^{d2} in Formula (J) to form a ring.

Specific examples of the photopolymerization initiator represented by Formula (J) include the following compounds.

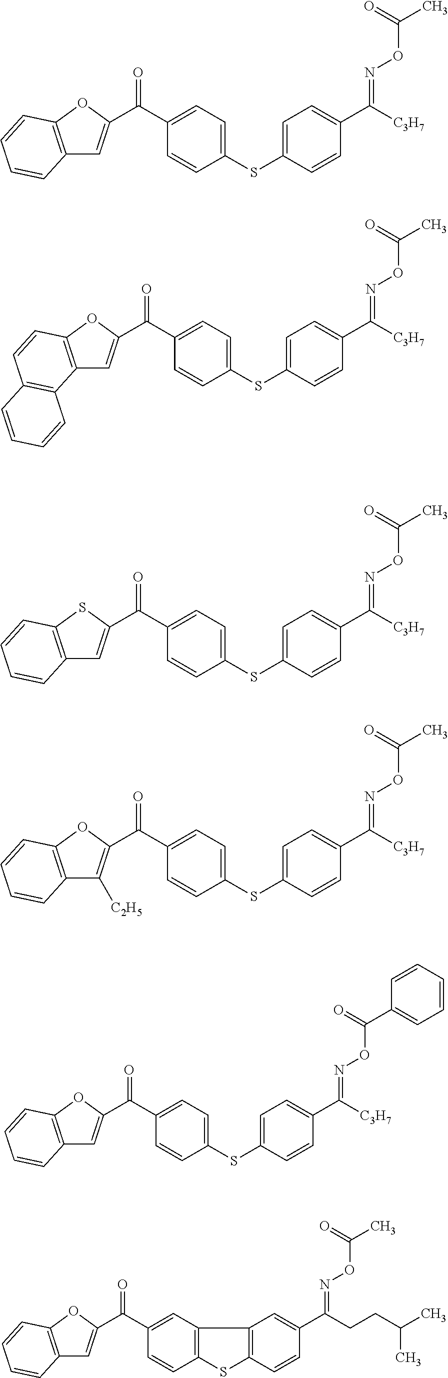

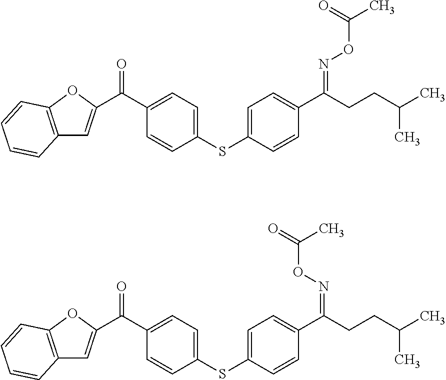 [SMILES: CC(=O)O/N=C(\CCC(C)C)c1ccc(Sc2ccc(C(=O)c3cc4ccccc4o3)cc2)cc1 ; CC(=O)O/N=C(/CCC(C)C)c1ccc(Sc2ccc(C(=O)c3cc4ccccc4o3)cc2)cc1]

In the present invention, an oxime compound having a benzofuran skeleton can also be used as the photopolymerization initiator. Specific examples thereof include a solution having an absorbance of 0.45 or more at a wavelength of 340 nm, in which 0.001% by mass of each of OE-01 to OE-75 described in WO2015/036910A is dissolved in acetonitrile.

A commercially available product thereof is not particularly limited, but examples thereof include IRGACURE-OXE03 (manufactured by BASF) and ADEKA ARKLS NCI-831 (manufactured by ADEKA Corporation).

The content of the photopolymerization initiator is preferably 0.1% to 30% by mass, more preferably 0.5% to 20% by mass, still more preferably 1% to 10% by mass, and particularly preferably 1% to 5% by mass, with respect to the total solid content of the coloring composition.

The coloring composition of the present invention may include one kind or two or more kinds of photopolymerization initiator. In a case where the composition includes two or more kinds of the photopolymerization initiator, the total amount thereof preferably falls within the above range.

[Resin]

The coloring composition of the present invention preferably includes a resin. The resin is blended in applications, such as an application for dispersing a coloring agent in the composition or an application as a binder. Incidentally, a resin which is usually used for dispersing a coloring agent is also referred to as a dispersant. However, such uses of the resin are only exemplary, and the resin can also be used for other purposes, in addition to the above uses.

The weight-average molecular weight (Mw) of the resin is preferably 2,000 to 2,000,000. The upper limit is preferably 1,000,000 or less, and more preferably 500,000 or less, and the lower limit is preferably 3,000 or more, and more preferably 5,000 or more.

The content of the resin in the coloring composition of the present invention is preferably 10% to 80% by mass, and more preferably 20% to 60% by mass, with respect to the total solid content of the coloring composition. The coloring composition of the present invention may include one kind or two or more kinds of the resin. In a case where two or more kinds of the resin are included, the total amount thereof preferably falls within the above range.

For a reason that the effect of the present invention is superior, the resin the coloring composition of the present invention has an acid value of preferably 50.0 mgKOH/g or less, and more preferably 31.5 mgKOH/g or less. The lower limit is not particularly limited, but is more preferably, for example, 5.0 mgKOH/g or more.

These resins are each preferably an alkali-soluble resin as will be described later.

The acid value is given by measuring the amount (mg) of an aqueous potassium hydroxide solution to be required for neutralization of a compound. A resin having a desired acid value can be obtained by adjusting the number of acid groups contained in monomers, the molecular weight of the monomers, the compositional ratio of the monomers, or the like to control the number of the acid groups contained in the resin.

<Dispersant>

The coloring composition of the present invention can contain a dispersant as a resin.

The dispersant preferably includes one or more selected from an acidic resin, a basic resin, and an amphoteric resin.

In the present invention, the acidic resin means a resin having an acid group, which has an acid value of 5 mgKOH/g or more and an amine value of less than 5 mgKOH/g. It is preferable that the acidic resin does not have a basic group.

Examples of the acid group contained in an acidic resin include a carboxyl group, a phosphoric acid group, a sulfonic acid group, and a phenolic hydroxyl group, with the carboxyl group being preferable.

As the acidic resin, any one of a block copolymer, a random copolymer, and a graft copolymer can also be used.

The acid value of the acidic resin is preferably 5 to 200 mgKOH/g, more preferably 10 to 150 mgKOH/g, and still more preferably 50 to 150 mgKOH/g.

In the present invention, the basic resin means a resin having a basic group, which has an amine value of 5 mgKOH/g or more and an acid value of less than 5 mgKOH/g. It is preferable that the basic resin does not have an acid group.

The basic group having a basic resin is preferably an amino group. As the basic resin, any one of a block copolymer, a random copolymer, and a graft copolymer can also be used.

The amine value of the basic resin is preferably 5 to 200 mgKOH/g, more preferably 5 to 150 mgKOH/g, and still more preferably 5 to 100 mgKOH/g.

In the present invention, the amphoteric resin means a resin having an acid group and a basic group, which has an acid value of 5 mgKOH/g or more and an amine value of 5 mgKOH/g or more. Examples of the acid group include the groups described above, with the carboxyl group being preferable. As the basic group, an amino group is preferable. As the amphoteric resin, any one of a block copolymer, a random copolymer, and a graft copolymer can also be used.

It is preferable that the amphoteric resin has an acid value of 5 mgKOH/g or more and an amine value of 5 mgKOH/g or more. The acid value is preferably 5 to 200 mgKOH/g, more preferably 10 to 200 mgKOH/g, still more preferably 30 to 200 mgKOH/g, and particularly preferably 30 to 180 mgKOH/g. The amine value is preferably 5 to 200 mgKOH/g, more preferably 10 to 150 mgKOH/g, and particularly preferably 10 to 130 mgKOH/g.

The ratio of the acid value to the amine value of the amphoteric resin is as follows: the acid value:amine value is preferably 1:3 to 3:1, and more preferably 1:2 to 2:1. In a case where the ratio of the acid value to the amine value falls within the range, both of the dispersibility of the coloring agent and the developability can be accomplished more effectively.

In a case of using the acidic resin, the basic resin, and the amphoteric resin in combination, it is preferable that the content of the basic resin is 10 to 150 parts by mass and the content of the amphoteric resin is 30 to 170 parts by mass, with respect to 100 parts by mass of the acidic resin. The content of the basic resin is more preferably 30 to 130 parts by mass, and still more preferably 50 to 110 parts by mass. The content of the amphoteric resin is more preferably 50 to 150 parts by mass, and still more preferably 90 to 150 parts by mass. According to this aspect, the above-mentioned effect is obtained more effectively. Further, the acidic resin is contained in the amount of preferably 1% to 30% by mass, and more preferably 1% to 20% by mass, with respect to the total solid content of the coloring composition. Further, the basic resin is contained in the amount of preferably 1% to 30% by mass, and more preferably 1% to 20% by mass, with respect to the total solid content of the coloring composition. In addition, the amphoteric resin is contained in the amount of preferably 1% to 30% by mass, and more preferably 1% to 20% by mass, with respect to the total solid content of the coloring composition.

The resin is also available as a commercially available product, and specific examples thereof include “DA-7301” manufactured by Kusumoto Chemicals, Ltd., “Disperbyk-101 (polyamidamine phosphate), 107 (carboxylic acid ester), 110 (copolymer including an acid group), 111 (phosphoric acid-based dispersant), 130 (polyamide), 161, 162, 163, 164, 165, 166, 170, and 190 (polymeric copolymers)”, and “BYK-P104 and P105 (high-molecular-weight unsaturated polycarboxylic acid) manufactured by BYK-Chemie, “EFKA 4047, 4050 to 4010 to 4165 (polyurethane-based), EFKA 4330 to 4340 (block copolymer), 4400 to 4402 (modified polyacrylate), 5010 (polyesteramide), 5765 (high-molecular-weight polycarboxylate), 6220 (aliphatic polyester), 6745 (phthalocyanine derivative), and 6750 (azo pigment derivative)” manufactured by EFKA, “AJISPER PB821, PB822, PB880, and PB881” manufactured by Ajinomoto Fine-Techno Co., Inc., “FLOWLEN TG-710 (urethane oligomer)” and “POLYFLOW No. 50E, No. 300 (acrylic copolymer)” manufactured by KYOEISHA CHEMICAL Co., LTD., “DISPARLON KS-860, 873 SN, 874, and #2150 (aliphatic polyvalent carboxylic acid), #7004 (polyether ester), DA-703-50, DA-705, and DA-725” manufactured by Kusumoto Chemicals, Ltd., “DEMOL RN and N (naphthalene sulfonate formaldehyde condensate), MS, C, and SN-B (aromatic sulfonate formaldehyde condensate)”, “HOMOGENOL L-18 (polymeric polycarboxylic acid)”, “EMULGEN 920, 930, 935, and 985 (polyoxyethylene nonyl phenyl ether)”, and “ACETAMINE 86 (stearylamine acetate)” manufactured by Kao Corporation, “SOLSPERSE 5000 (phthalocyanine derivative), 22000 (azo pigment derivative), 13240 (polyesteramine), 3000, 12000, 17000, 20000, and 27000 (polymers having a functional portion in the terminal portion), and 24000, 28000, 32000, and 38500 (graft polymers)” manufactured by The Lubrizol Corporation, “NIKKOL T106 (polyoxyethylene sorbitan monooleate) and MYS-IEX (polyoxyethylene monostearate)” manufactured by NIKKO CHEMICALS Co., Ltd., “HINOACT T-8000E” and the like manufactured by Kawaken Fine Chemicals Co., Ltd., “Organosiloxane Polymer KP341” manufactured by Shin-Etsu Chemical Co., Ltd., “W001: Cationic Surfactant” manufactured by Yusho Co., Ltd., non-ionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan aliphatic acid ester, and anionic surfactants such as “W004, W005, and W017”, “EFKA-46, EFKA-47, EFKA-47EA, EFKA POLYMER 100, EFKA POLYMER 400, EFKA POLYMER 401, and EFKA POLYMER 450” manufactured by MORISHITA SANGYO Corporation, polymer dispersants such as “DISPERSE AID 6, DISPERSE AID 8, DISPERSE AID 15, and DISPERSE AID 9100” manufactured by SAN NOPCO Ltd., “ADEKA PLURONIC L31, F38, L42, L44, L61, L64, F68, L72, P95, F77, P84, F87, P94, L101, P103, F108, L121, and P-123” manufactured by ADEKA CORPORATION, and “IONET (trade name) S-20” manufactured by Sanyo Chemical Industries, Ltd. Further, In addition, Acryl-Based FFS-6752, Acryl-Based FFS-187, ACRYCURE RD-F8, or CYCLOMER P can also be used.

In addition, examples of the commercially available product of the amphoteric resin include DISPERBYK-130, DISPERBYK-140, DISPERBYK-142, DISPERBYK-145, DISPERBYK-180, DISPERBYK-187, DISPERBYK-191, DISPERBYK-2001, DISPERBYK-2010, DISPERBYK-2012, DISPERBYK-2025, and BYK-9076 manufactured by BYK-Chemie, and AJISPUR PB821, AJISPUR PB822, and AJISPUR PB881 manufactured by Ajinomoto Fine Techno Co., Inc.

The resin used as the dispersant preferably includes a repeating unit having an acid group. By incorporating the repeating unit having an acid group into the resin, residues generated in the underlying substrate of colored pixels in a case where a colored pattern is formed by photolithography can further be reduced.

The repeating unit having an acid group can be configured with a monomer having an acid group. Examples of the monomer derived from an acid group include a vinyl monomer having a carboxyl group, a vinyl monomer having a sulfonic acid group, and a vinyl monomer having a phosphoric acid group.

Examples of the vinyl monomer having a carboxyl group include (meth)acrylic acid, vinyl benzoic acid, maleic acid, monoalkyl maleic ester, fumaric acid, itaconic acid, crotonic acid, cinnamic acid, and an acrylic acid dimer. Further, an addition reaction products of a monomer having a hydroxyl group, such as 2-hydroxyethyl (meth)acrylate, with a cyclic anhydride such as maleic anhydride, phthalic anhydride, succinic anhydride, and cyclohexane dicarboxylic anhydride; ω-carboxy-polycaprolactone mono(meth)acrylate; or the like can also be used. Incidentally, as a precursor of a carboxyl group, an anhydride-containing monomer such as maleic anhydride, itaconic anhydride, and citraconic anhydride may also be used. Among those, from the viewpoint of properties of removing the unexposed area by development, addition reaction products of a monomer having a hydroxyl group, such as 2-hydroxyethyl (meth)acrylate, with a cyclic anhydride such as maleic anhydride, phthalic anhydride, succinic anhydride, and cyclohexane dicarboxylic anhydride are preferable.

Examples of the vinyl monomer having a sulfonic acid group include 2-acrylamide-2-methylpropanesulfonic acid.

Examples of the vinyl monomer having a phosphoric acid group include phosphoric mono(2-acryloyloxyethylester) and phosphoric mono(1-methyl-2-acryloyloxyethylester).

In addition, with regard to the repeating unit having an acid group, reference can be made to the descriptions in paragraph Nos. 0067 to 0069 in JP2008-165059A, the contents of which are incorporated herein by reference.

Moreover, it is also preferable that the resin used as the dispersant is a graft copolymer. Since the graft copolymer has affinity to a solvent by a graft chain, the dispersibility of the coloring agent and the temporal dispersion stability are excellent. Further, since the composition has affinity to a polymerizable compound or an alkali-soluble resin due the presence of the presence of the graft chain, it can be difficult for residues to be generated by alkali development.

In addition, in the present invention, the graft copolymer means a resin having a graft chain. Further, the graft chain represents from an origin of the main chain of the polymer to the terminal of a group branched from the main chain.

In the present invention, a resin having a graft chain in the number of atoms excluding hydrogen atoms in the range of 40 to 10,000 is preferable as the graft copolymer.

Furthermore, the number of atoms excluding hydrogen atoms per graft chain is preferably 40 to 10,000, more preferably 50 to 2,000, and still more preferably 60 to 500.

Examples of the main chain structure of the graft copolymer include a (meth)acryl resin, a polyester resin, a polyurethane resin, a polyurea resin, a polyamide resin, and a polyether resin. Among those, the (meth)acryl resin is preferable.

As the graft chain of the graft copolymer, a graft chain having poly(meth)acryl, polyester, or polyether is preferable, and a graft chain having polyester or polyether is more preferable, for the purpose of improving the interaction between the graft site and the solvent, and thus, increasing the dispersibility.

The graft copolymer includes a repeating unit having a graft chain, preferably in the range of 2% to 90% by mass, and more preferably in the range of 5% to 30% by mass, in terms of mass, with respect to the total mass of the graft copolymer. In a case where the content of the repeating unit having a graft chain falls within the range, the dispersibility of the coloring agent is good.

As the macromonomer used in the production of a graft copolymer by radical polymerization, known macromonomers can be used, and examples thereof include macromonomers AA-6 (polymethyl methacrylate having a methacryloyl group as a terminal group), AS-6 (polystyrene having a methacryloyl group as a terminal group), AN-6S (a copolymer of styrene and acrylonitrile that has a methacryloyl group as a terminal group), and AB-6 (polybutyl acrylate having a methacryloyl group as a terminal group) manufactured by TOAGOSEI, CO., LTD.; PLACCEL FM5 (a product obtained by adding 5 molar equivalents of c-caprolactone to 2-hydroxyethyl methacrylate) and FA10L (a product obtained by adding 10 molar equivalents of ε-caprolactone to 2-hydroxyethyl acrylate) manufactured by DAICEL CORPORATION; and a polyester-based macromonomer described in JP1990-272009A (JP-H02-272009A).

In the present invention, an oligoimine-based graft copolymer containing a nitrogen atom in at least one of the main chain or the side chain can also be preferably used as the graft copolymer.

As the oligoimine-based graft copolymer, a resin having a side chain including a repeating unit having a partial structure X having a functional group with a pKₐ of 14 or less and an oligomer chain or polymer chain Y having 40 to 10,000 atoms, and having a basic nitrogen atom in at least one of the main chain or the side chain is preferable.

Here, the basic nitrogen atom is not particularly limited as long as it is a nitrogen atom exhibiting basicity. The oligoimine-based graft copolymer preferably contains a structure having a nitrogen atom with a basic strength pK_{b} of 14 or less, and more preferably contains a structure having a nitrogen atom with a pK_{b} of 10 or less.

In the present invention, the basic strength pK_{b} refers to a pK_{b} at a water temperature of 25° C., is one of the indices to quantitatively represent the intensity of a base, and has the same definition as the basicity constant. The basic strength pK_{b} and the acid strength pKₐ which will be described later are in a relationship of pK_{b}=14−pKₐ.

It is particularly preferable that the oligoimine-based graft copolymer has a repeating unit (i) which is at least one repeating unit having a basic nitrogen atom, selected from a poly(lower alkylenimine)-based repeating unit, a polyallylamine-based repeating unit, a polydiallylamine-based repeating unit, a methaxylenediamine-epichlorohydrin polycondensate-based repeating unit, and a polyvinylamine-based repeating unit, and has a partial structure X having a functional group with a pKₐ of 14 or less while being bonded to the basic nitrogen atom, and a side chain (ii) including an oligomer chain or polymer chain Y having 40 to 10,000 atoms.

Examples of the oligoimine-based graft copolymer include a resin including a repeating unit represented by General Formula (I-1) and a repeating unit represented by General Formula (I-2).

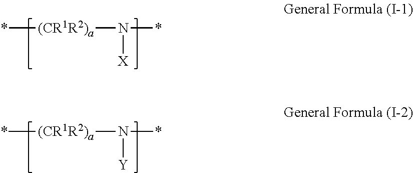

In General Formulae (I-1) and (I-2), R¹ and R² each independently represent a hydrogen atom, a halogen atom, or an alkyl group, a's each independently represent an integer of 1 to 5, * represents a linking moiety with between the repeating units, X represents a group having a functional group with a pKₐ of 14 or less, and Y represents an oligomer chain or polymer chain having 40 to 10,000 atoms.

The oligoimine-based graft copolymer preferably further includes a repeating unit represented by General Formula (I-3). According to this aspect, the dispersion stability of pigment forms are further improved.

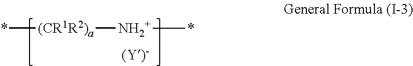

In General Formula (I-3), R¹, R², and a have the same definitions as R¹, R², and a, respectively, in General Formula (I-1). Y′ represents an oligomer chain or polymer chain having 40 to 10,000 atoms, containing an anion group. The repeating unit represented by General Formula (I-3) can be formed by causing a reaction by adding an oligomer or polymer having a group forming a salt by reacting with an amine to a resin having a primary or secondary amino group in the main chain moiety.

In General Formulae (I-1), (I-2), and (I-3), R¹ and R² are preferably a hydrogen atom. a is preferably 2 from the viewpoint of availability of raw materials.

The oligoimine-based graft copolymer may include a lower alkylenimine which contains a primary or tertiary amino group as a repeating unit, in addition to the repeating units represented by General Formulae (I-1), (I-2), and (I-3). Further, a group represented by X, Y, or Y′ may be bonded to a nitrogen atom in the lower alkylenimine repeating unit.

The repeating unit represented by General Formula (I-1) is contained in the proportion of preferably 1% to 80% by mole, and most preferably 3% to 50% by mole, in all the repeating units included in the oligoimine-based graft copolymer.

The repeating unit represented by General Formula (I-2) is contained in the proportion of preferably 10% to 90% by mole, and most preferably 30% to 70% by mole, in all the repeating units included in the oligoimine-based graft copolymer.

From the viewpoints of the dispersion stability and a balance between the hydrophobicity and the hydrophilicity, the content ratio [(I-1):(I-2)] of the repeating unit (I-1) and the repeating unit (I-2) is preferably in the range of 10:1 to 1:100, and more preferably in the range of 1:1 to 1:10, in terms of a molar ratio.

Furthermore, the repeating unit represented by General Formula (I-3), which is used in combination as desired, is a repeating unit in which a partial structure including an oligomer chain or polymer chain Y′ having 40 to 10,000 atoms is ionically bonded to a nitrogen atom in the main chain, and from the viewpoint of the effects, the repeating unit is preferably contained in the proportion of 0.5% to 20% by mole, and most preferably contained in the proportion of 1% to 10% by mole, in all the repeating units included in the oligoimine-based graft copolymer. Further, it is possible to confirm that the polymer chain Y′ is ionically bonded by means of infrared spectroscopy or base titration.

(Partial Structure X Having Functional Group with pKₐ 14 or Less)

The partial structure X has a functional group with a pKₐ of 14 or less at a water temperature of 25° C. The definition of “pKₐ” as mentioned herein is described in the Chemical Manual (II) (Revision 4^{th} edition, 1993, Chemical Society of Japan, Maruzen Co., Ltd.).

The “functional group with a pKₐ of 14 or less” is not particularly limited in terms of the structure or the like as long as the physical properties thereof satisfy these conditions, and examples thereof include a known functional group where the pKₐ satisfies the range; however, a functional group with a pKₐ of 12 or less is particularly preferable, and a functional group with a pKₐ of 11 or less is most preferable. Specific examples of the partial structure X include a carboxylic acid group (pKₐ: approximately 3 to 5), a sulfonic acid group (pKₐ: approximately −3 to −2), —COCH₂CO— (pKₐ: approximately 8 to 10), —COCH₂CN (pKₐ: approximately 8 to 11), —CONHCO—, a phenolic hydroxyl group, —R_{F}CH₂OH, or —(RF)₂CHOH (R_{F} represents a perfluoroalkyl group, pKₐ: approximately 9 to 11), and a sulfonamido group (pKₐ: approximately 9 to 11), and a carboxylic acid group (pKₐ: approximately 3 to 5), and a sulfonic acid group (pKₐ: approximately −3 to −2) and —COCH₂CO— (pKₐ: approximately 8 to 10) are particularly preferable.

The partial structure X is preferably directly bonded to a basic nitrogen atom. The basic nitrogen atom and the partial structure X may be linked to each other in an aspect where a salt is formed by a covalent bond as well an ionic bond.

In particular, the partial structure X preferably has a structure represented by General Formula (V-1), (V-2), or (V-3)

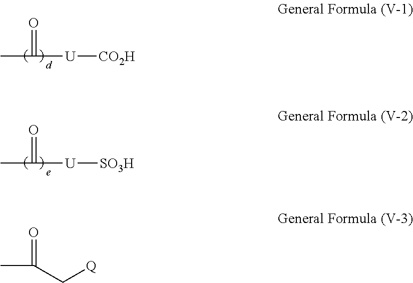

In General Formulae (V-1) and (V-2), U represents a single bond or a divalent linking group. d and e each independently represent 0 or 1. In General Formula (V-3), Q represents an acyl group or an alkoxycarbonyl group.

Examples of a divalent linking group represented by U include an alkylene group, an arylene group, and an alkyleneoxy group, each of which may have an oxygen atom. The divalent linking group is particularly preferably an alkylene group having 1 to 30 carbon atoms or an arylene group having 6 to 20 carbon atoms; and most preferably an alkylene group having 1 to 20 carbon atoms or an arylene group having 6 to 15 carbon atoms. In addition, from the viewpoint of productivity, d is preferably 1 and e is preferably 0.

Q represents an acyl group or an alkoxycarbonyl group. The acyl group in Q is preferably an acyl group having 1 to 30 carbon atoms, and particularly preferably acetyl. As the alkoxycarbonyl group in Q, Q is preferably an acetyl group from the viewpoint of the ease of production and the availability of the raw materials (a precursor X′ of X).

(Oligomer Chain or Polymer Chain Y Having Number of Atoms of 40 to 10,000)

Examples of the oligomer chain or polymer chain Y having the number of atoms of 40 to 10,000 include known polymer chains such as a polyester, a polyamide, a polyimide, and poly(meth)acrylic acid ester, which can be linked to the main chain portion of the oligoimine-based graft copolymer. The binding site in Y to the oligoimine-based graft copolymer is preferably the terminal of Y.

Y is preferably bonded to a basic nitrogen atom. The bonding mode between the basic nitrogen atom and Y is a covalent bond, an ionic bond, or a mixture of a covalent bond and an ionic bond. The ratio of the bonding mode between the basic nitrogen atom and Y, covalent bonds:ionic bonds, is preferably 100:0 to 0:100, more preferably 95:5 to 5:95, and most preferably 90:10 to 10:90. Y is preferably amide-bonded to the basic nitrogen atom, or ionically bonded as a carboxylic acid salt.

From the viewpoints of dispersibility, dispersion stability, and developability, the number of atoms of the oligomer chain or polymer chain Y is preferably 50 to 5,000, and more preferably 60 to 3,000.

The number-average molecular weight of Y can be measured as a value in terms of polystyrene by a GPC method. The number-average molecular weight of Y is particularly preferably 1,000 to 50,000, and from the viewpoints of dispersibility, dispersion stability, and developability, it is most preferably 1,000 to 30,000.

The side chain structure represented by Y is preferably linked to the chain in the main chain at 2 or more sites, and most preferably at 5 or more sites in one molecule of the resin.

With regard to the details of Y, reference can be made to the description in paragraph Nos. 0086 to 0098 of JP2013-064979A, the contents of which are incorporated herein by reference.

The above-mentioned oligoimine-based graft copolymer can be synthesized by the method described in paragraph Nos. 0110 to 0117 of JP2013-064979A.

Specific examples of the above-mentioned oligoimine-based graft copolymer include the following copolymers, and also include the resins described in paragraph Nos. 0099 to 0109, and 0119 to 0124 of JP2013-064979A, the contents of which are incorporated herein by reference.

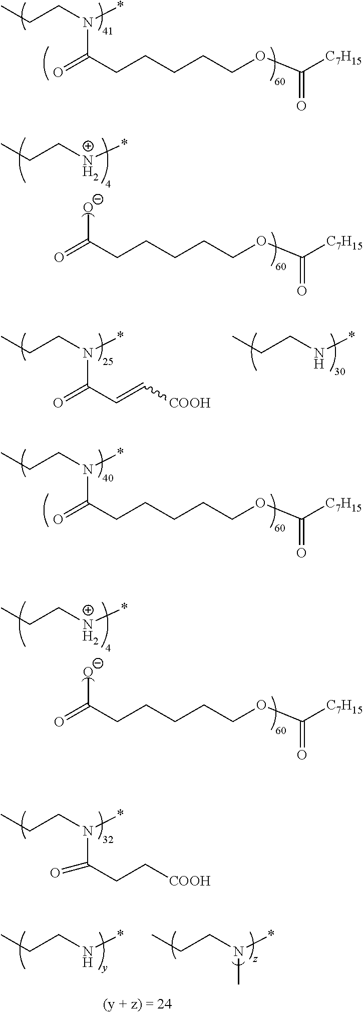

In the present invention, a copolymer including a repeating unit represented by any one of Formulae (1) to (4) can also be used as the graft copolymer. The graft copolymer can be particularly preferably used as a dispersant for a black pigment.

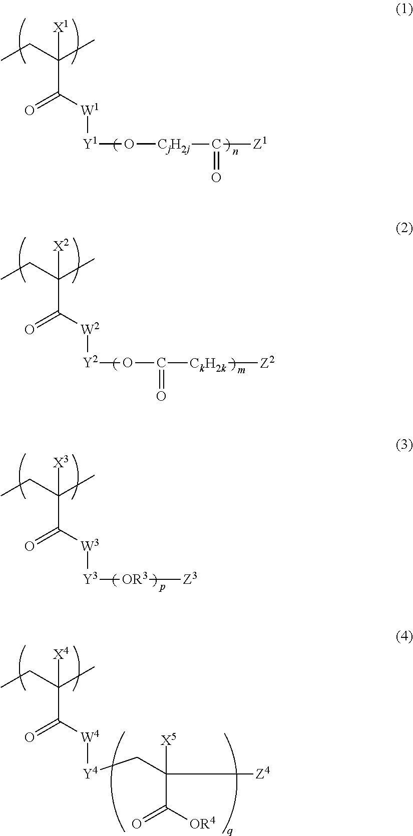

In Formulae (1) to (4), W¹, W², W³, and W⁴ each independently represent an oxygen atom or NH. W¹, W², W³, and W⁴ are preferably each an oxygen atom.

In Formulae (1) to (4), X¹, X², X³, X⁴, and X⁵ each independently represent a hydrogen atom or a monovalent organic group. From the viewpoint of synthesis, it is preferable that X¹, X², X³, X⁴, and X⁵ each independently represent a hydrogen atom or an alkyl group having 1 to 12 carbon atoms. It is more preferable that X¹, X², X³, X⁴, and X⁵ each independently represent a hydrogen atom or a methyl group, with the methyl group being particularly preferable.

In Formulae (1) to (4), Y¹, Y², Y³, and Y⁴ each independently represent a divalent linking group, and the linking group is not particularly limited from the viewpoint of its structure. Specific examples of the divalent linking groups represented by Y¹, Y², Y³, and Y⁴ include linking groups represented by (Y-1) to (Y-21). In the structures shown below, A and B means binding sites to a left terminal group and a right terminal group, respectively, in Formulae (1) to (4).

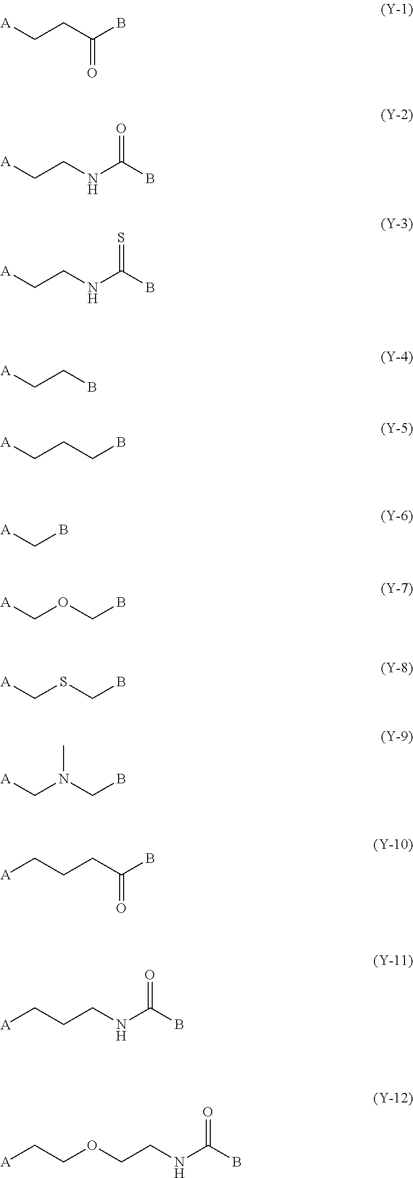

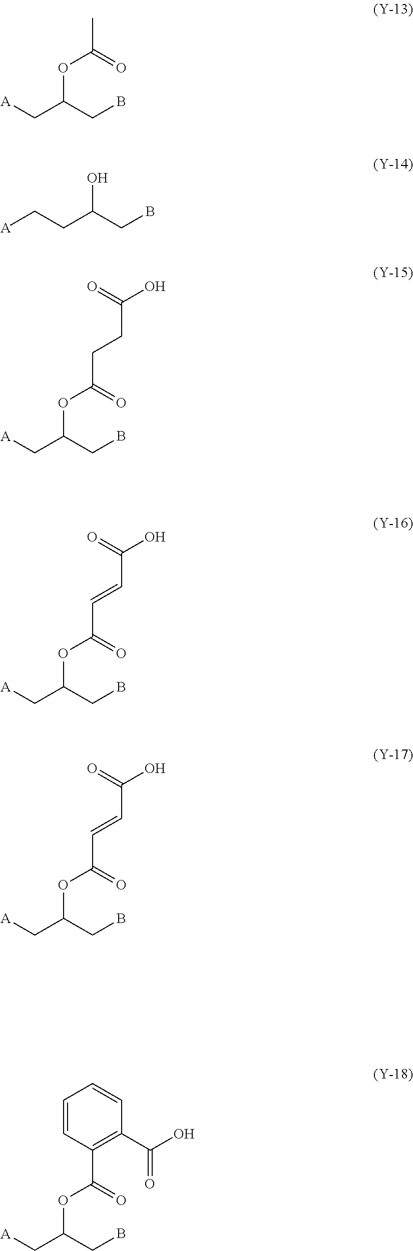

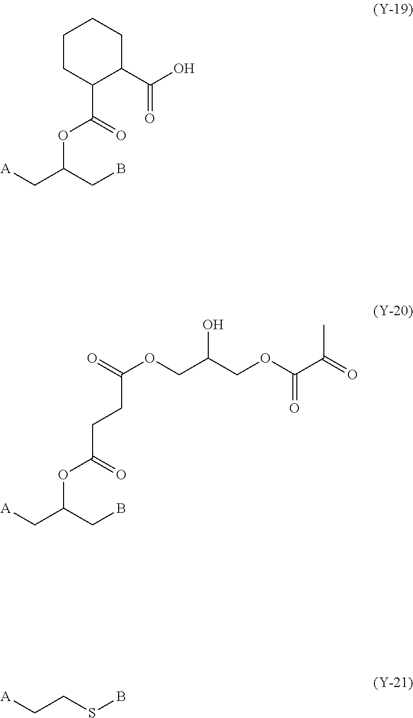

In Formulae (1) to (4), Z¹, Z², Z³, and Z⁴ each independently represent a monovalent organic group. The structure of the organic group is not particularly limited. Specific examples of the organic groups include an alkyl group, a hydroxyl group, an alkoxy group, an aryloxy group, heteroaryloxy group, an alkylthioether group, an arylthioether group, a heteroarylthioether group, and an amino group. Among those, ones having the steric repulsion effect are preferable as the organic groups represented by Z¹, Z², Z³, and Z⁴, in particular from the viewpoint of improving the dispersibility. Among those, it is particularly preferable that Z¹, Z², Z³, and Z⁴ each independently represent an alkyl group or an alkoxy group having 5 to 24 carbon atoms. It is particularly preferable that Z¹, Z², Z³, and Z⁴ each independently represent a branched alkyl group having 5 to 24 carbon atoms, a cyclic alkyl group having 5 to 24 carbon atoms, and an alkoxy group having 5 to 24 carbon atoms. In addition, the alkyl group contained in the alkoxy group may be in any one of linear, branched, and cyclic forms.

In Formulae (1) to (4), n, m, p, and q are each independently an integer of 1 to 500.

Furthermore, in Formulae (1) and (2), j and k each independently represent an integer of 2 to 8. j and k in Formulae (1) and (2) are preferably an integer of 4 to 6, and most preferably 5, from the viewpoints of dispersion stability and developability.

In Formula (3), R³ represents a branched or linear alkylene group, and is preferably an alkylene group having 1 to 10 carbon atoms, and more preferably an alkylene group having 2 or 3 carbon atoms. In a case where p is 2 to 500, R³ which are present in plural numbers may be the same as or different from each other.

In Formula (4), R⁴ represents a hydrogen atom or a monovalent organic group, and the monovalent organic group is not particularly limited in terms of its structure. R⁴ is preferably a hydrogen atom, an alkyl group, an aryl group, or a heteroaryl group, and more preferably a hydrogen atom or an alkyl group. In a case where R⁴ is an alkyl group, as the alkyl group, a linear alkyl group having 1 to 20 carbon atoms, a branched alkyl group having 3 to 20 carbon atoms, or a cyclic alkyl group having 5 to 20 carbon atoms is preferable, a linear alkyl group having 1 to 20 carbon atoms is more preferable, and a linear alkyl group having 1 to 6 carbon atoms is particularly preferable. In Formula (4), in a case where q is 2 to 500, X⁵ and R⁴ which are present in plural numbers in a graft copolymer may be the same as or different from each other.

As for the repeating unit represented by Formula (1), a repeating unit represented by Formula (1A) is more preferable from the viewpoints of dispersion stability and developability.

In addition, as the repeating unit represented by Formula (2), a repeating unit represented by Formula (2A) is more preferable from the viewpoint of dispersion stability and developability.

Moreover, as the repeating unit represented by Formula (3), a repeating unit represented by Formula (3A) or (3B) is more preferable from the viewpoint of dispersion stability and developability.

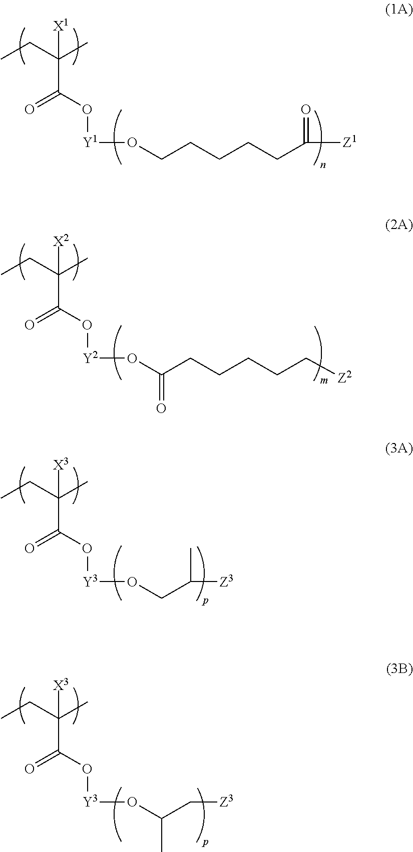

In Formula (1A), X¹, Y¹, Z¹, and n have the same definitions as X¹, Y¹, Z¹, and n, respectively, in formula (1), and preferred ranges thereof are also the same.

In Formula (2A), X², Y², Z², and m have the same definitions as X², Y², Z², and m, respectively, in Formula (2), and preferred ranges thereof are also the same.

In Formula (3A) or (3B), X³, Y³, Z³, and p have the same definitions as X³, Y³, Z³, and p, respectively, in Formula (3), and preferred ranges thereof are also the same.

Furthermore, it is also preferable that the above-mentioned graft copolymer has a hydrophobic repeating unit, in addition to the above-mentioned repeating units represented by Formula (1) to (4). Meanwhile, in the present invention, the hydrophobic repeating unit is a repeating unit having no acid group (for example, a carboxylic acid group, a sulfonic acid group, a phosphoric acid group, and a phenolic hydroxyl group).

The hydrophobic repeating unit is preferably a repeating unit which is derived from (corresponds to) a compound (monomer) having a C log P value of 1.2 or more, and more preferably a repeating unit derived from a compound having a C log P value of 1.2 to 8.

A C log P value is a value calculated using the program “C LOG P”, which is available from Daylight Chemical Information System, Inc. This program provides values of “calculated log P” calculated using Hansch and Leo's fragment approach (see documents below). The fragment approach is based on the chemical structure of a compound, and divides the chemical structure into partial structures (fragments) and sums the log P contribution allocated to each fragment. Thus the log P value of the compound is estimated. The details thereof are described in the following documents. In the present invention, the C log P values calculated by the program CLOGP v4.82 are used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990 C. Hansch & A. J. Leo. Substituent Constants For Correlation Analysis in Chemistry and Biology. John Wiley & Sons. A. J. Leo. Calculating log Poct from structure. Chem. Rev., 93, 1281-1306, 1993.

The log P means the common logarithm of a partition coefficient P. The log P is a value of a physical property, being a quantitative numeric value, representing how an organic compound is distributed in an equilibrium of the two-phase system of oil (typically 1-octanol) and water. The log P is expressed in the following expression.

log P=log(Coil/Cwater)

In the expression, Coil represents the molar concentration of the compound in the oil phase, and Cwater represents the molar concentration of the compound in the water phase.

Oil solubility increases as the value of log P crosses zero and increases in the positive direction and water solubility increases as an absolute value increases in the negative direction. The log P has a negative correlation with the water solubility of the organic compound and is widely used as a parameter for estimating the hydrophilicity or the hydrophobicity of an organic compound.

It is preferable that the graft copolymer has one or more repeating units selected from repeating units derived from monomers represented by General Formulae (i) to (iii) as the hydrophobic repeating unit.

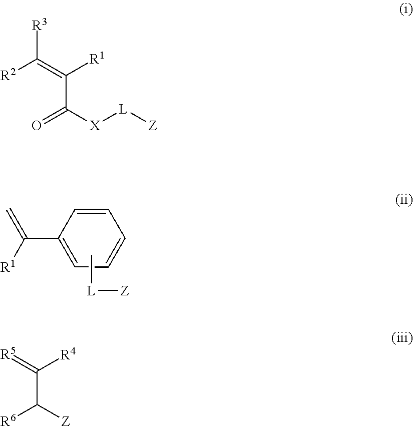

In Formulae (i) to (iii), R¹, R², and R³ each independently represent a hydrogen atom, a halogen atom (for example, fluorine, chlorine, and bromine), or an alkyl group having 1 to 6 carbon atoms (for example, a methyl group, an ethyl group, and a propyl group).

R¹, R², and R³ are each more preferably a hydrogen atom or an alkyl group having 1 to 3 carbon atoms, and most preferably a hydrogen atom or a methyl group. It is particularly preferable that R² and R³ are each a hydrogen atom.

X represents an oxygen atom (—O—) or an imino group (—NH—), and is preferably an oxygen atom.

L is a single bond or a divalent linking group. Examples of the divalent linking groups include a divalent aliphatic group (for example, an alkylene group, a substituted alkylene group, an alkenylene group, a substituted alkenylene group, an alkynylene group, and a substituted alkynylene group), a divalent aromatic group (for example, an arylene group and a substituted arylene group), a divalent heterocyclic group, an oxygen atom (—O—), a sulfur atom (—S—), an imino group (—NH—), a substituted imino group (—NR³¹—, in which R³¹ is an aliphatic group, an aromatic group, or a heterocyclic group), a carbonyl group (—CO—), and a combination thereof.

L is preferably a single bond or a divalent linking group including an alkylene group or an oxyalkylene structure. The oxyalkylene structure is more preferably an oxyethylene structure or an oxypropylene structure. Further, L may include a polyoxyalkylene structure including two or more repeating oxyalkylene structures. The polyoxyalkylene structure is preferably a polyoxyethylene structure or a polyoxypropylene structure. The polyoxyethylene structure is represented by —(OCH₂CH₂)ₙ—, and n is preferably an integer of 2 or more, and more preferably an integer of 2 to 10.

Examples of Z include an aliphatic group (for example, an alkyl group, a substituted alkyl group, an unsaturated alkyl group, and a substituted unsaturated alkyl group), an aromatic group (for example, an arylene group or a substituted arylene group), a heterocyclic group, an oxygen atom (—O—), a sulfur atom (—S—), an imino group (—NH—), a substituted imino group (—NR³¹— in which R³¹ represents an aliphatic group, an aromatic group, or a heterocyclic group), a carbonyl group (—CO—), and a combination thereof.

The aliphatic group may have a cyclic structure or a branched structure. The number of carbon atoms in the aliphatic group is preferably 1 to 20, more preferably 1 to 15, and still more preferably 1 to 10. Further, the aliphatic group includes a ring assembly hydrocarbon group or a crosslinked cyclic hydrocarbon ring. Examples of the ring assembly hydrocarbon groups include a bicyclohexyl group, a perhydronaphthalenyl group, a biphenyl group, and a 4-cyclohexyl phenyl group. Examples of the crosslinked cyclic hydrocarbon rings include a bicyclic hydrocarbon ring such as pinane, bornane, norpinane, norbornane, a bicyclooctane ring (a bicyclo[2.2.2]octane ring, a bicyclo[3.2.1]octane ring, and the like), a tricyclic hydrocarbon ring such as homobredane, adamantane, tricyclo[5.2.1.0^{2,6}]decane, and a tricyclo[4.3.1.1^{2,5}]undecane ring, and a tetracyclic hydrocarbon ring such as tetracyclic[4.4.0.1^{2,5}.1^{7,10}]dodecane and perhydro-1,4-methano-5,8-methanonaphthalene rings. In addition, the crosslinked cyclic hydrocarbon rings include fused cyclic hydrocarbon rings which are a plurality of fused rings of 5- to 8-membered cycloalkane rings such as perhydronaphthalene (decalin), perhydroanthracene, perhydrophenanthrene, perhydroacenaphthene, perhydrofluorene, perhydroindene, and perhydrophenalene rings. As the aliphatic group, a saturated aliphatic group is more preferable than an unsaturated aliphatic group. Further, the aliphatic group may have a substituent. Examples of the substituents include a halogen atom, an aromatic group, and a heterocyclic group. However, the aliphatic group has no acid group as the substituent.

The number of carbon atoms in the above-mentioned aromatic group is preferably 6 to 20, more preferably 6 to 15, and still more preferably 6 to 10. Further, the aromatic group may have a substituent. Examples of the substituents include a halogen atom, an aliphatic group, an aromatic group, and a heterocyclic group. However, the aromatic group has no acid group as the substituent.

The heterocyclic group preferably has a 5- or 6-membered ring as the heterocyclic ring. Another heterocyclic ring, aliphatic ring, or aromatic ring may be fused with the heterocyclic ring. The heterocyclic group may have a substituent. Examples of the substituents include a halogen atom, a hydroxyl group, an oxo group (═O), a thioxo group (═S), an imino group (═NH), a substituted imino group (═N—R³² in which R³² is an aliphatic group, an aromatic group, or a heterocyclic group), an aliphatic group, an aromatic group, and a heterocyclic group. However, the heterocyclic group has no acid group as the substituent.

In Formula (iii), R⁴, R⁵, and R⁶ each independently represent a hydrogen atom, a halogen atom (for example, fluorine, chlorine, and bromine), an alkyl group having 1 to 6 carbon atoms (for example, a methyl group, an ethyl group, and a propyl group), Z, or -L-Z. Here, L and Z have the same definitions as those defined above. As each of R⁴, R⁵, and R⁶, a hydrogen atom or an alkyl group having 1 to 3 carbon atoms is preferable, and a hydrogen atom is more preferable.

As the monomer represented by General Formula (i), a compound in which R¹, R², and R³ are each a hydrogen atom or a methyl group, L is a single bond, an alkylene group, or a divalent linking group including an oxyalkylene structure, X is an oxygen atom or an imino group, and Z is an aliphatic group, a heterocyclic group, or an aromatic group is preferable. As the monomer represented by General Formula (ii), a compound in which R¹ is a hydrogen atom or a methyl group, L is an alkylene group, and Z is an aliphatic group, a heterocyclic group, or an aromatic group is preferable. Further, as the monomer represented by General Formula (iii), a compound in which R⁴, R⁵, and R⁶ are each a hydrogen atom or a methyl group, and Z is an aliphatic group, a heterocyclic group, or an aromatic group is preferable.

Examples of the typical compounds represented by Formulae (i) to (iii) include radically polymerizable compounds selected from acrylic acid esters, methacrylic acid esters, and styrenes. In addition, with regard to the examples of the compounds represented by Formulae (i) to (iii), reference can be made to the compounds described in paragraphs 0089 to 0093 of JP2013-249417A, the contents of which are incorporated herein by reference.

In the graft copolymer, the hydrophobic repeating unit is preferably included in the amount in the range of 10% to 90% by mass, and more preferably included in the amount in the range of 20% to 80% by mass, in terms of mass, with respect to the total mass of the graft copolymer. In a case where the content is within the range, sufficient pattern formation is achieved.

It is preferable that the above-mentioned graft copolymer includes a repeating unit having a functional group capable of interacting with a coloring agent, in addition to the above-mentioned repeating units represented by Formulae (1) to (4).

Examples of the acid group include a carboxylic acid group, a sulfonic acid group, a phosphoric acid group, and a phenolic hydroxyl group. At least one of the carboxylic acid group, the sulfonic acid group, or the phosphoric acid group is preferable, and the carboxylic acid group is particularly preferable from the viewpoint that it has good adsorption force on the coloring agent such as a black pigment and high dispersibility.

The graft copolymer may have one kind or two or more kinds of repeating units having an acid group.

The graft copolymer may or may not contain a repeating unit having an acid group. In a case where the graft copolymer contains a repeating unit having an acid group, the content of the repeating unit having an acid group is preferably 5% to 80% by mass, and more preferably 10% to 60 by mass %, with respect to the total mass of the graft copolymer, in terms of mass.

Examples of the basic group include a primary amino group, a secondary amino group, a tertiary amino group, a heterocyclic ring containing an N atom, and an amido group. The tertiary amino group is particularly preferable from the viewpoint that it has good adsorption force on the coloring agent and high dispersibility. The graft copolymer may have one kind or two or more kinds of the basic groups.

The graft copolymer may or may not contain a repeating unit having a basic group. In a case where the graft copolymer contains the repeating unit having a basic group, the content of the repeating unit having a basic group, in terms of mass, with respect to the total mass of the graft copolymer, is preferably 0.01% to 50% by mass, and more preferably 0.01% to 30% by mass, from the viewpoint of suppressing the development inhibition.

Examples of the coordinating group and the reactive functional group include an acetylacetoxy group, a trialkoxysilyl group, an isocyanate group, an acid anhydride, and an acid chloride. The acetylacetoxy group is particularly preferable from the viewpoint that it has good adsorption force on the coloring agent and high dispersibility. The graft copolymer may have one kind or two or more kinds of the groups.

The graft copolymer may or may not contain a repeating unit having a coordinating group or a repeating unit having a reactive functional group. In a case where the graft copolymer contains the repeating unit having a coordinating group or the repeating unit having a reactive functional group, the content of the repeating unit, in terms of mass, with respect to the total mass of the graft copolymer, is preferably 10% to 80% by mass, and more preferably 20% to 60% by mass, from the viewpoint of suppressing the development inhibition.

In a case where the graft copolymer has a functional group capable of interacting with a coloring agent, in addition to the graft chain, it is not particularly limited how those functional groups are introduced, but the graft copolymer preferably has one or more repeating units selected from the repeating units derived from monomers represented by General Formulae (iv) to (vi).

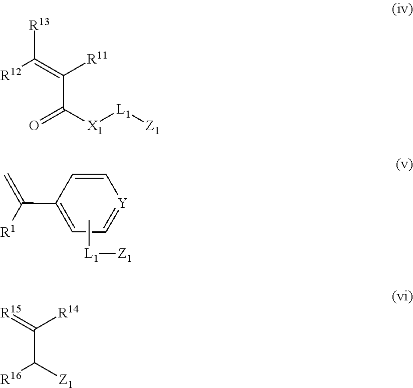

In General Formulae (iv) to (vi), R¹¹, R¹², and R¹³ each independently represent a hydrogen atom, a halogen atom (for example, a fluorine atom, a chlorine atom, and a bromine atom), or an alkyl group (for example, a methyl group, an ethyl group, and a propyl group) having 1 to 6 carbon atoms.

In General Formulae (iv) to (vi), it is more preferable that R¹¹, R¹², and R¹³ are each independently a hydrogen atom or an alkyl group having 1 to 3 carbon atoms, and it is most preferable that R¹¹, R¹², and R¹³ are each independently a hydrogen atom or a methyl group. In General Formula (iv), it is particularly preferable that R¹² and R¹³ are each a hydrogen atom.

In General Formula (iv), X₁ represents an oxygen atom (—O—) or an imino group (—NH—), and is preferably an oxygen atom.

Y in General Formula (v) represents a methine group or a nitrogen atom.

Moreover, in General Formulae (iv) to (v), L₁ represents a single bond or a divalent linking group. Examples of the divalent linking groups include a divalent aliphatic group (for example, an alkylene group, a substituted alkylene group, an alkenylene group, a substituted alkenylene group, an alkynylene group, and a substituted alkynylene group), a divalent aromatic group (for example, an arylene group and a substituted arylene group), a divalent heterocyclic group, an oxygen atom (—O—), a sulfur atom (—S—), an imino group (—NH—), a substituted imino bond (—NR³¹′— in which R³¹′ is an aliphatic group, an aromatic group, or a heterocyclic group), a carbonyl bond (—CO—), and a combination thereof.

It is preferable that L₁ is a single bond, an alkylene group, or a divalent linking group containing an oxyalkylene structure. It is more preferable that the oxyalkylene structure is an oxyethylene structure or an oxypropylene structure. Further, L₁ may include a polyoxyalkylene structure including two or more repeating oxyalkylene structures. As the polyoxyalkylene structure, a polyoxyethylene structure or a polyoxypropylene structure is preferable. The polyoxyethylene structure is represented by —(OCH₂CH₂)n- in which n is preferably an integer of 2 or more, and more preferably an integer of 2 to 10.

In General Formulae (iv) to (vi), Z₁ represents a functional group capable of interacting with the coloring agent, other than the graft chain, and is preferably a carboxylic acid group or a tertiary amino group, and more preferably a carboxylic acid group.

In General Formula (vi), R¹⁴, R¹⁵, and R¹⁶ each independently represents a hydrogen atom, a halogen atom (for example, fluorine, chlorine, and bromine), an alkyl group having 1 to 6 carbon atoms (for example, a methyl group, an ethyl group, and a propyl group), —Z₁, or -L₁-Z₁. Here, L₁ and Z₁ have the same definitions as L₁ and Z₁ above, respectively, and the preferred examples thereof are also the same. It is preferable that R¹⁴, R¹⁵, and R¹⁶ each independently represent a hydrogen atom or an alkyl group having 1 to 3 carbon atoms, and more preferably a hydrogen atom.

As the monomer represented by General Formula (iv), a compound in which R¹¹, R¹², and R¹³ are each independently a hydrogen atom or a methyl group, L₁ is an alkylene group or a divalent linking group containing an oxyalkylene structure, X₁ is an oxygen atom or an imino group, and Z₁ is a carboxylic acid group is preferable. As the monomer represented by General Formula (v), a compound in which R¹ is a hydrogen atom or a methyl group, L₁ is an alkylene group, Z₁ is a carboxylic acid group, and Y is a methine group is preferable. As the monomer represented by General Formula (vi), a compound in which R¹⁴, R¹⁵, and R¹⁶ are each independently a hydrogen atom or a methyl group, and Z₁ is a carboxylic acid group is preferable.

Specific examples of the graft copolymer include the following copolymers. In addition, reference can be made to the high-molecular-weight compounds described in paragraphs 0127 to 0129 of JP2013-249417A, the contents of which are incorporated herein by reference.

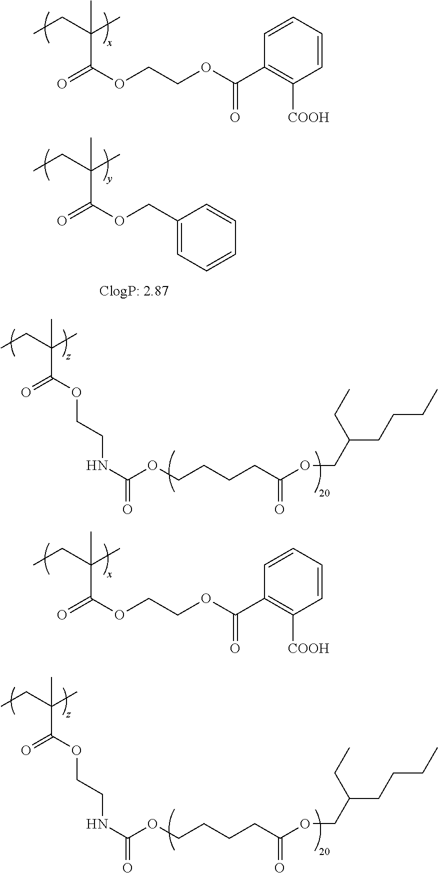

<Alkali-Soluble Resin>

The coloring composition of the present invention preferably contains an alkali-soluble resin as the resin. By incorporation of the alkali-soluble resin, the developability and the pattern formability are improved. In addition, the alkali-soluble resin can also be used as a dispersant and/or a binder.

The molecular weight of the alkali-soluble resin is not particularly determined, but the weight-average molecular weight (Mw) is preferably 5,000 to 100,000. Further, the number-average molecular weight (Mn) is preferably 1,000 to 20,000.

The alkali-soluble resin may be a linear organic high-molecular-weight polymer, and can be appropriately selected from alkali-soluble resins having at least one group enhancing alkali-solubility in a molecule (preferably a molecule having an acryl-based copolymer or a styrene-based copolymer as a main chain).

As the alkali-soluble resin, from the viewpoint of heat resistance, a polyhydroxystyrene-based resin, a polysiloxane-based resin, an acrylic resin, an acrylamide-based resin, and an acryl/acrylamide copolymer resin are preferable, and further, from the viewpoint of controlling developability, an acrylic resin, an acrylamide-based resin, and an acryl/acrylamide copolymer resin are preferable.

Examples of the group enhancing alkali-solubility (hereinafter also referred to as an acid group) include a carboxyl group, a phosphoric acid group, a sulfonic acid group, and a phenolic hydroxyl group. The group enhancing alkali-solubility is preferably a group which is soluble in an organic solvent and can be developed by an aqueous weak alkaline solution, and particularly preferred examples thereof include (meth)acrylic acid. These acid groups may be used singly or in combination of two or more kinds thereof.

For the production of the alkali-soluble resin, for example, a method using known radical polymerization can be applied. The polymerization conditions for producing the alkali-soluble resin by radical polymerization, such as a temperature, a pressure, the type and amount of a radical initiator, and the type of a solvent, can be easily set by those skilled in the art, and the conditions can also be determined experimentally.

As the alkali-soluble resin, polymers having a carboxylic acid in a side chain are preferable, and examples thereof include a methacrylic acid copolymer, an acrylic acid copolymer, an itaconic acid copolymer, a crotonic acid copolymer, a maleic acid copolymer, a partially esterified maleic acid copolymer, an alkali-soluble phenol resin or the like such as a novolac resin, an acidic cellulose derivative having a carboxyl group in a side chain, and a polymer obtained by adding an acid anhydride to a polymer having a hydroxyl group. In particular, a copolymer of a (meth)acrylic acid and another monomer copolymerizable with the (meth)acrylic acid is suitable as the alkali-soluble resin. Examples of another monomer copolymerizable with a (meth)acrylic acid include alkyl (meth)acrylate, aryl (meth)acrylate, and a vinyl compound. Examples of the alkyl (meth)acrylate and aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyltoluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of the N-position-substituted maleimide monomer disclosed in JP1998-300922A (JP-H10-300922A) include N-phenylmaleimide and N-cyclohexylmaleimide. Other monomers copolymerizable with a (meth)acrylic acid may be used singly or in combination of two or more kinds thereof.

Moreover, in order to improve the crosslinking efficiency of the coloring composition in the present invention, an alkali-soluble resin having a polymerizable group may be used. Examples of the polymerizable group include a (meth)allyl group and a (meth)acryloyl group. As the alkali-soluble resin having a polymerizable group, an alkali-soluble resin containing a polymerizable group on a side chain thereof, and the like are useful.

Examples of the alkali-soluble resin containing a polymerizable group include DIANAL NR Series (manufactured by Mitsubishi Rayon Co., Ltd.), Photomer 6173 (COOH-containing polyurethane acrylic oligomer, manufactured by Diamond Shamrock Co., Ltd.), VISCOAT R-264 and KS RESIST 106 (both manufactured by Osaka Organic Chemical Industry, Ltd.), CYCLOMER P Series (for example, ACA230AA) and PLACCEL CF200 Series (both manufactured by Daicel Corporation), Ebecryl 3800 (manufactured by Daicel-UCB Co., Ltd.), and ACRYCURE RD-F8 (manufactured by Nippon Shokubai Co., Ltd.).

As the alkali-soluble resin, a benzyl (meth)acrylate/(meth)acrylic acid copolymer, benzyl (meth)acrylate/(meth)acrylic acid/2-hydroxyethyl (meth)acrylate copolymer, or a multicomponent copolymer including benzyl (meth)acrylate/(meth)acrylic acid/other monomers can be preferably used. As the alkali-soluble resin, those obtained by copolymerizing 2-hydroxyethyl methacrylate, a 2-hydroxypropyl (meth)acrylate/polystyrene macromonomer/benzyl methacrylate/methacrylic acid copolymer described in JP 1995-140654A (JP-H07-140654A), a 2-hydroxy-3-phenoxypropylacrylate/polymethyl methacrylate macromonomer/benzyl methacrylate/methacrylic acid copolymer, a 2-hydroxyethyl (meth)acrylate/polystyrene macromonomer/methyl methacrylate/methacrylic acid copolymer, a 2-hydroxyethyl methacrylate/polystyrene macromonomer/benzyl methacrylate/methacrylic acid copolymer, and the like can be preferably used.

Furthermore, as a commercially available product thereof, for example, FF-426 (manufactured by Fujikura Kasei Co., Ltd.) or the like can also be used.

It is also preferable that the alkali-soluble resin includes a polymer (a) obtained by polymerizing monomer components including a compound represented by General Formula (ED 1) and/or a compound represented by General Formula (ED2) (these compounds are hereinafter also referred to as an “ether dimer” in some cases).

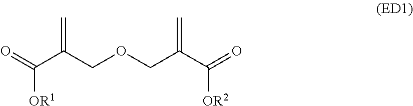

In General Formula (ED1), R¹ and R² each independently represent a hydrogen atom or a hydrocarbon group having 1 to 25 carbon atoms, which may have a substituent.

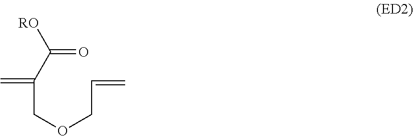

In General Formula (ED2), R represents a hydrogen atom or an organic group having 1 to 30 carbon atoms. With regard to the specific examples of General Formula (ED2), reference can be made to the descriptions in JP2010-168539A.

In General Formula (ED 1), the hydrocarbon group having 1 to 25 carbon atoms, represented by R¹ and R², which may have a substituent, is not particularly limited, and examples thereof include linear or branched alkyl groups such as methyl, ethyl, n-propyl, isopropyl, n-butyl, isobutyl, tert-butyl, tert-amyl, stearyl, lauryl, and 2-ethylhexyl; aryl groups such as phenyl; alicyclic groups such as cyclohexyl, tert-butylcyclohexyl, dicyclopentadienyl, tricyclodecanyl, isobornyl, adamantyl, and 2-methyl-2-adamantyl; alkyl groups substituted with alkoxy, such as 1-methoxyethyl and 1-ethoxyethyl; and alkyl groups substituted with an aryl group, such as benzyl. Among those, from the viewpoint of heat resistance, substituents of primary or secondary carbon, which are not easily eliminated by an acid or heat, such as methyl, ethyl, cyclohexyl, and benzyl, are particularly preferable.

Specific examples of the ether dimer include those described in paragraph 0317 of JP2013-29760A, the contents of which are incorporated herein by reference. These ether dimers may be used singly or in combination of two or more kinds thereof. The structure derived from the compound represented by General Formula (ED 1) and General Formula (ED2) may be copolymerized with other monomers.

The alkali-soluble resin may include a structural unit derived from a compound represented by Formula (X).

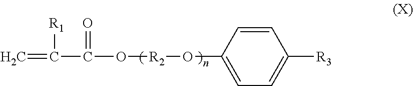

In Formula (X), R₁ represents a hydrogen atom or a methyl group, R₂ represents an alkylene group having 2 to 10 carbon atoms, R₃ represents a hydrogen atom or an alkyl group having 1 to 20 carbon atoms, which may contain a benzene ring, and n represents an integer of 1 to 15.

In Formula (X), the number of carbon atoms of the alkylene group of R₂ is preferably 2 or 3. Further, the number of carbon atoms of the alkyl group of R₃ is 1 to 20, and more preferably 1 to 10, and the alkyl group of R₃ may contain a benzene ring. Examples of the alkyl group containing a benzene ring, represented by R₃, include a benzyl group and a 2-phenyl(iso)propyl group.

Specific examples of the alkali-soluble resin include the following ones.

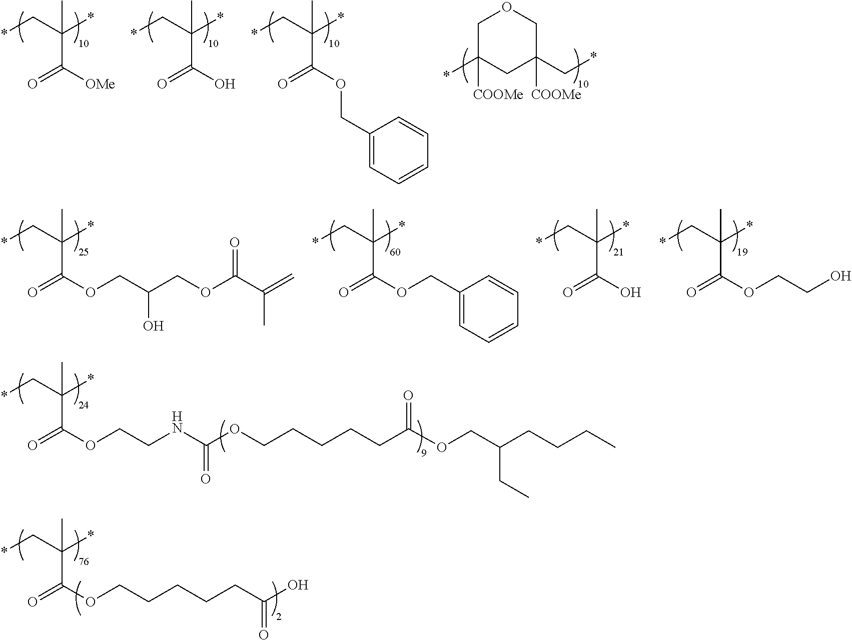

With regard to the alkali-soluble resin, reference can be made to the descriptions in paragraphs 0558 to 0571 of JP2012-208494A ([0685] to [0700] of the corresponding US2012/0235099A), the contents of which are incorporated herein by reference.

Moreover, it is possible to use the copolymers (B) described in paragraph Nos. 0029 to 0063 of JP2012-32767A and the alkali-soluble resins used in Examples of the document, the binder resins described in paragraph Nos. 0088 to 0098 of JP2012-208474A and the binder resins used in Examples of the document, the binder resins described in paragraph Nos. 0022 to 0032 of JP2012-137531A and the binder resins in Examples of the document, the binder resins described in paragraph Nos. 0132 to 0143 of JP2013-024934A and the binder resins used in Examples of the document, the binder resins described in paragraph Nos. 0092 to 0098 of JP2011-242752A and used in Examples, or the binder resins described in paragraph Nos. 0030 to 0072 of JP2012-032770A, the contents of which are incorporated herein by reference.

The acid value of the alkali-soluble resin is preferably 30 to 500 mgKOH/g. The lower limit is more preferably 50 mgKOH/g or more, and still more preferably 70 mgKOH/g or more. The upper limit is more preferably 400 mgKOH/g or less, still more preferably 200 mgKOH/g or less, particularly preferably 150 mgKOH/g or less, and most preferably 120 mgKOH/g or less.

The content of the alkali-soluble resin is preferably 0.1% to 20% by mass with respect to the total solid content of the coloring composition. The lower limit is preferably 0.5% by mass or more, more preferably 1% by mass or more, still more preferably 2% by mass or more, and particularly preferably 3% by mass or more. The upper limit is more preferably 12% by mass or less, and still more preferably 10% by mass or less. The coloring composition of the present invention may include one kind or two or more kinds of the alkali-soluble resin. In a case where two or more kinds of the alkali-soluble resin are included, a total amount thereof preferably falls within the above range.

[Organic Solvent]

The coloring composition of the present invention may include an organic solvent.

Basically, the organic solvent is not particularly limited as long as it satisfies the solubility of the respective components, the coatability of the coloring composition, and the like, but the organic solvent is preferably selected in consideration of the solubility, the coatability, and the safety of a polymerizable compound, an alkali-soluble resin, or the like.

Suitable examples of the organic solvent include esters such as ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl oxyacetate esters (e.g.: methyl oxyacetate, ethyl oxyacetate, and butyl oxyacetate (for example, methyl methoxyacetate, ethyl methoxyacetate, butyl methoxyacetate, methyl ethoxyacetate, and ethyl ethoxyacetate)), alkyl 3-oxypropionate esters (e.g.: methyl 3-oxypropionate and ethyl 3-oxypropionate (for example, methyl 3-methoxypropionate, ethyl 3-methoxypropionate, methyl 3-ethoxypropionate, and ethyl 3-ethoxypropionate)), alkyl 2-oxypropionate esters (e.g.: methyl 2-oxypropionate, ethyl 2-oxypropionate, and propyl 2-oxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-oxy-2-methyl propionate and ethyl 2-oxy-2-methyl propionate (e.g.: methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate; ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether (MFG), propylene glycol monmethyl ether acetate (PGMEA), propylene glycol monoethyl ether acetate, and propylene glycol propyl ether acetate; ketones such as methyl ethyl ketone, cyclohexanone, cyclopentanone, 2-heptanone, and 3-heptanone; and aromatic hydrocarbons such as toluene and xylene.

From the viewpoint of superior linearity of a colored pattern thus obtained, and further, from the viewpoints of the solubility of a polymerizable compound, an alkali-soluble resin, or the like, the improvement in the shape of coated surfaces, and the like, it is preferable that two or more kinds of these organic solvents are used in combination in the coloring composition of the present invention.

In this case, a mixed solution including two or more kinds selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol monomethyl ether (MFG), and propylene glycol monomethyl ether acetate (PGMEA) is particularly preferable.

In the present invention, the organic solvent preferably has a content of peroxides of 0.8 mmol/L or less, and the solvent which does not substantially include peroxides is more preferable.

From the viewpoint of coatability, the content of the organic solvent in the coloring composition is preferably set such that the concentration of the total solid content of the coloring composition becomes 5% to 80% by mass, more preferably 5% to 60% by mass, and particularly preferably 10% to 50% by mass.

In the coloring composition of the present invention, only one kind of the organic solvent may be used, but two or more kinds of the solvents are preferably used in combination. In a case where two or more kinds of the solvents are used in combination, the total amount thereof preferably falls within the above range.

[Surfactant]

From the viewpoint of further improving coatability, various surfactants may be added to the coloring composition of the present invention. As the surfactants, various surfactants such as a fluorine-based surfactant, a non-ionic surfactant, a cationic surfactant, an anionic surfactant, and a silicone-based surfactant can be used.

For example, by incorporation of a fluorine-based surfactant, liquid characteristics (in particular, fluidity) are further improved in a case where the coloring composition is prepared into a coating liquid. That is, in the case where a film is formed, using the coloring composition containing a fluorine-based surfactant, the interface tension between a surface to be coated and the coating liquid is reduced to improve wettability with respect to the surface to be coated, and enhance coatability with respect to the surface to be coated. Therefore, even in the case where a thin film of about several μm is formed of a small amount of liquid, the coloring composition containing a fluorine-based surfactant is effective in that a film with a uniform thickness which exhibits a small extent of thickness unevenness can be more suitably formed.

The fluorine content in the fluorine-based surfactant is suitably 3% to 40% by mass, more preferably 5% to 30% by mass, and particularly preferably 7% to 25% by mass. The fluorine-based surfactant in which the fluorine content falls within this range is effective in terms of the evenness of the thickness of the coating film, liquid saving properties, and the like, and the solubility of the surfactant in the coloring composition is also good.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781 (all manufactured by DIC Corporation); FLUORAD FC430, FC431, and FC171 (all manufactured by Sumitomo 3M); SURFLON S-382, SURFLON SC-101, SURFLON SC-103, SURFLON SC-104, SURFLON SC-105, SURFLON SC1068, SURFLON SC-381, SURFLON SC-383, SURFLON S393, and SURFLON KH-40 (all manufactured by ASAHI GLASS Co., Ltd.); and PF636, PF656, PF6320, PF6520, and PF7002 (manufactured by OMNOVA).

As the fluorine-based surfactant, a block polymer can also be used, and specific examples thereof include the compounds described in JP2011-89090A.

Furthermore, a compound represented by the following formula can also be exemplified as the fluorine-based surfactant.

Incidentally, in the compound, the amount of the structural units represented by (A) and (B) in the formula are 62% by mole and 38% by mole, respectively.

In the structural unit represented by Formula (B), a, b, and c satisfy the relationship of a+c=14 and b=17.

The weight-average molecular weight of the following compound is, for example, 15,311.

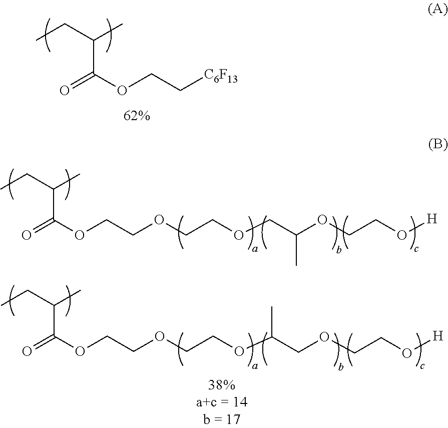

Furthermore, the following compound is also exemplified as the fluorine-based surfactant. The weight-average molecular weight of the following compound is, for example, 14,000.

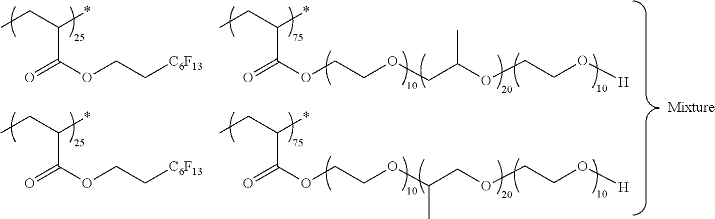

Specific examples of the non-ionic surfactant include glycerol, trimethylolpropane, trimethylolethane, and ethoxylate and propoxylate thereof (for example, glycerol propoxylate and glycerin ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters (PLURONIC L10, L31, L61, L62, 10R5, 17R2, and 25R2, and TETRONIC 304, 701, 704, 901, 904, and 150R1 manufactured by BASF), and SOLSEPERSE 20000 (manufactured by Lubrizol Japan Ltd.). Further, PIONIN D-6112-W manufactured by Takemoto Oil & Fat Co., Ltd., or NCW-101, NCW-1001, or NCW-1002 manufactured by Wako Pure Chemical Industries, Ltd. can also be used.

Specific examples of the cationic surfactant include a phthalocyanine derivative (trade name: EFKA-745, manufactured by MORISHITA KAGAKU SANGYO Corporation), an organosiloxane polymer KP341 (manufactured by Shin-Etsu Chemical Co., Ltd.), a (meth)acrylic acid-based (co)polymer POLYFLOW No. 75, No. 90, and No. 95 (manufactured by KYOEISHA CHEMICAL CO., LTD.), and W001 (manufactured by Yusho Co., Ltd.).

Specific examples of the anionic surfactant include W004, W005, and W017 (manufactured by Yusho Co., Ltd.).

Examples of the silicone-based surfactant include “TORAY SILICONE DC3PA”, “TORAY SILICONE SH7PA”, “TORAY SILICONE DC11PA”, “TORAY SILICONE SH21PA”, “TORAY SILICONE SH28PA”, “TORAY SILICONE SH29PA”, “TORAY SILICONE SH3OPA”, and “TORAY SILICONE SH8400”, manufactured by Dow Corning Toray CO., LTD., “TSF-4440”, “TSF-4300”, “TSF-4445”, “TSF-4460”, and “TSF-4452”, manufactured by Momentive Performance Materials Inc., “KP341”, “KF6001”, and “KF6002”, manufactured by Shin-Etsu Chemical Co., Ltd., and “BYK307”, “BYK323”, and “BYK330”, manufactured by BYK Additives & Instruments.

In a case where the coloring composition of the present invention includes a surfactant, the content of the surfactant is preferably 0.001% to 2.0% by mass, and more preferably 0.005% to 1.0% by mass, with respect to the total mass of the coloring composition.

The coloring composition of the present invention may include one kind or two or more kinds of the surfactant. In a case where the coloring composition includes two or more kinds of the surfactant, the total amount thereof preferably falls within the above range.

[Ultraviolet Absorber]

The coloring composition of the present invention preferably further contains an ultraviolet absorber. Since the photopolymerization initiator used in the present invention has high light reactivity, portions which are not exposed may also be reacted in some cases, but by incorporation of the ultraviolet absorber, the reaction of the portions which are not exposed can be suppressed.

As the ultraviolet absorber, for example, salicylate-, benzophenone-, benzotriazole-, cyanoacrylate-, and nickel chelate-based ultraviolet absorbers, with the benzotriazole-based compound being preferable.

Examples of the benzotriazole-based compound include 2-(2H-benzotriazol-2-yl)-4,6-bis(1-methyl-1-phenylethyl)phenol, 2-(2′-hydroxy-5′-methylphenyl)benzotriazole, 2-(2′-hydroxy-3′-t-butyl-5′-methylphenyl)-5-chlorobenzotriazole, and 2-[2-hydroxy-3,5-bis(α,α-dimethylbenzyl)phenyl]-2H-benzotriazole. Among these, 2-(2H-benzotriazol-2-yl)-4,6-bis(1-methyl-1-phenylethyl)phenol is particularly preferable. As the benzotriazole-based compound which is commercially available, TINUVIN 900, TINUVIN 928, TINUVIN P, TINUVIN 234, TINUVIN 326, TINUVIN 329, or the like manufactured by BASF can be used.

Besides those, examples of the ultraviolet absorber which can be used in the present invention include phenyl salicylate, 4-t-butylphenylsalicylate, 2,4-di-t-butylphenyl-3′,5′-di-t-butyl-4′-hydroxybenzoate, 2,4-dihydroxybenzophenone, 2-hydroxy-4-methoxybenzophenone, 2-hydroxy-4-n-octyloxybenzophenone, ethyl-2-cyano-3,3-diphenylacrylate, 2,2′-hydroxy-4-methoxybenzophenone, nickel dibutyl dithiocarbamate, bis(2,2,6,6-tetramethyl-4-piperidine)-sebacate, 4-hydroxy-2,2,6,6-tetramethylpiperidine condensates, succinic acid-bis(2,2,6,6-tetramethyl-4-piperidine)ester, and 7-{[4-chloro-6-(diethylamino)-1,3,5-triazin-2-yl]amino}-3-phenylcoumarin. Two or more kinds of these ultraviolet absorbers can be used in combination, and the ultraviolet absorbers can be adjusted so as to absorb light in a desired wavelength range.

The blend amount of the ultraviolet absorber in the coloring composition of the present invention is preferably 1% to 20% by mass, more preferably 2% to 15% by mass, and still more preferably 3% to 10% by mass, with respect to the total solid content.

[Silane Coupling Agent]

The coloring composition of the present invention preferably contains a silane coupling agent. The silane coupling agent improves the adhesiveness to a layer adjacent to the coloring composition layer, or to a substrate.

The silane coupling agent is a compound having a hydrolyzable group and other functional groups in a molecule thereof. Further, the hydrolyzable group such as an alkoxy group is bonded to a silicon atom.

The hydrolyzable group refers to a substituent that can be directly linked to a silicon atom to generate a siloxane bond by a hydrolysis reaction and/or a condensation reaction. Examples of the hydrolyzable group include a halogen atom, an alkoxy group, an acyloxy group, and an alkenyloxy group. In a case where the hydrolyzable group has a carbon atom, the number of carbon atoms thereof is preferably 6 or less, and more preferably 4 or less. In particular, an alkoxy group having 4 or less carbon atoms or an alkenyloxy group having 4 or less carbon atoms is preferable. Further, an alkoxy group having 2 or less carbon atoms or an alkenyloxy group having 4 or less carbon atoms is preferable.

The silane coupling agent preferably has a group represented by Formula (Z). * represents a binding position.

*—Si—(R_{Z1})₃ Formula (Z)

In Formula (Z), R_{z1} represents a hydrolyzable group, and the definition of the hydrolyzable group is as described above.

The silane coupling agent may have a curable functional group. The curable functional group may be either a thermosetting functional group or a photocurable functional group. Examples of the curable functional group include one or more selected from a (meth)acryloyloxy group, an epoxy group, an oxetanyl group, an isocyanate group, a hydroxyl group, an amino group, a carboxyl group, a thiol group, an alkoxysilyl group, a methylol group, a vinyl group, a (meth)acrylamido group, a styryl group, and a maleimido group. In a view that the effect of the present invention is superior, it is preferable that the silane coupling agent has one or more selected from the group consisting of a (meth)acryloyloxy group, an epoxy group, and an oxetanyl group. The curable functional group may be bonded to a silicon atom directly or via a linking group.

Suitable aspects of the curable functional group included in the silane coupling agent also include a radically polymerizable group.

The molecular weight of the silane coupling agent is not particularly limited, and in a view of handling properties, the molecular weight is 100 to 1,000 in many cases, and in a view that the effect of the present invention is superior, the molecular weight is preferably 150 or more, and more preferably 150 to 1,000.

As one of suitable aspects of the silane coupling agent, a silane coupling agent X represented by Formula (W) can be exemplified.

R_{Z2}-Lz-Si—(R_{Z1})₃ Formula (W)

R_{z1} represents a hydrolyzable group and the definition thereof is as described above.

R_{z2} represents a curable functional group, and the definition and a suitable range thereof are also as described above.

Lz represents a single bond or a divalent linking group. The definition of the divalent linking group is the same as that of the divalent linking group represented by L¹ as described above.

Examples of the silane coupling agent X include N-β-aminoethyl-γ-aminopropyl-methyldimethoxysilane (trade name: KBM-602, manufactured by Shin-Etsu Chemical Co., Ltd.), N-β-aminoethyl-γ-aminopropyl-trimethoxysilane (trade name: KBM-603, manufactured by Shin-Etsu Chemical Co., Ltd.), N-β-aminoethyl-γ-aminopropyl-triethoxysilane (trade name: KBE-602, manufactured by Shin-Etsu Chemical Co., Ltd.), γ-aminopropyl-trimethoxysilane (trade name: KBM-903, manufactured by Shin-Etsu Chemical Co., Ltd.), γ-aminopropyl-triethoxysilane (trade name: KBE-903, manufactured by Shin-Etsu Chemical Co., Ltd.), 3-methacryloxypropyltrimethoxysilane (trade name: KBM-503, manufactured by Shin-Etsu Chemical Co., Ltd.), glycidoxyoctyltrimethoxysilane (trade name: KBM-4803, manufactured by Shin-Etsu Chemical Co., Ltd.), 2-(3,4-epoxycyclohexyl)ethyltrimethoxysilane (trade name: KBM-303, manufactured by Shin-Etsu Chemical Co., Ltd.), 3-glycidoxypropyltrimethoxysilane (trade name: KBM-403, manufactured by Shin-Etsu Chemical Co., Ltd.), and 3-glycidoxypropyltriethoxysilane (trade name: KBE-403, manufactured by Shin-Etsu Chemical Co., Ltd.).

Other suitable aspects of the silane coupling agent include a silane coupling agent Y having at least a silicon atom, a nitrogen atom, and a curable functional group, as well as a hydrolyzable group bonded to the silicon atom, in a molecule thereof.

This silane coupling agent Y may have at least one silicon atom in a molecule thereof, and the silicon atom may be bonded to the following atoms and substituents. They may be the same or different atoms or substituents. Examples of the atoms and substituents to which the silane coupling agent Y may be bonded include a hydrogen atom, a halogen atom, a hydroxyl group, an alkyl group having 1 to 20 carbon atoms, an alkenyl group, an alkynyl group, an aryl group, an amino group which can be substituted with an alkyl group and/or an aryl group, a silyl group, an alkoxy group having 1 to 20 carbon atoms, and an aryloxy group. These substituent may also further be substituted with a silyl group, an alkenyl group, an alkynyl group, an aryl group, an alkoxy group, an aryloxy group, a thioalkoxy group, an amino group which can be substituted with an alkyl group and/or an aryl group, a halogen atom, a sulfonamido group, an alkoxycarbonyl group, an amido group, a urea group, an ammonium group, an alkylammonium group, a carboxyl group or a salt thereof, a sulfo group or a salt thereof, or the like.

In addition, at least one hydrolyzable group is bonded to the silicon atom. The definition of the hydrolyzable group is as described above.

The silane coupling agent Y may include a group represented by Formula (Z).

It is preferable that the silane coupling agent Y has at least one nitrogen atom in a molecule thereof and the nitrogen atom is present in the form of a secondary amino group or a tertiary amino group, that is, it is preferable that the nitrogen atom has at least one organic group as a substituent. Further, with regard to the structure of the amino group, the amino group may be present in the form of a partial structure of a nitrogen-containing heterocycle in a molecule thereof, or may be present as a substituted amino group such as aniline.

Here, examples of the organic group include an alkyl group, an alkenyl group, an alkynyl group, an aryl group, and a combination thereof. These organic groups may further have a substituent, and examples of the substituent which can be introduced include a silyl group, an alkenyl group, an alkynyl group, an aryl group, an alkoxy group, an aryloxy group, a thioalkoxy group, an amino group, a halogen atom, a sulfonamido group, an alkoxycarbonyl group, a carbonyloxy group, an amido group, a urea group, an alkyleneoxy group, an ammonium group, an alkylammonium group, a carboxyl group or a salt thereof, and a sulfo group.

In addition, it is preferable that the nitrogen atom is bonded to a curable functional group via an arbitrary organic linking group. Preferable examples of the organic linking group include the above-mentioned substituents which can be introduced into the nitrogen atom and the organic group bonded to the nitrogen atom.

The definition of the curable functional group included in the silane coupling agent Y is as described above and suitable ranges thereof are as described above.

Any silane coupling agent Y is available as long as it has at least one curable functional group in a molecule thereof, but aspects in which the silane coupling agent Y has two or more curable functional groups can also be adopted. From the viewpoints of sensitivity and stability, the silane coupling agent Y more preferably has 2 to 20 curable functional groups, and more preferably has 4 to 15 curable functional groups, and in the most preferred aspect, the silane coupling agent Y has 6 to 10 curable functional groups in a molecule thereof.

The molecular weights of the silane coupling agent X and the silane coupling agent Y are not particularly limited, but can be each in the above-mentioned range (preferably 150 or more).

The content of the silane coupling agent in the coloring composition of the present invention is preferably 0.1% to 10% by mass, more preferably 0.5% to 8% by mass, and still more preferably 1.0% to 6% by mass, with respect to the total solid content in the coloring composition of the present invention.

The coloring composition of the present invention may include one kind or two or more kinds of silane coupling agent. In a case where the composition includes two or more of the silane coupling agents, a total thereof only needs to be in the range.

[Polymerization Inhibitor]

The coloring composition of the present invention preferably contains a polymerization inhibitor. Thus, a colored pattern obtained by using the coloring composition of the present invention has superior linearity even when not accompanied by a heating treatment at a high temperature.

The reason therefor is thought to be that by incorporating a polymerization inhibitor into the coloring composition of the present invention, a photopolymerization initiator is trapped, and as a result, curing in an unexposed area or the like is suppressed, and the line width of the obtained colored pattern is thus more uniform.

Examples of the polymerization inhibitor include known polymerization inhibitors, such as a phenol-based polymerization inhibitor, a quinone-based polymerization inhibitor, a hindered amine-based polymerization inhibitor, a phenothiazine-based polymerization inhibitor, and a nitrobenzene-based polymerization inhibitor.

Among these, for a reason that the linearity of a colored pattern thus obtained is superior, a phenol-based polymerization inhibitor and/or a hindered amine-based polymerization inhibitor is preferable, and a phenol-based polymerization inhibitor is more preferable.

Specific examples of the phenol-based polymerization inhibitor include phenol, 4-methoxyphenol, hydroquinone, 2-tert-butylhydroquinone, catechol, 4-tert-butyl-catechol, 2,6-di-tert-butylphenol, 2,6-di-tert-butyl-4-methylphenol, 2,6-di-tert-butyl-4-ethylphenol, 4-hydroxymethyl-2,6-di-tert-butylphenol, pentaerythritol tetrakis(3,5-di-tert-butyl-4-hydroxyhydrocinnamate), 4-methoxy-1-naphthol, and 1,4-dihydroxynaphthalene.

As the phenol-based polymerization inhibitor, a phenol-based polymerization inhibitor represented by General Formula (IH-1) is preferable.

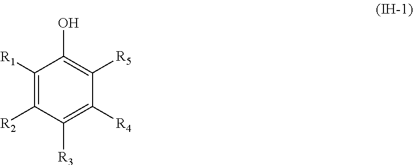

In General Formula (IH-1), R₁ to R₅ each independently represent a hydrogen atom, an alkyl group, an alkenyl group, a hydroxyl group, an amino group, an aryl group, an alkoxy group, a carboxyl group, an alkoxycarbonyl group, or an acyl group. R₁ to R₅ may be linked to each other to form a ring.

As each of R₁ to R₅ in General Formula (IH-1), a hydrogen atom, an alkyl group having 1 to 5 carbon atoms (for example, a methyl group and an ethyl group), an alkoxy group having 1 to 5 carbon atoms (for example, a methoxy group and an ethoxy group), an alkenyl group having 2 to 4 carbon atoms (for example, a vinyl group), or a phenyl group is preferable.

In particular, R₁ and R₅ are each more preferably a hydrogen atom or a tert-butyl group, each of R₂ and R₄ are each more preferably a hydrogen atom, and R₃ is more preferably a hydrogen atom, an alkyl group having 1 to 5 carbon atoms, or an alkoxy group having 1 to 5 carbon atoms.

Examples of the quinone-based polymerization inhibitor include 1,4-benzoquinone, 1,2-benzoquinone, and 1,4-naphthoquinone.

Suitable examples of the hindered amine-based polymerization inhibitor include a polymerization inhibitor represented by General Formula (IH-2).

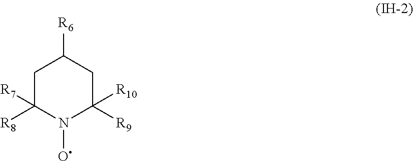

R₆ in General Formula (IH-2) represents a hydrogen atom, a hydroxyl group, an amino group, an alkoxy group, an alkoxycarbonyl group, or an acyl group. Among those, a hydrogen atom or a hydroxyl group is preferable, and a hydroxyl group is more preferable.

In addition, R₇ to R₁₀ in General Formula (IH-2) each independently represent a hydrogen atom or an alkyl group. As the alkyl group represented by each of R₇ to R₁₀, an alkyl group having 1 to 5 carbon atoms is preferable, and a methyl group or an ethyl group is more preferable.

In a case of using the polymerization inhibitor, for a reason that the linearity of a colored pattern thus obtained is superior, it is more preferable that two or more kinds of polymerization initiators are used in combination, it is still more preferable that two or more kinds of phenol-based polymerization initiators are used in combination, or a phenol-based polymerization initiator and a hindered amine-based polymerization initiator are used in combination, and it is particularly preferable that a phenol-based polymerization initiator and a hindered amine-based polymerization initiator are used in combination.

In a case where the coloring composition of the present invention contains a polymerization inhibitor, the content of the polymerization inhibitor (in a case where two or more kinds of the polymerization inhibitors are used, a total amount thereof) is, for example, 0.001% to 0.100% by mass, and for a reason that the linearity of a colored pattern thus obtained is superior, the content is preferably 0.003% to 0.010% by mass, and more preferably 0.003% by mass or more and less than 0.010% by mass, with respect to the total solid content of the coloring composition.

In a case where the coloring composition of the present invention contains the polymerization inhibitor, the mass ratio of the polymerization inhibitor to the photopolymerization initiator (polymerization inhibitor/photopolymerization initiator) is, for example, 0.001 to 0.100, and for the reasons that the linearity of a colored pattern thus obtained is superior and the adhesiveness a cured film (including a pattern) thus obtained to a support is also superior, the mass ratio is preferably 0.003 to 0.030.

[Other Additives]

Various additives, for example, a filler, an adhesion promoter, an antioxidant, an aggregation inhibitor, or the like can be blended into the coloring composition of the present invention, as desired. Examples of these additives include those described in paragraphs 0155 to 0156 of JP2004-295116A, the contents of which are incorporated herein by reference.

The coloring composition of the present invention can contain the sensitizer or the light stabilizer described in paragraph 0078 of JP2004-295116A, or the thermal polymerization inhibitor described in paragraph 0081 of the same publication.

[Method for Preparing Coloring Photosensitive Composition]

The coloring composition of the present invention can be prepared by mixing the above-mentioned components.

During the preparation of the coloring composition, the respective components constituting the coloring composition may be blended together at the same time or may be blended together sequentially after being dissolved and dispersed in a solvent. Further, the order of the components to be introduced or the operational conditions during the blending is not particularly limited. For example, the composition may be prepared by dissolving or dispersing all the components in a solvent at the same time, or by appropriately leaving the respective components in two or more solutions or dispersion liquids, and mixing them into a solution during the use (during the coating), as desired.

It is preferable that the coloring composition of the present invention is filtered using a filter for the purpose of removing foreign matters, reducing defects, or the like. As the filter, any filters that have been used in the related art for filtration use and the like may be used without particular limitation. Examples of the filter include filters formed of a fluorine resin such as polytetrafluoroethylene (PTFE), a polyamide-based resin such as Nylon-6 and Nylon-6,6, and a polyolefin resin (including a high density and an ultrahigh-molecular-weight weight) such as polyethylene and polypropylene (PP). Among those materials, polypropylene (including high-density polypropylene) is preferable.

The pore diameter of the filter is suitably approximately 0.01 to 7.0 μm, preferably approximately 0.01 to 3.0 μm, and more preferably approximately 0.05 to 0.5 μm. By setting the pore diameter of the filter to the range, it is possible to reliably remove fine foreign matters, which interfere with the preparation of a uniform and smooth coloring composition in the later steps.

In a case of using the filter, different filters may be combined. Here, the filtration through the first filter may be run once, or may be repeated twice or more times.

Incidentally, the first filters having different pore diameters within the range may be combined. With regard to the pore diameter of the filter herein, reference can be made to nominal values of filter manufacturers. A commercially available filter may be selected from various filters provided by Nihon Pall Corporation (DFA4201NXEY and the like), Toyo Roshi Kaisha., Ltd., Nihon Entegris K. K. (formerly Nippon Microlith Co., Ltd.), Kitz Micro Filter Corporation, or the like, for example.

As the second filter, those formed of the same material as that of the above-described first filter may be used.

For example, the filtration through the first filter may be carried out with only a dispersion liquid, the other components may be mixed, and then the filtration through the second filter may be carried out.

[Cured Film (Color Filter or Light-Shielding Film)]

Next, the cured film of the present invention will be described.

The cured film of the present invention is formed by curing the coloring composition of the present invention (formed using the coloring composition of the present invention). The cured film of the present invention can be preferably used as a color filter or a light-shielding film. That is, the color filter and the light-shielding film of the present invention are formed by curing the coloring composition of the present invention (formed using the coloring composition of the present invention).

The color filter can be suitably used for a solid-state imaging device such as a charge coupled device (CCD) and a complementary metal-oxide semiconductor (CMOS), and is particularly suitable for a CCD, a CMOS, and the like with a high resolution, having more than 1,000,000 pixels. The color filter can be used as, for example, a color filter disposed between a light-receiving portion of each pixel constituting a CCD or a CMOS and a microlens for collecting light.

Furthermore, the color filter can be preferably used for an organic electroluminescence (organic EL) device. As the organic EL device, a white organic EL device is preferable. The organic EL device preferably has a tandem structure. The tandem structure of the organic EL device is described in JP2003-45676A, “Forefront of Organic EL Technology Development—Know-How Collection of High Brightness/High Precision/Long Life—”, reviewed by Mikami Akiyoshi, Technical Information Institute, pp. 326 to 328, 2008, and the like. Examples of the tandem structure of the organic EL device include a structure in which an organic EL layer is provided between a lower electrode with light reflectivity and an upper electrode with light-transmitting properties on one surface of a substrate. The lower electrode is preferably configured with a material having a sufficient reflectivity in a visible light wavelength range. The organic EL layer preferably has a lamination structure (tandem structure) including a plurality of light emitting layers, with the plurality of the light emitting layers laminated. The plurality of light emitting layers of the organic EL layer can include, for example, a red light emitting layer, a green light emitting layer, and a blue light emitting layer. Further, the organic EL layer preferably has a plurality of light emitting auxiliary layers for light emission of the light emitting layers, in addition to the plurality of light emitting layers. The organic EL layer can have, for example, a lamination structure in which a light emitting layer and a light emitting auxiliary layer are alternately laminated. An organic EL device having an organic EL layer such a structure can emit white light. In this case, it is preferable that a spectrum of white light which the organic EL device emits has strong maximum light emitting peaks at a blue region (430 nm to 485 nm), a green region (530 nm to 580 nm), and a yellow region (580 nm to 620 nm). It is more preferable that the spectrum additionally has a strong maximum light emitting peak at a red region (650 nm to 700 nm), in addition to the light emitting peaks. By combining an organic EL device (white organic EL device) that emits white light with the color filter of the present invention, an excellent spectrum in terms of color reproducibility is obtained, and thus, a clearer picture or image can be displayed.

The film thickness of the colored pattern (colored pixel) in the color filter is preferably 2.0 μm or less, more preferably 1.0 μm or less, and still more preferably 0.7 μm or less. The lower limit can be set to, for example, 0.1 μm or more, or also to 0.2 μm or more.

Incidentally, the size (pattern width) of the colored pattern (colored pixel) is preferably 2.5 μm or less, more preferably 2.0 μm or less, and particularly preferably 1.7 μm or less. The lower limit can be set to, for example, 0.1 μm or more, or also to 0.2 μm or more.

The light-shielding film can be used after being formed in various members (for example, an infrared cut filter, a peripheral portion of a solid-state imaging device, a peripheral portion of a wafer level lens, and a backside of a solid-state imaging device), or the like within a device such as an image display device and a sensor module.

Incidentally, a light-shielding film may be formed in at least a part on the surface of an infrared cut filter, thereby providing an infrared cut filter with a light-shielding film.

The thickness of the light-shielding film is not particularly limited, but is preferably 0.2 to 25 μm, and more preferably 1.0 to 10 μm. The thickness is an average thickness, which is a value obtained by measuring the thickness at arbitrary 5 or more points of the light-shielding film, and arithmetically averaging the values.

The reflectivity of the light-shielding film is preferably 10% or less, more preferably 8% or less, still more preferably 6% or less, and particularly preferably 4% or less. Further, reflectivity of the light-shielding film is a value by making light at 400 to 700 nm be incident onto the light-shielding film under the conditions of an angle of incidence of 5°, and measuring the reflectivity using a spectrometer UV4100 (trade name) manufactured by HITACHI High-Technologies Corporation.

[Method for Producing Cured Film]

Next, the method for producing a cured film of the present invention will be described.

The method for producing a cured film of the present invention includes at least a step of forming a coloring photosensitive composition layer on a support using the coloring composition of the present invention, and a step of exposing the coloring photosensitive composition layer (exposing step). Here, in a case where as the exposing step, a step of exposing the coloring photosensitive composition layer in a pattern shape, the method for producing a cured film of the present invention may further include a step of removing unexposed areas by development after the exposing step to form a colored pattern (developing step).

Meanwhile, in a method for producing a cured film in the related art, from the viewpoint of accelerating curing after the exposure (or after the development or after drying following the development), the cured film may be subjected to, for example, a heating treatment (post-baking) in an environment at approximately 200° C. in some cases, but there has recently been an increasing demand that the cured film should be cured in a low-temperature environment.

Accordingly, by using the coloring composition of the present invention, curing sufficiently proceeds across the film even though a heating treatment at a high temperature is not carried out, and therefore, the heating treatment at a high temperature is not necessary.

That is, the production method of the present invention may further include a step of subjecting the cured film to a heating treatment, but the temperature of this heating treatment is preferably 120° C. or lower, more preferably 80° C. or lower, and still more preferably 50° C. or lower. The lower limit of the temperature is not particularly limited, but is, for example, 30° C. or higher.

Furthermore, in the heating of the cured film, a heating means such as a hot plate, a convection oven (hot air circulation type dryer), and an ultrasonic heater can be used and can be carried out in a continuous or batch mode.

In addition, the time for the heating treatment is preferably 3 to 180 minutes, and more preferably 5 to 120 minutes.

[Step of Forming Coloring Photosensitive Composition Layer]

In the step of forming a coloring photosensitive composition layer, the coloring photosensitive composition layer (hereinafter also simply referred to as a “coloring composition layer”) is formed on a support, using the coloring composition of the present invention.

Examples of the support include transparent substrates such as glass, a silicone, a polycarbonate, a polyester, an aromatic polyamide, a polyamideimide, and a polyimide. A thin-film transistor for driving an organic EL device may be formed on these transparent substrates.

Furthermore, it is possible to use a substrate for a solid-state imaging device in which a solid-state imaging device (light-receiving element) such as a charge coupled device (CCD) and a complementary metal-oxide semiconductor (CMOS) is provided onto a substrate.

As a method for applying the coloring composition of the present invention onto the support, various coating methods such as slit coating, an ink jet method, spin coating, spray coating, cast coating, roll coating, and a screen printing method can be used.

From the viewpoint of the uniformity of the film thickness of the coloring photosensitive composition layer, spin coating or spray coating is preferable, in a case where the under layer surface of the coloring photosensitive composition layer is not flat, from the viewpoint of the uniformity of the film thickness, spray coating or an ink jet method is preferable.

If the film thickness is uniform, uniform curing can be performed, and peeling of films due to partial curing failure or partial development failure in a case where a treatment with a developer is carried out can be suppressed. In particular, the effect is noticeable during the curing in a low-temperature environment.

Moreover, in the present invention, it is preferable that an epoxy resin layer is formed on the support on which the coloring composition layer is formed, that is, a support having an epoxy resin layer is used. Thus, the adhesiveness of a cured film obtained by using the coloring composition of the present invention to a support (in this case, the epoxy resin layer) is superior.

An epoxy resin constituting the epoxy resin layer is not particularly limited, and for example, a bisphenol A type epoxy resin, a bisphenol F type epoxy resin, a phenol novolac type epoxy resin, a cresol novolac type epoxy resin, an aliphatic epoxy resin, or the like which has been known in the related art can be appropriately used.

In addition, the coloring composition layer formed on the support may be subjected to a heating treatment (pre-baked), but the temperature therefor is preferably 120° C. or lower, more preferably 80° C. or lower, and still more preferably 50° C. or lower, for the same reason as above.

The prebaking time is preferably 10 seconds to 300 seconds, and more preferably 40 seconds to 250 seconds. Heating can be carried out using a hot plate, an oven, or the like.

[Exposing Step]

Next, the coloring composition layer formed on the support is exposed, whereby a cured film is formed. Here, in a case of carrying out development in the later step, the coloring composition layer is preferably exposed in a pattern shape. For example, the coloring composition layer formed on the support can be subjected to patternwise exposure using, for example, an exposure device such as a stepper through a mask having a predetermined mask pattern. Thus, the exposed areas can be cured.

As the radiation (light) which can be used during the exposure, ultraviolet rays such as a g-ray and an i-ray (particularly preferably an i-ray) are preferably used. The irradiation dose (exposure dose) is, for example, preferably 30 to 1,500 mJ/cm², more preferably 50 to 1,000 mJ/cm², and most preferably 80 to 500 mJ/cm².

The film thickness of the cured film is preferably 1.0 μm or less, more preferably 0.1 to 0.9 μm, and still more preferably 0.2 to 0.8 μm. By setting the film thickness to 1.0 μm or less, high resolution and high adhesiveness are easily obtained.

[Developing Step]

Next, the unexposed area can be removed by development to form a colored pattern. The removal of the unexposed area by development can be carried out using a developer. Thus, the coloring composition layer on the unexposed area in the exposing step is eluted into the developer, and as a result, only a photocured area remains.

As the developer, an organic alkaline developer causing no damage on the underlying solid-state imaging device or a circuit is desirable.

The temperature of the developer is preferably for example, 20° C. to 30° C., and the development time is preferably 20 to 180 seconds.

Examples of the alkali agent used for the developer include organic alkaline compounds such as aqueous ammonia, ethylamine, diethylamine, dimethylethanolamine, tetramethylammonium hydroxide, tetraethylammonium hydroxide, tetrapropylammoniumhydroxide, tetrabutylammoniumhydroxide, benzyltrimethylammonium hydroxide, choline, pyrrole, piperidine, and 1,8-diazabicyclo-[5.4.0]-7-undecene. An aqueous alkaline solution obtained by diluting the alkali agent using pure water to have a concentration of 0.001% to 10% by mass, and preferably 0.01% to 1% by mass is preferably used as the developer.

In addition, an inorganic alkali may be used in a developer. Preferred examples of the inorganic alkali include sodium hydroxide, potassium hydroxide, sodium carbonate, sodium hydrogen carbonate, sodium silicate, and sodium metasilicate.

Moreover, a surfactant may also be used in the developer. Examples of the surfactant include the surfactants described as the above-mentioned coloring composition, with a non-ionic surfactant being preferable.

Incidentally, in a case where a developer formed of such an aqueous alkaline solution is used, it is preferable that washing (rinsing) using pure water is generally performed after development.

[Solid-State Imaging Device]

The solid-state imaging device of the present invention includes the cured film (the color filter, the light-shielding film, or the like) of the present invention as described above. The configuration of the solid-state imaging device of the present invention is not particularly limited as long as the solid-state imaging device is configured to include the cured film in the present invention and function as a solid-state imaging device. However, examples thereof include the following configurations.

The solid-state imaging device is configured to have a plurality of photodiodes constituting a light receiving area of the solid-state imaging device (a CCD image sensor, a CMOS image sensor, or the like), and a transfer electrode formed of polysilicon or the like”, on a support; have as a light-shielding film having openings only over the light receiving portion of the photodiode, on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film.

In addition, the solid-state imaging device may also be configured, for example, such that it has a light collecting means (for example, a microlens, which is the same hereinafter) on a device-protective film under a color filter (a side closer to the support), or has a light-collecting means on a color filter.

[Image Display Device]

The cured film (the color filter, the light-shielding film, or the like) of the present invention can be used for an image display device such as a liquid crystal display device and an organic electroluminescence display device.

The definition of display devices and the details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989), and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and for example, the present invention can be applied to liquid crystal display devices employing various systems described in the “Liquid Crystal Display Technology for Next Generation”.

The color filter of the present invention may be used for a liquid crystal display device using a color Thin Film Transistor (TFT) system. The liquid crystal display device using a color TFT system is described in, for example, “Color TFT Liquid Crystal Display (KYORITSU SHUPPAN Co., Ltd., published in 1996)”. Further, the present invention can be applied to a liquid crystal display device having an enlarged view angle, which uses an in-plane switching mode such as In Plane Switching (IPS), a pixel division system such as Multi-domain Vertical Alignment (MVA), or the like, or to Super-Twist Nematic (STN), Twisted Nematic (TN), Vertical Alignment (VA), on-chip spacer (OCS), fringe field switching (FFS), Reflective Optically Compensated Bend (R-OCB), and the like.

In addition, the color filter in the present invention can be provided to a Color-filter On Array (COA) system which is a bright and high-definition system. In the liquid crystal display device of the COA system, the characteristics required for a color filter layer need to include characteristics required for an interlayer insulating film, that is, a low dielectric constant and resistance to a peeling solution in some cases, in addition to the generally required characteristics as described above. Since the color filter of the present invention has excellent light resistance or the like, a liquid crystal display device in a COA system which has high resolution and excellent long-term durability can be provided. In addition, in order to satisfy the characteristics required for a low dielectric constant, a resin-coated film may be provided on the color filter layer.

These image display systems are described in, for example, p. 43 of “EL, PDP, and LCD Display—Technologies and Recent Trend in Market—(TORAY RESEARCH CENTER, Research Department, published in 2001)”, and the like.

The liquid crystal display device of the present invention is constituted with various members such as an electrode substrate, a polarizing film, a retardation film, a backlight, a spacer, and a view angle compensation film, in addition to the color filter in the present invention. The color filter of the present invention can be applied to a liquid crystal display device constituted with these known members. These members are described in, for example, “94 Market of Peripheral Materials And Chemicals of Liquid Crystal Display (Kentaro Shima, CMC Publishing Co., Ltd., published in 1994)” and “2003 Current Situation of Market Relating to Liquid Crystal and Prospects (Vol. 2) (Ryokichi Omote, Fuji Chimera Research Institute, Inc., published in 2003)”.

The backlight is described in SID Meeting Digest 1380 (2005) (A. Konno, et al.), December Issue of Monthly “Display”, Issued in December 2005, pp. 18 to 24 (Yasuhiro Shima) and pp. 25 to 30 (Takaaki Yagi) of the document, and the like.

[Infrared Sensor]

The infrared sensor of the present invention includes the cured film of the present invention. The configuration of the infrared sensor of the present invention is a configuration including the cured film of the present invention, and is not particularly limited as long as it is a configuration for functioning as a solid-state imaging device. However, examples thereof include the following configuration.

The infrared sensor is configured such that it has a plurality of photodiodes constituting a light receiving area of a solid-state imaging device (a CCD image sensor, an organic CMOS image sensor, or the like), and a transfer electrode formed of polysilicon or the like”, on a substrate, has a light-shielding film including tungsten or the like, having openings only over the light receiving portion of the photodiode, on the photodiodes and the transfer electrodes, has a device-protecting film formed of silicon nitride or the like, which is formed to cover the entire surface of the light-shielding film and the light receiving portion of the photodiodes, on the light-shielding film, and has the cured film of the present invention on the device-protective film.

In addition, the infrared sensor may be configured, for example, such that it has a light collecting means (for example, a microlens, which is the same hereinafter) under the cured film (a side closer to the substrate) of the present invention on a device-protective film, or has a light-collecting means on the cured film of the present invention.

### EXAMPLES

Hereinbelow, the present invention will be described in more detail with reference to Examples. However, the present invention is not limited to Examples shown below while not departing from the spirit of the present invention. Further, “%” and “part(s)” are based on mass unless otherwise specified.

<Manufacture of Titanium Black TB-1>

120 g of titanium oxide (“TTO-51N” trade name: manufactured by Ishihara Sangyo Kaisha Ltd.) having a BET specific surface area of 110 m²/g, 25 g of silica particles (“AEROSIL (registered trademark) 300”, manufactured by Evonik Industries) having a BET specific surface area of 300 m²/g, and 100 g of a dispersant (“Disperbyk 190” trade name: manufactured by BYK-Chemie) were weighed, and 71 g of ion exchange water. The mixture was treated for 30 minutes at a revolution rotation speed of 1,360 rpm and a spinning rotation speed of 1,047 rpm, using MAZERSTAR KK-400W manufactured by KURABO, thereby obtaining a uniform aqueous mixed solution. The aqueous mixed solution was filled into a quartz vessel and heated at 920° C. in an oxygen atmosphere, using a compact size rotary kiln (manufactured by K. K. MOTOYAMA). Then, the mixture was subjected to a nitridization reduction treatment by replacing the atmosphere with nitrogen and then flowing ammonia gas thereinto at the same temperature at the rate of 100 mL/min for 5 hours. After the completion of the treatment, recovered powder was pulverized in a mortar, thereby obtaining a titanium black TB-1 [dispersoid including titanium black particles and Si atoms] including Si atoms and having a specific surface area of 85 m²/g in the powder shape.

The titanium black particles in the titanium black TB-1 correspond to titanium oxynitride.

### Example 1

The components shown in Table 1 were mixed and then filtered using a nylon-made filter having a pore diameter of 0.45 μm (DFA4201NXEY, manufactured by Nihon Pall Ltd.) to prepare a coloring composition. More specifically, titanium black, a dispersant, and a solvent were first mixed using a stirrer (EUROSTAR manufactured by IKA) for 15 minutes and filtered in the same manner to obtain a dispersion. Then, the rest of the components were added to the dispersion and mixed to obtain a coloring composition.

The concentrations of the respective components are as follows.
Titanium black TB-1 25%
Dispersant D-1 7.5%
M: Polymerizable compound A-13.5%
B: Alkali-soluble resin B-1 3.0%
Photopolymerization initiator I-1 0.04%
Surfactant W-1 0.001%
Organic solvent (PGMEA) Balance

In this case, the content of the photopolymerization initiator was 0.1% with respect to the total solid content of the obtained coloring composition.

### Examples 2 and 3

In the same manner as in Example 1 except that the content of the photopolymerization initiator I-1 (with respect to the total solid content) was changed from 0.1% to 1% or 5%, a coloring composition was obtained.

### Examples 4 to 6

In the same manner as in Example 2 except that each of alkali-soluble resins B-2 to B-4 was used instead of the alkali-soluble resin B-1, a coloring composition was obtained.

### Examples 7 and 8

In the same manner as in Example 2 except that the content of the polymerizable compound (M) was reduced such that the mass ratio (B/M) of the alkali-soluble resin (B) to the polymerizable compound (M) was changed from 0.9 to 1.5 or 2.0, a coloring composition was obtained.

### Examples 9 to 16

In the same manner as in Examples 1 to 8 except that a photopolymerization initiator I-2 was used instead of the photopolymerization initiator I-1, a coloring composition was obtained.

### Example 17

In the same manner as in Example 2 except that the coloring agent was changed from the titanium black TB-1 to titanium nitride, a coloring composition was obtained.

In addition, “Titanium Nitride 50 nm” manufactured by Wako Pure Chemical Industries, Ltd. was used as the titanium nitride (the same hereinafter).

### Examples 18 and 19

In the same manner as in Example 10 except that the coloring agent was changed from the titanium black TB-1 to titanium nitride or niobium oxynitride, a coloring composition was obtained.

In addition, niobium oxynitride prepared in accordance with JP2012-96945A was used as the niobium oxynitride (the same hereinafter).

### Example 20

In the same manner as in Example 2 except that the coloring agent was changed from the titanium black TB-1 to niobium oxynitride, and the content of the polymerizable compound (M) was reduced such that the mass ratio (B/M) of the alkali-soluble resin (B) to the polymerizable compound (M) was changed from 0.9 to 1.9, a coloring composition was obtained.

### Examples 21 to 23

In the same manner as in Example 10 except that the coloring agent was changed from the titanium black TB-1 used singly to PR254 and PY139 used in combination, PG36 and PY139 used in combination, or PB15:6 and PV23 used in combination, a coloring composition was obtained.

The mass ratio (PR254/PY139) of PR254 to PY139, the mass ratio (PG36/PY139) of PG36 to PY139, and the mass ratio (PB15:6/PV23) of PB15:6 to PV23 were all set to 2/1.

In addition, PR254 represents Pigment Red 254, PY139 represents Pigment Yellow 139, PG36 represents Pigment Green 36, PB15:6 represents Pigment Blue 15:6, and PV23 represents Pigment Violet 23 (all manufactured by BASF).

### Examples 24 and 25

The components shown in Table 2 were mixed and then filtered using a nylon-made filter having a pore diameter of 0.45 μm (DFA4201NXEY, manufactured by Nihon Pall Ltd.) to prepare a coloring composition.

The concentrations of the respective components are as follows.
RDW-K01 or RDW-R56 (manufactured by Wako Pure Chemical Industries, Ltd.) 25%
M: polymerizable compound A-13.5%
B: alkali-soluble resin B-1 10.5%
Photopolymerization initiator I-1 0.395%
Surfactant W-1 0.001%
Organic solvent (PGMEA) Balance

In this case, the content of the photopolymerization initiator was 1.0% with respect to the total solid content of the obtained coloring composition.

### Examples 26 to 28

Furthermore, in the same manner as in Example 17 except that the polymerization inhibitor Ih-1 was added in such an amount that its contents with respect to the total solid content of a coloring composition corresponded to 0.003%, 0.004%, or 0.005%, a coloring composition was obtained.

### Examples 29 to 32

Furthermore, in the same manner as in Example 19 except that the polymerization inhibitor Ih-1 was added in such an amount that its contents with respect to the total solid content of a coloring composition corresponded to 0.010%, 0.020%, 0.030%, or 0.040%, a coloring composition was obtained.

### Example 33

Moreover, in the same manner as in Example 26 except that a photopolymerization initiator I-2 was used instead of the photopolymerization initiator I-1, and a polymerization inhibitor Ih-2 was used instead of the polymerization inhibitor Ih-1, a coloring composition was obtained.

### Examples 34 to 36

In the same manner as in Examples 29 to 32 except that the polymerization inhibitor was changed to a polymerization inhibitor Ih-3 (content with respect to the total solid content of the coloring composition: 0.003%) used singly; a polymerization inhibitor Ih-1(content with respect to the total solid content of the coloring composition: 0.0015%) and a polymerization inhibitor Ih-2 (content with respect to the total solid content of the coloring composition: 0.0015%) used in combination; and a polymerization inhibitor Ih-1 (content with respect to the total solid content of the coloring composition: 0.0015%) and a polymerization inhibitor Ih-3 (content with respect to the total solid content of the coloring composition: 0.0015%) used in combination, coloring compositions were obtained.

### Example 37

In the same manner as in Examples 26 to 28 except that the polymerization inhibitor was changed to a polymerization inhibitor Ih-1 (content with respect to the total solid content of the coloring composition: 0.0015%) and a polymerization inhibitor Ih-3 (content with respect to the total solid content of the coloring composition: 0.0015%) used in combination, a coloring composition was obtained.

### Example 38

In the same manner as in Example 37 except that the coloring agent was changed to titanium black TB-1, a coloring composition was obtained.

### Example 39

In the same manner as in Example 37 except that the solvent was changed to PGMEA and cyclohexanone used in combination, a coloring composition was obtained.

In addition, the mass ratio (PGMEA/cyclohexanone) of PGMEA to cyclohexanone was set to 50/50.

### Example 40

In the same manner as in Example 37 except that the coloring agent was changed to niobium oxynitride, and the solvent was changed to PGMEA and MFG used in combination, a coloring composition was obtained.

In addition, the mass ratio (PGMEA/MFG) of PGMEA to MFG was set to 80/20.

### Comparative Examples 1 and 2

In the same manner as in Example 2 except that the photopolymerization initiator I-3 or I-4 was used instead of the photopolymerization initiator I-1, a coloring composition was obtained.

### Comparative Example 3

In the same manner as in Example 24 except that the photopolymerization initiator I-3 was used instead of the photopolymerization initiator I-1, a coloring composition was obtained.

### Comparative Example 4

In the same manner as in Example 25 except that the photopolymerization initiator I-4 was used instead of the photopolymerization initiator I-1, a coloring composition was obtained.

<Evaluation>

A support having an epoxy resin layer formed on a glass substrate (Eag1eXG, manufactured by Corning Inc.) using an epoxy resin (JER-827, manufactured by Japan Epoxy Resins Co., Ltd.) was prepared.

The obtained coloring composition was applied onto the support by a spray method such that the thickness reached 3.0 μm. Then, exposure was carried out at an exposure dose of 1,000 mJ/cm², using an i-ray stepper exposure device FPA-3000i5+ (manufactured by Canon Inc.). After the exposure, a heating treatment was carried out in a low-temperature (50° C.) environment for 120 minutes, using a clean oven CLH-21CDH (manufactured by Koyo Thermo Systems Co., Ltd.) to obtain an evaluation substrate.

Next, evaluations which will be described below were carried out. The results are shown in Tables 1 and 2. Further, measurement of light transmittance was carried out in an environment at 25° C.

(Heat Resistance)

For the obtained evaluation substrate, the light transmittance in a wavelength range of 400 to 700 nm was measured using a spectrophotometer of an ultraviolet-visible-near-infrared spectrophotometer UV 3600 (manufactured by Shimadzu Corporation) (reference: glass substrate).

Then, the evaluation substrate was subjected to a test in which it as was heated on a hot plate in an environment at 260° C. for 5 minutes, and thereafter, the light transmittance was measured in the same manner as before the test.

The light transmittance variation between before and after the test (in a case where the light transmittance before the test was defined as T0 and the light transmittance after the test was defined as T1, a value represented by formula |T0−T1|) in the entire range at 400 to 700 nm was evaluated in accordance with the following standard. A or B can be evaluated to show that curing proceeds by heating at a low temperature.

A: The light transmittance variation between before and after the test is 5% or less

B: The light transmittance variation between before and after the test is more than 5% and 10% or less

C: The light transmittance variation between before and after the test is more than 10% and 20% or less

D: The light transmittance variation between before and after the test is more than 20%

(Light Resistance)

The obtained evaluation substrate was subjected to a test in which it was irradiated at an illuminance of 1.0×10⁵ lux for 50 hours, and in the same manner as in the evaluation of the heat resistance, the light transmittance variation between before and after the test in the entire range at 400 to 700 nm was evaluated in accordance with the following standard. A or B can be evaluated to show that curing proceeds by heating at a low temperature.

A: The light transmittance variation between before and after the test is 5% or less

B: The light transmittance variation between before and after the test is more than 5% and 10% or less

C: The light transmittance variation between before and after the test is more than 10% and 20% or less

D: The light transmittance variation between before and after the test is more than 20%

(Solvent Resistance)

The obtained evaluation substrate was subjected to a test in which it was immersed in acetone in a room-temperature environment for 5 minutes, and in the same manner as in the evaluation of the heat resistance, the light transmittance variation between before and after the test in the entire range at 400 to 700 nm was evaluated in accordance with the following standard. A or B can be evaluated to show that curing proceeds by heating at a low temperature.

A: The light transmittance variation between before and after the test is 5% or less

B: The light transmittance variation between before and after the test is more than 5% and 10% or less

C: The light transmittance variation between before and after the test is more than 10% and 20% or less

D: The light transmittance variation between before and after the test is more than 20%

(Moisture Resistance)

The obtained evaluation substrate was subjected to a test in which it was left to stand in a moisture resistance tester for 72 hours at a temperature of 85° C. and a relative humidity of 80%, and in the same manner as in the evaluation of the heat resistance, the light transmittance variation (unit: %) between before and after the test in the entire range at 400 to 700 nm was determined. A smaller light transmittance variation can be evaluated to show that curing proceeds by heating at a low temperature. In addition, the measurement of the light transmittance was carried out after being left to stand for 72 hours as above, and then exposed to an environment at a temperature of 25° C. and a relatively humidity of 50% for 4 hours.

(Adhesiveness)

The obtained coloring composition was applied onto the above-mentioned support by a spray method such that the thickness reached 3.0 μm. Then, exposure was carried out through a linear 300-μm mask (with a width of 300 μm and a length of 4 mm) at an exposure dose of 1,000 mJ/cm², using an i-ray stepper exposure device FPA-3000i5+ (manufactured by Canon Inc.). After the exposure, a heating treatment was carried out in a low-temperature (50° C.) environment for 120 minutes, using a clean oven CLH-21CDH (manufactured by Koyo Thermo Systems Co., Ltd.), thereby obtaining an evaluation substrate for evaluation of adhesiveness.

The evaluation substrate was placed on a horizontal rotary table of a spin/shower developing machine (Model DW-30, manufactured by Chemitronics Co., Ltd.), and subjected to puddle development in an environment at 23° C. for 60 seconds, using CD-2000 (manufactured by Fujifilm Electronic Materials Co., Ltd.), and evaluation was carried out in accordance with the following standard. A, B, or C can be evaluated to show that curing proceeds by heating at a low temperature.

A: Peeling of patterns was not observed.

B: Peeling of patterns was slightly observed.

C: Peeling of patterns was observed in some parts.

D: Patterns were peeled and disappeared.

(Linearity)

A support having an epoxy resin layer formed on a glass substrate EagleXG (manufactured by Corning Inc.) using an epoxy resin (JER-827, manufactured by Japan Epoxy Resins Co., Ltd.) was prepared.

The obtained coloring composition was applied onto the support by a spray method such that the film thickness reached 3.0 μm.

Then, exposure was carried out with selection of a wavelength at 365 nm, through a mask with a line/space pattern having 20 μm patterns, at various exposure doses of 50 to 1,200 mJ/cm², using an i-ray stepper exposure device FPA-3000i5+ (manufactured by Canon Inc.). After the exposure, a heating treatment was carried out in a low-temperature (50° C.) environment for 120 minutes, using a clean oven CLH-21CDH (manufactured by KoyoThermo Systems Co., Ltd.), to obtain an evaluation substrate for evaluation of linearity.

Thereafter, the support having the exposed coating film formed thereon was placed on a horizontal rotary table of a spin/shower developing machine (Model DW-30, manufactured by Chemitronics Co., Ltd.), and subjected to puddle development in an environment at 23° C. for 60 seconds, using CD-2000 (manufactured by Fujifilm Electronic Materials Co., Ltd.), thereby forming a colored pattern on the support.

The support having the colored pattern formed thereon was fixed on the horizontal rotary table in a vacuum chuck system, and then, while the support was rotated under the condition of a rotation speed of 50 rpm, pure water was supplied thereonto from a spray nozzle in the form of a shower from the position above the rotation center, so as to carry out a rinsing treatment. Thereafter, the support was spray-dried.

Thereafter, the size of the colored pattern was measured using a length-measuring SEM “S-9260A” (manufactured by HITACHI High-Technologies Corporation). The exposure dose at which the pattern size became 20 μm was defined as an optimal exposure dose. In the observation and measurement of a 20 μm (1:1) line-and-space pattern resolved with the optimal exposure dose, the line width was observed and measured at arbitrary points upon observation from the upper part of the pattern by SEM, and the measurement deviation was evaluated as 3σ. A smaller value thereof indicates better performance.

TABLE 1

| | | | | B: | | | | |
|---|---|---|---|---|---|---|---|---|
| | | | M: | Alkali-soluble | I: | | Organic | |
| | Coloring agent | | Polymerizable | resin (acid | Photopolymerization | | solvent | B/M |
| | (mass ratio) | Dispersant | compound | value) | initiator (content) | Surfactant | (mass ratio) | ratio |
| Example 1 | TB-1 | D-1 | A-1 | B-1 (31.6) | I-1 (0.1%) | W-1 | PGMEA | 0.9 |
| Example 2 | TB-1 | D-1 | A-1 | B-1 (31.6) | I-1 (1%) | W-1 | PGMEA | 0.9 |
| Example 3 | TB-1 | D-1 | A-1 | B-1 (31.6) | I-1 (5%) | W-1 | PGMEA | 0.9 |
| Example 4 | TB-1 | D-1 | A-1 | B-2 (31.5) | I-1 (1%) | W-1 | PGMEA | 0.9 |
| Example 5 | TB-1 | D-1 | A-1 | B-3 (29.6) | I-1 (1%) | W-1 | PGMEA | 0.9 |
| Example 6 | TB-1 | D-1 | A-1 | B-4 (112.8) | I-1 (1%) | W-1 | PGMEA | 0.9 |
| Example 7 | TB-1 | D-1 | A-1 | B-1 (31.6) | I-1 (1%) | W-1 | PGMEA | 1.5 |
| Example 8 | TB-1 | D-1 | A-1 | B-1 (31.6) | I-1 (1%) | W-1 | PGMEA | 2.0 |
| Example 9 | TB-1 | D-1 | A-1 | B-1 (31.6) | I-2 (0.1%) | W-1 | PGMEA | 0.9 |
| Example 10 | TB-1 | D-1 | A-1 | B-1 (31.6) | I-2 (1%) | W-1 | PGMEA | 0.9 |
| Example 11 | TB-1 | D-1 | A-1 | B-1 (31.6) | I-2 (5%) | W-1 | PGMEA | 0.9 |
| Example 12 | TB-1 | D-1 | A-1 | B-2 (31.5) | I-2 (1%) | W-1 | PGMEA | 0.9 |
| Example 13 | TB-1 | D-1 | A-1 | B-3 (29.6) | I-2 (1%) | W-1 | PGMEA | 0.9 |
| Example 14 | TB-1 | D-1 | A-1 | B-4 (112.8) | I-2 (1%) | W-1 | PGMEA | 0.9 |
| Example 15 | TB-1 | D-1 | A-1 | B-1 (31.6) | I-2 (1%) | W-1 | PGMEA | 1.5 |
| Example 16 | TB-1 | D-1 | A-1 | B-1 (31.6) | I-2 (1%) | W-1 | PGMEA | 2.0 |
| Example 17 | Titanium nitride | D-1 | A-1 | B-1 (31.6) | I-1 (1%) | W-1 | PGMEA | 0.9 |
| Example 18 | Titanium nitride | D-1 | A-1 | B-1 (31.6) | I-2 (1%) | W-1 | PGMEA | 0.9 |
| Example 19 | Niobium | D-1 | A-1 | B-1 (31.6) | I-2 (1%) | W-1 | PGMEA | 0.9 |
| | oxynitride | | | | | | | |
| Example 20 | Niobium | D-1 | A-1 | B-1 (31.6) | I-1 (1%) | W-1 | PGMEA | 1.9 |
| | oxynitride | | | | | | | |
| Example 21 | PR254/PY139 | D-1 | A-1 | B-1 (31.6) | I-2 (1%) | W-1 | PGMEA | 0.9 |
| | (2/1) | | | | | | | |
| Example 22 | PG36/PY139 | D-1 | A-1 | B-1 (31.6) | I-2 (1%) | W-1 | PGMEA | 0.9 |
| | (2/1) | | | | | | | |
| Example 23 | PB15:6/PV23 | D-1 | A-1 | B-1 (31.6) | I-2 (1%) | W-1 | PGMEA | 0.9 |
| | (2/1) | | | | | | | |

| | Ih: Polymerization | Ih/I | Heat | Light | Solvent | Moisture | | |
|---|---|---|---|---|---|---|---|---|
| | inhibitor (content) | ratio | resistance | resistance | resistance | resistance | Adhesiveness | Linearity |
| Example 1 | — | 0 | B | B | B | 9 | B | 3.5 |
| Example 2 | — | 0 | A | A | A | 8 | B | 3.2 |
| Example 3 | — | 0 | A | A | A | 4 | A | 3.3 |
| Example 4 | — | 0 | A | A | A | 3 | A | 3.4 |
| Example 5 | — | 0 | A | A | A | 4 | A | 3.5 |
| Example 6 | — | 0 | A | A | A | 4 | B | 3.2 |
| Example 7 | — | 0 | A | A | A | 4 | A | 3.3 |
| Example 8 | — | 0 | A | A | A | 4 | A | 3.5 |
| Example 9 | — | 0 | B | B | B | 9 | C | 3.1 |
| Example 10 | — | 0 | A | A | A | 8 | C | 3.8 |
| Example 11 | — | 0 | A | A | A | 4 | B | 3.2 |
| Example 12 | — | 0 | A | A | A | 3 | B | 3.3 |
| Example 13 | — | 0 | A | A | A | 4 | B | 3.4 |
| Example 14 | — | 0 | A | A | A | 3 | C | 3.5 |
| Example 15 | — | 0 | A | A | A | 3 | B | 3.4 |
| Example 16 | — | 0 | A | A | A | 3 | B | 3.5 |
| Example 17 | — | 0 | A | A | A | 2 | A | 3.5 |
| Example 18 | — | 0 | A | A | A | 2 | A | 3.6 |
| Example 19 | — | 0 | A | A | A | 0 | A | 3.4 |
| Example 20 | — | 0 | A | A | A | 0 | A | 3.5 |
| Example 21 | — | 0 | A | A | A | 7 | B | 3.7 |
| Example 22 | — | 0 | A | A | A | 8 | B | 3.5 |
| Example 23 | — | 0 | A | A | A | 7 | B | 3.5 |

TABLE 2

| | | | M: | | I: | | |
|---|---|---|---|---|---|---|---|
| | Coloring agent | | Polymerizable | B: Alkali-soluble | Photopolymerization | | Organic solvent (mass |
| | (mass ratio) | Dispersant | compound | resin (acid value) | initiator (content) | Surfactant | ratio) |
| Example 24 | RDW-K01 | — | A-1 | B-1 (31.6) | I-1 (1%) | W-1 | PGMEA |
| Example 25 | RDW-R56 | — | A-1 | B-1 (31.6) | I-1 (1%) | W-1 | PGMEA |
| Example 26 | Titanium nitride | D-1 | A-1 | B-1 (31.6) | I-1 (1%) | W-1 | PGMEA |
| Example 27 | Titanium nitride | D-1 | A-1 | B-1 (31.6) | I-1 (1%) | W-1 | PGMEA |
| Example 28 | Titanium nitride | D-1 | A-1 | B-1 (31.6) | I-1 (1%) | W-1 | PGMEA |
| Example 29 | Niobium | D-1 | A-1 | B-1 (31.6) | I-2 (1%) | W-1 | PGMEA |
| | oxynitride | | | | | | |
| Example 30 | Niobium | D-1 | A-1 | B-1 (31.6) | I-2 (1%) | W-1 | PGMEA |
| | oxynitride | | | | | | |
| Example 31 | Niobium | D-1 | A-1 | B-1 (31.6) | I-2 (1%) | W-1 | PGMEA |
| | oxynitride | | | | | | |
| Example 32 | Niobium | D-1 | A-1 | B-1 (31.6) | I-2 (1%) | W-1 | PGMEA |
| | oxynitride | | | | | | |
| Example 33 | Titanium nitride | D-1 | A-1 | B-1 (31.6) | I-2 (1%) | W-1 | PGMEA |
| Example 34 | Niobium | D-1 | A-1 | B-1 (31.6) | I-2 (1%) | W-1 | PGMEA |
| | oxynitride | | | | | | |
| Example 35 | Niobium | D-1 | A-1 | B-1 (31.6) | I-2 (1%) | W-1 | PGMEA |
| | oxynitride | | | | | | |
| Example 36 | Niobium | D-1 | A-1 | B-1 (31.6) | I-2 (1%) | W-1 | PGMEA |
| | oxynitride | | | | | | |
| Example 37 | Titanium nitride | D-1 | A-1 | B-1 (31.6) | I-1 (1%) | W-1 | PGMEA |
| Example 38 | TB-1 | D-1 | A-1 | B-1 (31.6) | I-1 (1%) | W-1 | PGMEA |
| Example 39 | Titanium nitride | D-1 | A-1 | B-1 (31.6) | I-1 (1%) | W-1 | PGMEA/ |
| | | | | | | | cyclohexanone |
| | | | | | | | (50/50) |
| Example 40 | Niobium | D-1 | A-1 | B-1 (31.6) | I-1 (1%) | W-1 | PGMEA/MFG (80/20) |
| | oxynitride | | | | | | |
| Comparative | TB-1 | D-1 | A-1 | B-1 (31.6) | I-3 (1%) | W-1 | PGMEA |
| Example 1 | | | | | | | |
| Comparative | TB-1 | D-1 | A-1 | B-1 (31.6) | I-4 (1%) | W-I | PGMEA |
| Example 2 | | | | | | | |
| Comparative | RDW-K01 | — | A-1 | B-1 (31.6) | I-3 (1%) | W-1 | PGMEA |
| Example 3 | | | | | | | |
| Comparative | RDW-R56 | — | A-1 | B-1 (31.6) | I-4 (1%) | W-1 | PGMEA |
| Example 4 | | | | | | | |

| | B/M | Ih: Polymerization | | Heat | Light | Solvent | Moisture | | |
|---|---|---|---|---|---|---|---|---|---|
| | ratio | inhibitor (content) | Ih/I ratio | resistance | resistance | resistance | resistance | Adhesiveness | Linearity |
| Example 24 | 0.9 | — | 0 | A | A | A | 7 | B | 3.4 |
| Example 25 | 0.9 | — | 0 | A | A | A | 9 | B | 3.4 |
| Example 26 | 0.9 | Ih-1 (0.003%) | 0.003 | A | A | A | 2 | A | 1.7 |
| Example 27 | 0.9 | Ih-1 (0.004%) | 0.004 | A | A | A | 2 | A | 1.8 |
| Example 28 | 0.9 | Ih-1 (0.005%) | 0.005 | A | A | A | 2 | A | 1.8 |
| Example 29 | 0.9 | Ih-1 (0.010%) | 0.010 | A | A | A | 0 | A | 1.9 |
| Example 30 | 0.9 | Ih-1 (0.020%) | 0.020 | A | A | A | 0 | A | 2.4 |
| Example 31 | 0.9 | Ih-1 (0.030%) | 0.030 | A | A | A | 0 | A | 2.3 |
| Example 32 | 0.9 | Ih-1 (0.040%) | 0.040 | A | A | A | 0 | B | 2.3 |
| Example 33 | 0.9 | Ih-2 (0.003%) | 0.003 | A | A | A | 3 | A | 1.8 |
| Example 34 | 0.9 | Ih-3 (0.003%) | 0.003 | A | A | A | 0 | A | 2.9 |
| Example 35 | 0.9 | Ih-1 (0.0015%) | 0.003 | A | A | A | 0 | A | 1.4 |
| | | Ih-2 (0.0015%) | | | | | | | |
| Example 36 | 0.9 | Ih-1 (0.0015%) | 0.003 | A | A | A | 0 | A | 0.9 |
| | | Ih-3 (0.0015%) | | | | | | | |
| Example 37 | 0.9 | Ih-1 (0.0015%) | 0.003 | A | A | A | 2 | A | 0.8 |
| | | Ih-3 (0.0015%) | | | | | | | |
| Example 38 | 0.9 | Ih-1 (0.0015%) | 0.003 | A | A | A | 4 | A | 0.9 |
| | | Ih-3 (0.0015%) | | | | | | | |
| Example 39 | 0.9 | Ih-1 (0.0015%) | 0.003 | A | A | A | 0 | A | 0.3 |
| | | Ih-3 (0.0015%) | | | | | | | |
| Example 40 | 0.9 | Ih-1 (0.0015%) | 0.003 | A | A | A | 0 | A | 0.4 |
| | | Ih-3 (0.0015%) | | | | | | | |
| Comparative | 0.9 | — | 0 | C | C | C | 13 | D | 5.2 |
| Example 1 | | | | | | | | | |
| Comparative | 0.9 | — | 0 | C | C | C | 14 | D | 6.5 |
| Example 2 | | | | | | | | | |
| Comparative | 0.9 | — | 0 | C | C | C | 14 | D | 6.5 |
| Example 3 | | | | | | | | | |
| Comparative | 0.9 | — | 0 | C | C | C | 16 | D | 6.5 |
| Example 4 | | | | | | | | | |

The respective components used in Examples and Comparative Examples are as follows.

(Dispersant)

The structural formula of the dispersant D-1 is as follow.

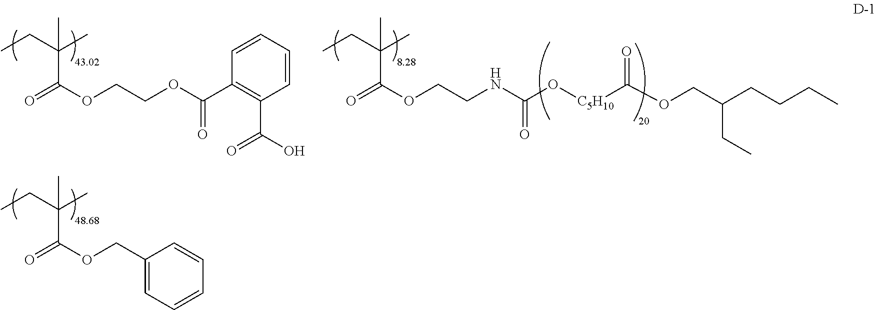

(M: Polymerizable Compound)

The structural formula of the polymerizable compound A-1 is as follows.

In addition, the mixing ratio (mass ratio) of the respective monomers in the polymerizable compound A-1 is 7:3 in the order starting from the left. The SP value of the polymerizable compound A-1 was 10.62.

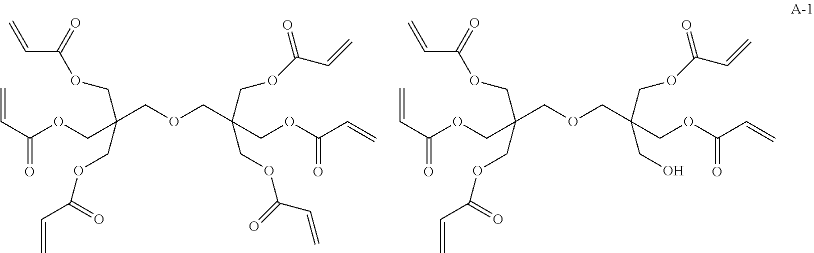

(B: Alkali-Soluble Resin)

The structural formulae of the alkali-soluble resins B-1 to B-4 are as follows.

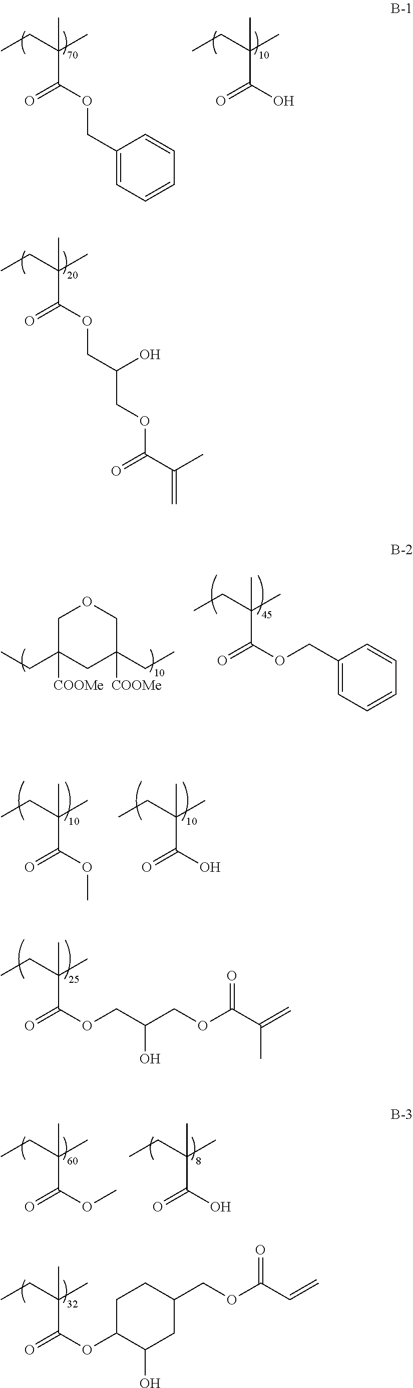

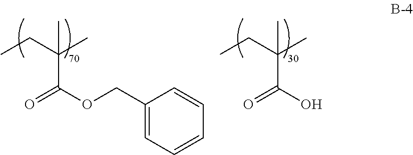

(I: Photopolymerization Initiator)

The structural formulae of the photopolymerization initiators I-1 to I-4 are as follows.

Furthermore, I-1 is IRGACURE-OXE03 (manufactured by BASF), I-2 is NCI-831 (manufactured by ADEKA Corporation), I-3 is IRGACURE-OXE01 (manufactured by BASF), and I-4 is IRGACURE-OXE02 (manufactured by BASF).

In addition, the absorbances at a wavelength of 340 nm of the solutions in which the photopolymerization initiators were dissolved in acetonitrile at a concentration 0.001% by mass were I-1: 0.50, I-2: 0.48, I-3: 0.41, and I-4: 0.44, respectively.

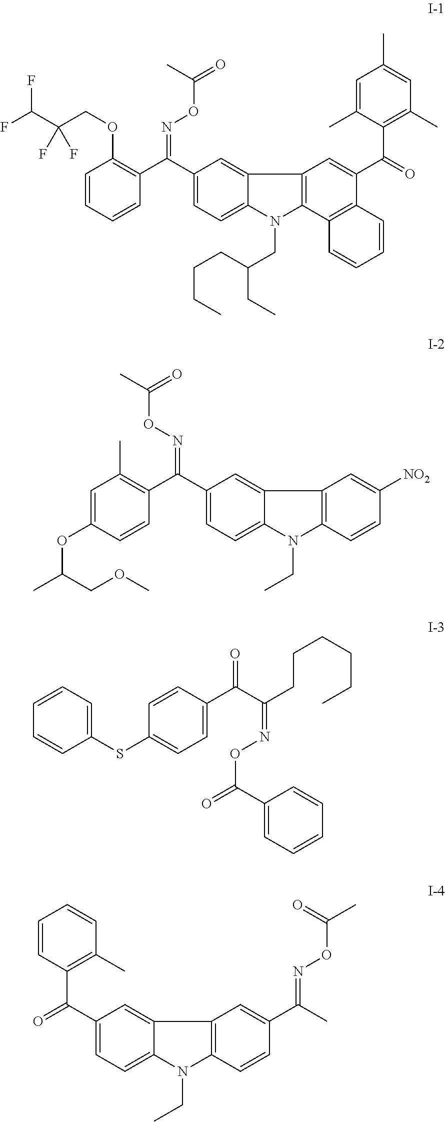

(Surfactant)

Surfactant W-1: Compound represented by the following formula (weight-average molecular weight (Mw)=15,311)

Here, in the following formula, the amounts of the structural units represented by (A) and (B) in the formula are 62% by mole and 38% by mole, respectively. In the structural unit represented by Formula (B), a, b, and c satisfy the relationship of a+c=14 and b=17.

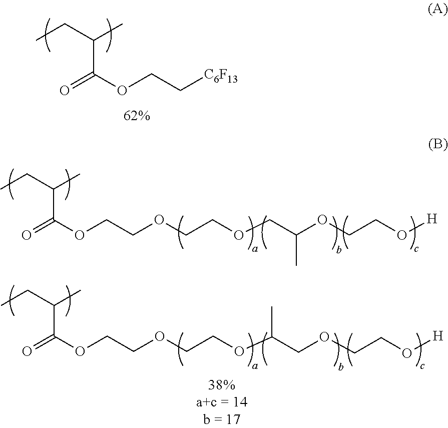

(Ih: Polymerization Inhibitor)

The polymerization inhibitors Ih-1 to Ih-3 are as follows.

Ih-1: 4-Methoxyphenol

Ih-2: 2,6-Di-tert-butyl-4-methylphenol

Ih-3: 4-Hydroxy-2,2,6,6-tetramethylpiperidin-1-oxyl free radical

As clear from the results shown in Tables 1 and 2, it could be seen that in Examples 1 to 40 in which the photopolymerization initiator I-1 or I-2 was used, the curing proceeded even with heating at a low temperature (50° C.).

To the contrary, in Comparative Examples 1 to 4 in which the photopolymerization initiator I-3 or I-4 was used, the curing was insufficient with heating at a low temperature (50° C.).

In addition, in comparison of Examples 1 to 8 with Examples 9 to 16, it is shown that the adhesiveness in Examples 1 to 8 in which the photopolymerization initiator I-1 was used tended to better than that in Examples 9 to 16 in which the photopolymerization initiator I-2 was used.

Moreover, in comparison of Examples 1 to 25 in which a polymerization inhibitor was not contained, the moisture resistance in Examples 17 to 20 in which titanium nitride or niobium oxynitride was used as the coloring agent was better than that in Examples 1 to 16 and 21 to 25 in which coloring agents were used, and the moisture resistance in Examples 19 and 20 in which niobium oxynitride was used was better.

These were the same results as in Examples 26 to 34 in which one kind of polymerization initiator was used.

Moreover, in comparison of Examples 26 to 32 in which the polymerization inhibitor Ih-1 was used, the linearity in Examples 26 to 29 in which the content of the polymerization inhibitor was 0.003% to 0.010% was superior to that in Examples 30 to 32 in which the content was 0.020% to 0.040%.

In addition, with regard to Examples 26 to 29, the linearity in Examples 26 to 28 in which the content of the polymerization inhibitor was less than 0.010% was superior to that in Example 29 in which the content was 0.010%.

In addition, in comparison of Examples 26 to 32 in which the polymerization inhibitor Ih-1 was used, the adhesiveness in Examples 26 to 31 in which the Ih/I ratio was in the range of 0.003 to 0.030 was superior to that of Example 32 in which the Ih/I ratio was 0.040.

Furthermore, in comparison of Examples 26 and 33 with 34, in which one kind of polymerization inhibitor was used in the same amount (0.003%), the linearity in Examples 26 and 33 in which the phenol-based polymerization inhibitors Ih-1 and Ih-2 were used was better than that in Example 34 in which the hindered amine-based polymerization inhibitor Ih-3 was used.

Moreover, in comparison of Example 26 with Examples 35 to 38, in which the polymerization inhibitor was used in the same amount (0.003%), the linearity in Examples 35 to 38 in which the polymerization inhibitor Ih-1 and the polymerization inhibitor Ih-2 or Ih-3 were used in combination was better than that in Example 26 in which only the polymerization inhibitor Ih-1 was used.

In addition, in comparison of Examples 35 to 38, the linearity in Examples 36 to 38 in which the phenol-based polymerization inhibitor (Ih-1) and the hindered amine-based polymerization inhibitor (Ih-3) were used in combination was better than that in Example 35 in which only the phenol-based polymerization inhibitor (Ih-1 and Ih-2) was used in combination.

Furthermore, in comparison of Examples 36 to 40 in which the phenol-based polymerization inhibitor (Ih-1) and the hindered amine-based polymerization inhibitor (Ih-3) were used in combination, the linearity in Examples 39 and 40 in which two kinds of organic solvents were used in combination was better than that in Examples 36 and 38 in which only one kind of organic solvent was used in combination.

### Examples 41 to 47

(Preparation of Fine Particles Containing Silver-Tin Alloy)

Hereinafter, in accordance with the method described in JP4696098B, a dispersion liquid containing a silver-tin alloy was manufactured.

First, 10.0 g of a tin colloidal dispersion liquid (with an average primary particle diameter of 20 nm and a solid content of 10% by mass, manufactured by Sumitomo Osaka Cement Co., Ltd.) was collected and pure water was added thereto, thereby manufacturing 300 mL of a liquid A.

Furthermore, 23.0 g of glucose, 2.0 g of tartaric acid, and 40.0 g of ethanol were added to pure water, thereby manufacturing a liquid B having a total mass of 500 g.

In addition, 15.0 g of silver nitrate and 50.0 mL of concentrated aqueous ammonia (NH₃ concentration of 28% by mass) were added to pure water, thereby manufacturing a liquid C having a total mass of 500 g.

Subsequently, the liquid B and the liquid C were mixed to afford a liquid D, and 50.0 g of a fraction was collected from the liquid D, and added to the liquid A, thereby obtaining a mixed solution. While stirring this mixed solution, 10 g of a 0.05 N aqueous sodium hydroxide solution was slowly added dropwise to this mixed solution, and further, 60.0 g of a 10% by mass aqueous tartaric acid solution was added thereto. Then, this mixed solution was stirred for 1 hour using a magnetic stirrer, and then washed by centrifugation, thereby obtaining a dispersion liquid with a particle (solid) concentration of 15% by mass.

The obtained dispersion liquid was dried using a spray dryer (MDL-050B, manufactured by Fujisaki Electric Co., Ltd.) to obtain fine particles containing a silver-tin alloy. The fine particles were manufactured by increasing the amount through the repetition of the treatment.

Furthermore, the dispersion liquid was filtered to separate the particles, and the separated particles were dried to manufacture a powder sample. A generated phase in the manufactured powder sample was identified by a powder X-ray diffraction method, and thus, it was confirmed that a silver-tin alloy (Ag₃Sn and/or Ag₄Sn) and silver are present.

(Preparation of Pigment Dispersion)

The fine particles containing a silver-tin alloy, a dispersant, and an organic solvent were mixed for 15 minutes, using a stirrer (EUROSTAR manufactured by IKA) to obtain a dispersion. Next, the obtained dispersion was subjected to a dispersion treatment, using an NPM Pilot (manufactured by Shinmaru Enterprises Corp.) under the following conditions, thereby obtaining a pigment dispersion. Further, the ratio (D/P) of the dispersant (D) to the fine particles containing a silver-tin alloy (P) was set to 0.3.

(Dispersion Conditions)
Bead diameter: φ 0.05 mm (manufactured by NIKKATO, zirconia beads, YTZ)
Beads filling rate: 65% by volume
Mill circumferential speed: 13 m/sec
Separator circumferential speed: 13 m/s
Amount of mixed solution to be subjected to dispersion treatment: 15 kg
Circulation flow rate (pump feed rate): 90 kg/hour
Temperature of liquid being treated: 19° C. to 21° C.
Cooling water: water
Treatment time: approximately 22 hours

A coloring composition of Example 41 shown in Table 3 was prepared in the same manner as in Example 1, using the obtained dispersion. The concentrations of the respective components are as follows.
Fine particles containing a silver-tin alloy 25%
Dispersant D-1 7.5%
M: Polymerizable compound A-13.5%
B: Alkali-soluble resin B-1 3.0%
Photopolymerization initiator I-1 0.04%
Surfactant W-1 0.001%
Organic solvent (PGMEA) Balance

In this case, the content of the photopolymerization initiator was 0.1% with respect to the total solid content of the obtained coloring composition.

Furthermore, in the same manner as in Example 41 except that the alkali-soluble resin and/or the photopolymerization initiator was changed (including the change in the content), the coloring compositions of Examples 42 to 47 shown in Table 3 were prepared.

In the same manner as in Examples 1 to 40 using the obtained coloring compositions of Examples 41 to 47, evaluations were carried out (however, the evaluation of the linearity was excluded). The results are shown in Table 3.

TABLE 3

| | | | | B: | | | | |
|---|---|---|---|---|---|---|---|---|
| | | | M: | Alkali-soluble | | | | |
| | | | Polymerizable | resin (acid | I: Photopolymerization | | Organic | B/M |
| | Coloring agent | Dispersant | compound | value) | initiator (content) | Surfactant | solvent | ratio |
| Example | Fine particles | D-1 | A-1 | B-1 (31.6) | I-1 (0.1%) | W-1 | PGMEA | 0.9 |
| 41 | containing silver-tin | | | | | | | |
| | alloy | | | | | | | |
| Example | Fine particles | D-1 | A-1 | B-1 (31.6) | I-1 (1%) | W-1 | PGMEA | 0.9 |
| 42 | containing silver-tin | | | | | | | |
| | alloy | | | | | | | |
| Example | Fine particles | D-1 | A-1 | B-1 (31.6) | I-1 (5%) | W-1 | PGMEA | 0.9 |
| 43 | containing silver-tin | | | | | | | |
| | alloy | | | | | | | |
| Example | Fine particles | D-1 | A-1 | B-1 (31.6) | I-2 (5%) | W-1 | PGMEA | 0.9 |
| 44 | containing silver-tin | | | | | | | |
| | alloy | | | | | | | |
| Example | Fine particles | D-1 | A-1 | B-2 (31.5) | I-1 (5%) | W-1 | PGMEA | 0.9 |
| 45 | containing silver-tin | | | | | | | |
| | alloy | | | | | | | |
| Example | Fine particles | D-1 | A-1 | B-3 (29.6) | I-1 (5%) | W-1 | PGMEA | 0.9 |
| 46 | containing silver-tin | | | | | | | |
| | alloy | | | | | | | |
| Example | Fine particles | D-1 | A-1 | B-4 (112.8) | I-1 (5%) | W-1 | PGMEA | 0.9 |
| 47 | containing silver-tin | | | | | | | |
| | alloy | | | | | | | |

| | Ih: Polymerization | Ih/I | Heat | Light | Solvent | Moisture | | |
|---|---|---|---|---|---|---|---|---|
| | inhibitor (content) | ratio | resistance | resistance | resistance | resistance | Adhesiveness | Linearity |
| Example | — | 0 | B | B | B | 9 | B | — |
| 41 | | | | | | | | |
| Example | — | 0 | B | A | A | 8 | B | — |
| 42 | | | | | | | | |
| Example | — | 0 | B | A | A | 4 | A | — |
| 43 | | | | | | | | |
| Example | — | 0 | B | A | A | 3 | A | — |
| 44 | | | | | | | | |
| Example | — | 0 | B | A | A | 4 | A | — |
| 45 | | | | | | | | |
| Example | — | 0 | B | A | A | 4 | A | — |
| 46 | | | | | | | | |
| Example | — | 0 | B | A | A | 4 | B | — |
| 47 | | | | | | | | |

As shown in Table 3, also in Examples 41 to 47 in which fine particles containing a silver-tin alloy were used as the coloring agent, it could be seen that the curing proceeded even with heating at a low temperature (50° C.) in the same manner as in Examples 1 to 40.

### Example 4-A

Next, in the same manner as in Example 4 except that a support not having an epoxy resin layer formed on a glass substrate (that is, a glass substrate alone) was used as the support, an evaluation substrate (hereinafter also referred to as “Example 4-A”) for evaluation of the adhesiveness was obtained.

The evaluation substrate was placed on a horizontal rotary table of a spin/shower developing machine (Model DW-30, manufactured by Chemitronics Co., Ltd.), and subjected to puddle development in an environment at 23° C. for 60 seconds, using CD-2000 (manufactured by Fujifilm Electronic Materials Co., Ltd.), and evaluation was carried out in the same manner as the above-mentioned evaluation (for adhesiveness). Thus, also in Example 4-A, peeling of patterns was not observed in the same manner as in Example 4.

Furthermore, puddle development was five repeated in an environment at 23° C. for 60 seconds, using CD-2000 (manufactured by Fujifilm Electronic Materials Co., Ltd.), and thus, peeling of patterns was not observed in Example 4, but peeling of patterns was slightly observed in Example 4-A.

The other evaluations were carried out using the evaluation substrate, and thus, in Example 4-A, the same results as in Example 4 were obtained.

### Example 4-B

In the same manner as in Example 4 except that carbon black (trade name: “color black S170”, manufactured by Degussa Corporation, average primary particle diameter of 17 nm, BET specific surface area of 200 m²/g, carbon black produced by a gas black method) was used instead of titanium black TB-1, an evaluation substrate for evaluation of adhesiveness (hereinafter also referred to as “Example 4-B”) was obtained.

The evaluation substrate was placed on a horizontal rotary table of a spin/shower developing machine (Model DW-30, manufactured by Chemitronics Co., Ltd.), and subjected to puddle development in an environment at 23° C. for 60 seconds, using CD-2000 (manufactured by Fujifilm Electronic Materials Co., Ltd.), and evaluation was carried out in the same manner as the above-mentioned evaluation (for adhesiveness). Thus, also in Example 4-B, peeling of patterns was not observed in the same manner as in Example 4.

Furthermore, puddle development was five repeated in an environment at 23° C. for 60 seconds, using CD-2000 (manufactured by Fujifilm Electronic Materials Co., Ltd.), and thus, peeling of patterns was not observed in Example 4, but peeling of patterns was slightly observed in Example 4-B.

The other evaluations were carried out using the evaluation substrate, and thus, in Example 4-B, the same results as in Example 4 were obtained.

### Example 4-C

In the same manner as in Example 4 except that 0.25% of an ultraviolet absorber (trade name: “TINUVIN 900”, manufactured by BASF) was further added when the coloring composition was obtained, an evaluation substrate for light resistance (hereinafter also referred to as “Example 4-C”) was obtained.

The obtained evaluation substrate and the evaluation substrate of Example 4 were subjected to a test in which they were irradiated at an illuminance of 1.0×10⁵ lux for 70 hours or 90 hours, using a xenone lamp, and thus, a result that a difference was not observed with irradiation for 70 hours, but the light transmittance variation of Example 4-C was less with irradiation for 90 hours was obtained.

The other evaluations were carried out using the evaluation substrates, and thus, in Example 4-C, the same results as in Example 4 were obtained.

### Example 4-D

In the same manner as in Example 4 except that the solvent was changed to a mixed solvent of PGMEA and cyclohexanone (at a mass ratio of 1 to 1), an evaluation substrate (hereinafter also referred to as “Example 4-D”) was obtained.

The respective evaluations were carried out using the evaluation substrates, and thus, the same results as in Example 4 were obtained.

### Example 4-E

In the same manner as in Example 4 except that Pigment Red 254 (trade name: BK-CF, manufactured by Ciba Specialty Chemicals Inc.) was used instead of titanium black TB-1, an evaluation substrate (hereinafter also referred to as “Example 4-E”) was obtained.

The respective evaluations were carried out using the evaluation substrates, and thus, the same results as in Example 4 were obtained.

### Example 4-F

In the same manner as in Example 4 except that titanium black TB-1 (25%) was changed to titanium black TB-1 (20%) and Pigment Red 254 (5%), an evaluation substrate (hereinafter also referred to as “Example 4-F”) was obtained.

The respective evaluations were carried out using the evaluation substrates, and thus, the same results as in Example 4 were obtained.

In addition, as compared with Example 4, it could be seen that the light reflectivity and the light transmittance were low, and the light-shielding properties were excellent at a wavelength in the infrared ray region.

From the above results, it is presumed that even in a case of changing the coloring agent or using changing the coloring agents in combination, an effect desired in the present invention is obtained.

### Example 4-G

In the same manner as in Example 4 except that the polymerizable compound was changed to 2.5% of KAYARAD dipentaerythritol hexaacrylate (DPHA, manufactured by Nippon Kayaku Co., Ltd.) and 1.0% of PET-30 (pentaerythritol triacrylate, manufactured by Nippon Kayaku Co., Ltd.), an evaluation substrate (hereinafter also referred to as “Example 4-G”) was obtained.

The respective evaluations were carried out using the evaluation substrates, and thus, the same results as in Example 4 were obtained. In addition, as compared with Example 4, it could be seen that the developing speed was high and the developability was excellent.

### Examples 48 to 57

In the same manner as in Examples 1 to 47 except that the coloring agent 1 and the coloring agent 2 were used in combination at the mixing ratios (mass ratios) of the coloring agents shown in Table 4, coloring compositions were obtained using the components described in Table 4.

As the coloring agent 1, the same titanium black TB-1 as the titanium black TB-1 used in Example 1 or the like was used. As the coloring agent 2, the same niobium oxynitride as the niobium oxynitride used in Example 19 or the like was used.

### Example 58

In the same manner as in Example 49 except that niobium oxynitride 2 was used as the coloring agent 2, a coloring composition was obtained.

The niobium oxynitride 2 was prepared by producing niobium oxide particles produced by a method for producing fine nano-sized particles using plasma described in JP2012-055840A, and then using the niobium oxide particles thus produced, in accordance with JP2012-96945A.

More specifically, with regard to the production of the nano-sized fine particles, in the same manner as described in JP2012-055840A except that the raw material was changed from Ti powder to niobium powder (manufactured by Mitsuwa Chemicals Co., Ltd., trade name: niobium (powder)<-325 mesh>), and the treatment parameter of the device was appropriately adjusted, niobium oxide fine particles having particle diameters of 15 nm were obtained.

Subsequently, the obtained niobium oxide fine particles were reduced in an ammonia atmosphere at a high temperature, described in JP2012-96945A. a niobium oxynitride 2 was obtained.

### Comparative Example 5

In the same manner as in Example 49 except that the photopolymerization initiator was changed from the photopolymerization initiator I-1 (IRGACURE-OXE03 (manufactured by BASF)) to a photopolymerization initiator I-4 (IRGACURE-OXE02 (manufactured by BASF)), a coloring composition was obtained.

<Evaluations>

In the same manner as in Examples 1 to 47, using the obtained coloring compositions in Examples 48 to 58 and Comparative Example 5, evaluations were carried out. The results are shown in Table 4.

TABLE 4

| | | | Coloring agent | | | B: | | | |
|---|---|---|---|---|---|---|---|---|---|
| | | | 1/Coloring | | | Alkali-soluble | I: | | |
| | Coloring | Coloring | agent 2 (mass | | M: Polymerizable | resin (acid | Photopolymerization | | Organic |
| | agent 1 | agent 2 | ratio) | Dispersant | compound | value) | initiator (content) | Surfactant | solvent |
| Example 48 | TB-1 | Niobium | 10/90 | D-1 | A-1 | B-1 (31.6) | I-1 (5%) | W-1 | PGMEA |
| | | oxynitride | | | | | | | |
| Example 49 | TB-1 | Niobium | 20/80 | D-1 | A-1 | B-1 (31.6) | I-1 (5%) | W-1 | PGMEA |
| | | oxynitride | | | | | | | |
| Example 50 | TB-1 | Niobium | 30/70 | D-1 | A-1 | B-1 (31.6) | I-1 (5%) | W-1 | PGMEA |
| | | oxynitride | | | | | | | |
| Example 51 | TB-1 | Niobium | 50/50 | D-1 | A-1 | B-1 (31.6) | I-1 (5%) | W-1 | PGMEA |
| | | oxynitride | | | | | | | |
| Example 52 | TB-1 | Niobium | 70/30 | D-1 | A-1 | B-2 (31.5) | I-1 (5%) | W-1 | PGMEA |
| | | oxynitride | | | | | | | |
| Example 53 | TB-1 | Niobium | 30/70 | D-1 | A-1 | B-3 (29.6) | I-1 (5%) | W-1 | PGMEA |
| | | oxynitride | | | | | | | |
| Example 54 | TB-1 | Niobium | 30/70 | D-1 | A-1 | B-4 (112.8) | I-1 (5%) | W-1 | PGMEA |
| | | oxynitride | | | | | | | |
| Example 55 | TB-1 | Niobium | 30/70 | D-1 | A-1 | B-1 (31.6) | I-1 (0.1%) | W-1 | PGMEA |
| | | oxynitride | | | | | | | |
| Example 56 | TB-1 | Niobium | 30/70 | D-1 | A-1 | B-1 (31.6) | I-1 (1%) | W-1 | PGMEA |
| | | oxynitride | | | | | | | |
| Example 57 | TB-1 | Niobium | 30/70 | D-1 | A-1 | B-1 (31.6) | I-2 (5%) | W-1 | PGMEA |
| | | oxynitride | | | | | | | |
| Example 58 | TB-1 | Niobium | 20/80 | D-1 | A-1 | B-1 (31.6) | I-1 (5%) | W-1 | PGMEA |
| | | oxynitride 2 | | | | | | | |
| Comparative | TB-1 | Niobium | 20/80 | D-1 | A-1 | B-1 (31.6) | I-4 (5%) | W-1 | PGMEA |
| Example 5 | | oxynitride 2 | | | | | | | |

| | B/M | Ih: Polymerization | | Heat | Light | Solvent | Moisture | | |
|---|---|---|---|---|---|---|---|---|---|
| | ratio | inhibitor (content) | Ih/I ratio | resistance | resistance | resistance | resistance | Adhesiveness | Linearity |
| Example 48 | 0.9 | Ih-1 (0.003%) | 0.003 | A | A | A | 0 | A | 2.2 |
| Example 49 | 0.9 | Ih-1 (0.003%) | 0.003 | A | A | A | 0 | A | 2.1 |
| Example 50 | 0.9 | Ih-1 (0.003%) | 0.003 | A | A | A | 0 | A | 2.2 |
| Example 51 | 0.9 | Ih-1 (0.003%) | 0.003 | A | A | A | 0 | A | 2.3 |
| Example 52 | 0.9 | Ih-1 (0.003%) | 0.003 | A | A | A | 0 | A | 2.1 |
| Example 53 | 0.9 | Ih-1 (0.003%) | 0.003 | A | A | A | 0 | A | 2.1 |
| Example 54 | 0.9 | Ih-1 (0.003%) | 0.003 | A | A | A | 0 | A | 2.1 |
| Example 55 | 0.9 | Ih-1 (0.003%) | 0.003 | A | B | B | 3 | B | 3.1 |
| Example 56 | 0.9 | Ih-1 (0.003%) | 0.003 | A | A | A | 1 | B | 2.8 |
| Example 57 | 0.9 | Ih-1 (0.003%) | 0.003 | A | A | A | 0 | A | 2.1 |
| Example 58 | 0.9 | Ih-1 (0.003%) | 0.003 | A | A | A | 0 | A | 2.1 |
| Comparative | 0.9 | Ih-1 (0.003%) | 0.003 | C | C | C | 16 | D | 6.5 |
| Example 5 | | | | | | | | | |

As shown in Table 4, it could be seen that also in Examples 48 to 58, the curing proceeded even with heating at a low temperature (50° C.) as in Examples 1 to 47.

To the contrary, in Comparative Example 5, the curing was insufficient with heating at a low temperature (50° C.).

### Examples 59 and 60

In the same manner as in Examples 50 and 52 except that titanium black TB-1 was changed to titanium nitride, coloring compositions of Examples 59 and 60 were prepared. The same evaluations as above were carried out using the coloring compositions of Examples 59 and 60, and thus, the same evaluation results as each of Examples 50 and 52 were obtained.

### Examples 61 and 62

In the same manner as in Examples 50 and 52 except that niobium oxynitride was changed to titanium nitride, coloring compositions of Examples 61 to 62 were prepared. The same evaluations as above were carried out using the coloring compositions of Examples 61 to 62, and thus, the same evaluation results as each of Examples 50 and 52 were obtained.

### Example 63

In the same manner as in Example 50 except that niobium oxynitride was changed to carbon black, a coloring composition of Example 63 was prepared. The same evaluations as above were carried out using the coloring composition of Example 63, and thus, the same evaluation results as each of Example 50 were obtained.

### Example 64

In the same manner as in Example 50 except that titanium black TB-1 was changed to carbon black, a coloring composition of Example 64 was prepared. The same evaluations as above were carried out using the coloring composition of Example 64, and thus, the same evaluation results as each of Example 50 were obtained.

### Example 65

In the same manner as in Example 50 except that niobium oxynitride was changed to carbon black and the titanium black TB-1 was changed to titanium nitride, a coloring composition of Example 65 was prepared. The same evaluations as above were carried out using the coloring composition of Example 65, and thus, the same evaluation results as each of Example 50 were obtained.

### Examples 66 to 77

In the same manner as in Examples 1 to 40 except that the photopolymerization initiator was changed to OE-1, OE-3, OE6, OE7, OE11, OE62, or OE74 (a single form as an E isomer, a single form as a Z isomer, or a mixture of an E isomer and a Z isomer), coloring compositions of Examples 66 to 77 were prepared.

In the same manner as in Examples 1 to 40 except that the exposure was carried out at an exposure dose of 100 mJ/cm² using the coloring compositions of Examples 66 to 77, evaluations were carried out. The results are shown in Table 5.

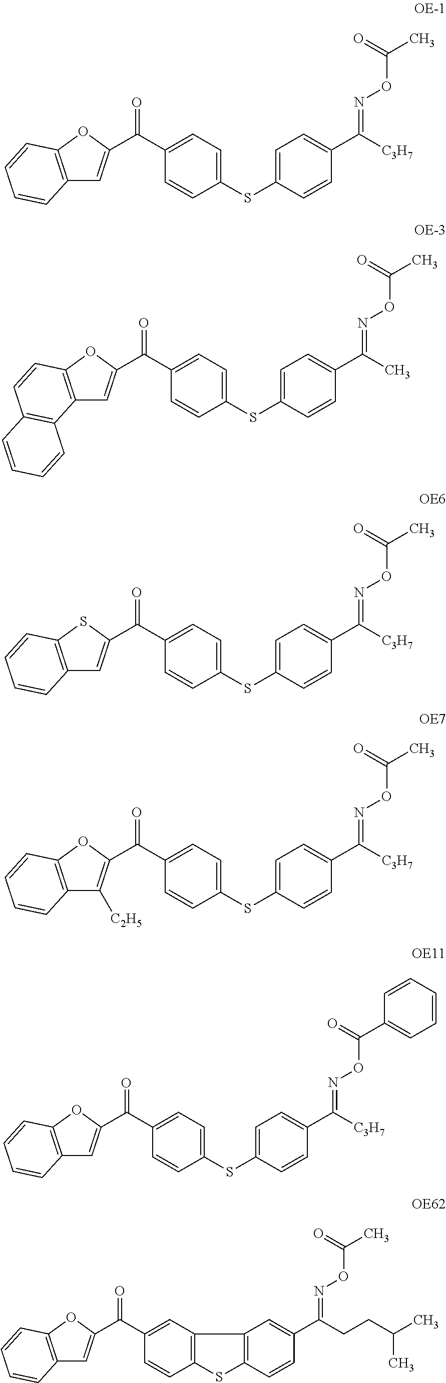

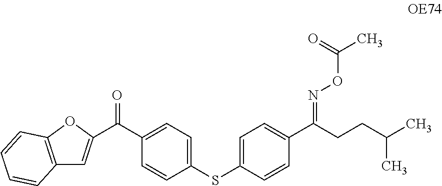 [SMILES: CC(=O)O/N=C(\CCC(C)C)c1ccc(Sc2ccc(C(=O)c3cc4ccccc4o3)cc2)cc1]

TABLE 5

| | | | | B: | | | | |
|---|---|---|---|---|---|---|---|---|
| | | | M: | Alkali-soluble | I: | | | |
| | Coloring | | Polymerizable | resin (acid | Photopolymerization | | Organic | B/M |
| | agent | Dispersant | compound | value) | initiator (content) | Surfactant | solvent | ratio |
| Example 66 | TB-1 | D-1 | A-1 | B-2 (31.5) | OE-1 (5%) | W-1 | PGMEA | 0.9 |
| Example 67 | TB-1 | D-1 | A-1 | B-2 (31.5) | OE-3 (5%) | W-1 | PGMEA | 0.9 |
| Example 68 | TB-1 | D-1 | A-1 | B-2 (31.5) | OE6 (5%) | W-1 | PGMEA | 0.9 |
| Example 69 | TB-1 | D-1 | A-1 | B-2 (31.5) | OE7 (5%) | W-1 | PGMEA | 0.9 |
| Example 70 | TB-1 | D-1 | A-1 | B-2 (31.5) | OE11 (5%) | W-1 | PGMEA | 0.9 |
| Example 71 | TB-1 | D-1 | A-1 | B-2 (31.5) | OE62 (5%) | W-1 | PGMEA | 0.9 |
| Example 72 | TB-1 | D-1 | A-1 | B-2 (31.5) | OE74 (5%) | W-1 | PGMEA | 0.9 |
| Example 73 | TB-1 | D-1 | A-1 | B-1 (31.6) | OE74 (5%) | W-1 | PGMEA | 0.9 |
| Example 74 | TB-1 | D-1 | A-1 | B-3 (29.6) | OE74 (5%) | W-1 | PGMEA | 0.9 |
| Example 75 | TB-1 | D-1 | A-1 | B-4 (112.8) | OE74 (5%) | W-1 | PGMEA | 0.9 |
| Example 76 | TB-1 | D-1 | A-1 | B-2 (31.5) | OE74 (0.1%) | W-1 | PGMEA | 0.9 |
| Example 77 | TB-1 | D-1 | A-1 | B-2 (31.5) | OE74 (1%) | W-1 | PGMEA | 0.9 |

| | Ih: Polymerization | Ih/I | Heat | Light | Solvent | Moisture | | |
|---|---|---|---|---|---|---|---|---|
| | inhibitor (content) | ratio | resistance | resistance | resistance | resistance | Adhesiveness | Linearity |
| Example 66 | Ih-1 (0.003%) | 0.003 | A | A | A | 4 | A | 2.3 |
| Example 67 | Ih-1 (0.003%) | 0.003 | A | A | A | 3 | A | 2.7 |
| Example 68 | Ih-1 (0.003%) | 0.003 | A | A | A | 3 | A | 2.8 |
| Example 69 | Ih-1 (0.003%) | 0.003 | A | A | A | 4 | A | 2.4 |
| Example 70 | Ih-1 (0.003%) | 0.003 | A | A | A | 2 | B | 2.5 |
| Example 71 | Ih-1 (0.003%) | 0.003 | A | A | A | 3 | A | 2.3 |
| Example 72 | Ih-1 (0.003%) | 0.003 | A | A | A | 0 | A | 2.2 |
| Example 73 | Ih-1 (0.003%) | 0.003 | A | A | A | 1 | A | 2.4 |
| Example 74 | Ih-1 (0.003%) | 0.003 | A | A | A | 0 | A | 2.3 |
| Example 75 | Ih-1 (0.003%) | 0.003 | A | A | A | 0 | A | 2.3 |
| Example 76 | Ih-1 (0.003%) | 0.003 | B | A | B | 5 | B | 2.8 |
| Example 77 | Ih-1 (0.003%) | 0.003 | A | A | A | 3 | B | 2.6 |

As shown in Table 5, it could be seen that also in Examples 66 to 77, the curing proceeded even with heating at a low exposure dose (100 mJ/cm²) and a low temperature (50° C.).

### Example 78

The components shown in Table 6 were mixed and then filtered using a nylon-made filter having a pore diameter of 0.45 μm (DFA4201NXEY, manufactured by Nihon Pall Ltd.) to prepare a coloring composition. More specifically, titanium black, a dispersant, and a solvent were first mixed using a stirrer (EUROSTAR manufactured by IKA) for 15 minutes and filtered in the same manner to obtain a dispersion. Then, the rest of the components were added to the dispersion and mixed to obtain a coloring composition.

The concentrations of the respective components are as follows.
Titanium black TB-1 14.7%
Dispersant D-1 4.4%
M: Polymerizable compound A-16.7%
B: Alkali-soluble resin B-2 4.2%
Photopolymerization initiator I-1 1.38%
Surfactant W-1 0.02%
Organic solvent Balance

In this case, the content of the photopolymerization initiator was 4.4% with respect to the total solid content of the obtained coloring composition.

### Examples 79 to 88

In the same manner as in Example 78 except that the alkali-soluble resin, the photopolymerization initiator, the organic solvent, and the B/M ratio were changed as shown in Table 6, coloring compositions of Examples 79 to 88 were prepared. Further, in a case where the B/M ratio was changed, the content of the polymerizable compound (M) was increased or decreased.

<Evaluation 1>

In the same manner as in Examples 1 to 40, evaluations were carried out using the coloring compositions of Examples 78 to 88. The results are shown in Table 6.

TABLE 6

| | | | | B: | | | |
|---|---|---|---|---|---|---|---|
| | | | M: | Alkali-soluble | I: | | |
| | Coloring | | Polymerizable | resin (acid | Photopolymerization | | |
| | agent | Dispersant | compound | value) | initiator (content) | Surfactant | Organic solvent (mass ratio) |
| Example | TB-1 | D-1 | A-1 | B-2 (31.5) | I-1 (4.4%) | W-1 | PGMEA |
| 78 | | | | | | | |
| Example | TB-1 | D-1 | A-1 | B-2 (31.5) | I-1 (4.4%) | W-1 | PGMEA/cyclohexanone/acetate |
| 79 | | | | | | | butyl (50/25/25) |
| Example | TB-1 | D-1 | A-1 | B-2 (31.5) | I-1 (1.0%) | W-1 | PGMEA/cyclohexanone/acetate |
| 80 | | | | | | | butyl (50/25/25) |
| Example | TB-1 | D-1 | A-1 | B-2 (31.5) | I-1 (5.4%) | W-1 | PGMEA/cyclohexanone/acetate |
| 81 | | | | | | | butyl (50/25/25) |
| Example | TB-1 | D-1 | A-1 | B-2 (31.5) | I-1 (4.4%) | W-1 | PGMEA/cyclohexanone/acetate |
| 82 | | | | | | | butyl (50/25/25) |
| Example | TB-1 | D-1 | A-1 | B-2 (31.5) | I-1 (4.4%) | W-1 | PGMEA/cyclohexanone/acetate |
| 83 | | | | | | | butyl (50/25/25) |
| Example | TB-1 | D-1 | A-1 | B-1 (31.6) | I-1 (4.4%) | W-1 | PGMEA/cyclohexanone/acetate |
| 84 | | | | | | | butyl (50/25/25) |
| Example | TB-1 | D-1 | A-1 | B-3 (29.6) | I-1 (4.4%) | W-1 | PGMEA/cyclohexanone/acetate |
| 85 | | | | | | | butyl (50/25/25) |
| Example | TB-1 | D-1 | A-1 | B-4 (112.8) | I-1 (4.4%) | W-1 | PGMEA/cyclohexanone/acetate |
| 86 | | | | | | | butyl (50/25/25) |
| Example | TB-1 | D-1 | A-1 | B-2 (31.5) | I-2 (4.4%) | W-1 | PGMEA/cyclohexanone/acetate |
| 87 | | | | | | | butyl (50/25/25) |
| Example | TB-1 | D-1 | A-1 | B-2 (31.5) | OE74 (4.4%) | W-1 | PGMEA/cyclohexanone/acetate |
| 88 | | | | | | | butyl (50/25/25) |

| | | Ih: | | | | | | | |
|---|---|---|---|---|---|---|---|---|---|
| | | Polymerization | | | | | | | |
| | B/M | inhibitor | Ih/I | Heat | Light | Solvent | Moisture | | |
| | ratio | (content) | ratio | resistance | resistance | resistance | resistance | Adhesiveness | Linearity |
| Example | 0.6 | Ih-1 (0.003%) | 0.003 | A | A | A | 2 | A | 2.7 |
| 78 | | | | | | | | | |
| Example | 0.6 | Ih-1 (0.003%) | 0.003 | A | A | A | 2 | A | 2.7 |
| 79 | | | | | | | | | |
| Example | 0.6 | Ih-1 (0.003%) | 0.003 | A | A | A | 2 | B | 2.9 |
| 80 | | | | | | | | | |
| Example | 0.6 | Ih-1 (0.003%) | 0.003 | A | A | A | 2 | A | 2.7 |
| 81 | | | | | | | | | |
| Example | 0.9 | Ih-1 (0.003%) | 0.003 | A | A | A | 2 | B | 2.9 |
| 82 | | | | | | | | | |
| Example | 0.3 | Ih-1 (0.003%) | 0.003 | A | A | A | 2 | A | 2.8 |
| 83 | | | | | | | | | |
| Example | 0.6 | Ih-1 (0.003%) | 0.003 | A | A | A | 4 | A | 2.7 |
| 84 | | | | | | | | | |
| Example | 0.6 | Ih-1 (0.003%) | 0.003 | A | A | A | 3 | A | 3 |
| 85 | | | | | | | | | |
| Example | 0.6 | Ih-1 (0.003%) | 0.003 | A | A | A | 3 | A | 2.8 |
| 86 | | | | | | | | | |
| Example | 0.6 | Ih-1 (0.003%) | 0.003 | A | A | A | 2 | A | 2.7 |
| 87 | | | | | | | | | |
| Example | 0.6 | Ih-1 (0.003%) | 0.003 | A | A | A | 2 | A | 2.7 |
| 88 | | | | | | | | | |

As shown in Table 6, it could be seen that also in Examples 78 to 88, the curing proceeded even with heating at a low temperature (50° C.).

<Evaluation 2>

A support having an epoxy resin layer formed on a glass substrate (EagleXG, manufactured by Corning Inc.) using an epoxy resin (JER-827, manufactured by Japan Epoxy Resins Co., Ltd.) was prepared.

The coloring compositions of Examples 78 to 88 were applied onto the support by a spin method such that the thickness reached 1.5 μm. Then, exposure and development were carried out in the same manner as in Examples 1 to 40 except that a mask with a pattern having a contact hole in 10 μm was used. As a result, a good pattern having a measurement deviation 3a of 3 or less was obtained. This is referred to as a substrate A.

### Example 89

An epoxy resin layer was formed on the substrate obtained in Evaluation 2 of Example 78, using an epoxy resin (JER-827, manufactured by Japan Epoxy Resins Co., Ltd.), and a pattern was formed in the same manner as in Evaluation 2, using the coloring composition of Example 78. Thus, a good pattern having a measurement deviation 3a of 3 or less was obtained.

### Examples 90 to 99

Evaluations were carried out in the same manner as in Example 89, using the coloring compositions of Examples 79 to 88, and thus, the same results as in Example 89 were obtained.

What is claimed is:

1. A coloring photosensitive composition comprising:
a coloring agent;
a polymerizable compound; and
a photopolymerization initiator,
wherein the photopolymerization initiator in the form of a solution in which 0.001% by mass of the photopolymerization initiator is dissolved in acetonitrile has an absorbance of 0.45 or more at a wavelength of 340 nm.

2. The coloring photosensitive composition according to claim 1,
wherein the photopolymerization initiator is a compound represented by Formula (I), 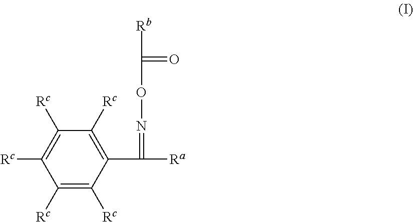
in Formula (I), R^{a} represents an alkyl group, an acyl group, an aryl group, or a heterocyclic group, R^{b} represents an alkyl group, an aryl group, or a heterocyclic group, a plurality of R^{c}'s each independently represent a hydrogen atom, an alkyl group, or a group represented by —OR^{h}, and R^{h} represents an electron-withdrawing group or an alkyl ether group, provided that at least one of the plurality of R^{c}'s represents a group represented by —OR^{h}.

3. The coloring photosensitive composition according to claim 2,
wherein R^{a} is a heterocyclic group.

4. The coloring photosensitive composition according to claim 2,
wherein one or two of the plurality of R^{c}'s are the groups represented by —OR^{h}.

5. The coloring photosensitive composition according to claim 2,
wherein R^{h} in the group represented by —OR^{h} represents an electron-withdrawing group, and the electron-withdrawing group is an alkyl group having 1 to 20 carbon atoms, in which at least one hydrogen atom is substituted with a fluorine atom.

6. The coloring photosensitive composition according to claim 2,
wherein R^{h} in the group represented by —OR^{h} represents an alkyl ether group.

7. The coloring photosensitive composition according to claim 1,
wherein the polymerizable compound has 5 or more ethylenically unsaturated double bonds.

8. The coloring photosensitive composition according to claim 1, further comprising a polymerization inhibitor.

9. The coloring photosensitive composition according to claim 8,
wherein two or more phenol-based polymerization inhibitors are used in combination as the polymerization inhibitor.

10. The coloring photosensitive composition according to claim 8,
wherein a phenol-based polymerization inhibitor and a hindered amine-based polymerization inhibitor are used in combination as the polymerization inhibitor.

11. The coloring photosensitive composition according to claim 1,
wherein the coloring agent includes titanium black.

12. The coloring photosensitive composition according to claim 11,
wherein the titanium black is titanium nitride.

13. The coloring photosensitive composition according to claim 1,
wherein the coloring agent includes niobium oxynitride.

14. The coloring photosensitive composition according to claim 1, further comprising an organic solvent.

15. The coloring photosensitive composition according to claim 14,
wherein two or more organic solvents are used in combination as the organic solvent.

16. A method for producing a cured film, comprising at least:
a step of forming a coloring photosensitive composition layer on a support, using the coloring photosensitive composition according to claim 1; and
a step of exposing the coloring photosensitive composition layer to form a cured film.

17. The method for producing a cured film according to claim 16, further comprising a step of subjecting the cured film to a heating treatment,
wherein the temperature for the heating treatment is 120° C. or lower.

18. The method for producing a cured film according to claim 16, further comprising a step of subjecting the cured film to a heating treatment,
wherein the temperature for the heating treatment is 80° C. or lower.

19. The method for producing a cured film according to claim 16, further comprising a step of subjecting the cured film to a heating treatment,
wherein the temperature for the heating treatment is 50° C. or lower.

20. The method for producing a cured film according to claim 16,
wherein the support has an epoxy resin layer on the surface on which the cured film is formed.
